(19) United States
(12) Patent Application Publication
(10) Pub. No.: US 2026/0075785 A1
(43) Pub. Date: Mar. 12, 2026

(54) Electrostatic Protection Structure For Display Panel And Display Panel And Display Device Using The Same

(71) Applicant: Century Technology (ShenZhen) Corp.,LTD, Shen-zhen (CN)

(72) Inventors: RUI LI, Shen-zhen (CN); YUAN XIONG, Shen-zhen (CN); QUN YE, Shen-zhen (CN); CHIH-CHUNG LIU, Shen-zhen (CN); MENG-CHIEH TAI, Shen-zhen (CN); WEN-LIN CHEN, Shen-zhen (CN); HUI WANG, Shen-zhen (CN); LIE-BIN WU, Shen-zhen (CN); HONG-HUAN HUANG, Shen-zhen (CN); ZAN-BIAO YANG, Shen-zhen (CN); YU-XI QIAO, Shen-zhen (CN); WEN-PO KO, Shen-zhen (CN); KUO-SHENG LEE, Shen-zhen (CN); CHIH-KWANG TZEN, Shen-zhen (CN); CHUN-GUANG PANG, Shen-zhen (CN); HONG-ZHEN HUANG, Shen-zhen (CN)

(21) Appl. No.: 19/286,928

(22) Filed: Jul. 31, 2025

(30) Foreign Application Priority Data
Jul. 31, 2024 (CN) 202411046763.X
Oct. 25, 2024 (CN) 202411505135.3
Nov. 1, 2024 (CN) 202411554378.6
Dec. 6, 2024 (CN) 202411796663.9
Dec. 6, 2024 (CN) 202411798890.5
Dec. 31, 2024 (CN) 202411997009.4
Dec. 31, 2024 (CN) 202411997099.7
Feb. 11, 2025 (CN) 202510152212.X
Apr. 30, 2025 (CN) 202510569933.0

(51) Int. Cl. H05K 9/00; G02F 1/1335; G02F 1/1362; G02F 1/1368

(52) U.S. Cl. CPC H05K 9/0054; G02F 1/133512; G02F 1/136286; G02F 1/1368; G02F 2201/503

(57) ABSTRACT

The present application relates to an electrostatic protection structure for a display panel. The display panel comprises a substrate, a pixel array, a plurality of scan lines, a plurality of data lines, and an electrostatic protection structure. The substrate has a display region and a non-display region, which includes a bezel area. The pixel array is disposed on the display region of the substrate and comprises a plurality of pixel units arranged in an array. The scan lines are formed on the substrate and electrically connected to each row of pixel units in the pixel array. The data lines are formed on the substrate and electrically connected to each column of pixel units in the pixel array. The electrostatic protection structure is disposed in the bezel area and comprises a first metal layer, a first insulating layer, a second metal layer, and a second insulating layer stacked in sequence.

### CROSS-REFERENCE TO RELATED APPLICATION

This application claims priority to Chinese Patent Applications No. CN 202510569933.0 filed on Apr. 30, 2025; CN 202510152212.X filed on Feb. 11, 2025; CN 202411997099.7 filed on Dec. 31, 2024; CN 202411997009.4 filed on Dec. 31, 2024; CN 202411798890.5 filed on Dec. 6, 2024; CN 202411796663.9 filed on Dec. 6, 2024; CN 202411554378.6 filed on Nov. 1, 2024; CN 202411505135.3 filed on Oct. 25, 2024; and CN 202411046763.X filed on Jul. 31, 2024, the disclosures of which are incorporated herein in their entireties by reference.

### TECHNICAL FIELD

The present application relates to the field of display technology, particularly to an electrostatic protection structure for a display panel and a display panel and display device using the same.

### BACKGROUND

In modern display technology, display devices play a crucial role. These devices are widely used in televisions, computer monitors, smartphones, and various other equipment. The display panel is the core component of a display device, responsible for generating images visible to users. Existing display panel technologies include liquid crystal displays (LCDs), organic light-emitting diodes (OLEDs), and quantum-dot light-emitting diodes (QLEDs). Among these, LCD technology relies on a backlight module to illuminate the display panel. The backlight module typically includes light-emitting diodes (LEDs) as the light source and a light guide plate to distribute light evenly. Additionally, the pixel array in the display panel is essential for producing high-quality images. Each pixel consists of red, green, and blue sub-pixels, which work together to create vibrant and colorful images. However, while current technologies offer high resolution and color accuracy, they often face challenges in energy efficiency and manufacturing costs.

During the manufacturing process of display devices, three main stages are typically involved: the array process, the cell process, and the module integration process. In the array process, steps such as cleaning, thin-film deposition, photolithography, etching, and metallization are performed on a glass substrate to form a thin-film transistor array (also known as a TFT array substrate or pixel array substrate). Subsequently, in the cell process, the thin-film transistor array is combined with a color filter, and liquid crystal material is injected to encapsulate and form the display unit/panel. In the module integration process, a plurality of display panels arranged on a mother substrate are segmented and assembled with corresponding driving circuits to form independent display devices.

During the array manufacturing process, steps such as film formation, mask exposure, and etching are involved, where high-speed airflow rubbing against the glass substrate can easily generate static electricity. Additionally, during the handling of the glass substrate for the TFT array substrate, friction with equipment can also produce static electricity, leading to electrostatic discharge (ESD). Static electricity is a common phenomenon in nature, occurring when two materials with different dielectric constants rub against each other. The release of accumulated charge from a charged object, returning it to a neutral state (such as the spark produced when a person touches a doorknob), is called electrostatic discharge, or ESD. The effects of ESD can significantly reduce the yield rate of display panels.

More specifically, when the aforementioned electrostatic discharge (ESD damage) occurs, it generates high temperatures exceeding those of the metals used in the TFT array substrate manufacturing process. The temperature during ESD is above 3000° C., which is higher than the melting points of materials commonly used in TFT array substrates (such as aluminum, copper, and molybdenum), thus causing electrostatic damage to the metal lines in the TFT array substrate. For example, when a large instantaneous current flows through an indium tin oxide (ITO) electrode, it can cause oxygen atoms to escape, leaving behind indium and tin and making the electrode opaque. Additionally, when a high voltage instantaneously breaks down the insulating layer, it can leave defects, leading to leakage between electrodes and preventing accurate voltage setting. Although these defects typically occur under high electrostatic voltages, even smaller electrostatic voltages can still damage the structure of the TFT array substrate.

In common mother substrate designs, test circuit lines are present on the glass substrate of the mother substrate, surrounding the display panels on the glass substrate. Each test circuit line connects to its corresponding display panel. During manufacturing, if static electricity is generated due to friction between high-speed airflow and the glass substrate or during substrate handling, the charges produced can be dispersed across the entire glass substrate of the mother substrate through these test circuit lines. This helps reduce damage to the circuitry on the display panels caused by static electricity.

However, due to the fixed size of the glass substrate of the mother substrate, when manufacturing small-sized display panels, those skilled in the art will strive to design and place as many display panels as possible on a single glass substrate. In other words, the number of display panels arranged on the glass substrate becomes a crucial factor in the production process. To maximize the utilization of the glass substrate, no gaps are left between display panels, thereby optimizing the substrate's usage efficiency. Yet, under such a design, there is no extra space to further accommodate the test circuit lines, which increases the risk of electrostatic damage during the manufacturing process, leading to yield losses.

Currently, the electrostatic protection structure of the mother substrate primarily relies on test circuit lines to achieve its purpose, but this approach limits the number of display panels that can be arranged on a single mother substrate. Specifically, the test circuit lines on the array substrate occupy significant space. In conventional techniques, the spacing from one side of a line away from another line to the side of another line near a line is 90-160 μm. Typically, the test circuit lines on an array substrate require at least 7 to 14 such spacings, and the test points on the array substrate also need 5000 μm or more space. In other words, the space required for the test circuit lines per display panel on an array substrate must exceed 6120-7240 μm.

Additionally, to further mitigate electrostatic effects, some applications incorporate an electrostatic discharge ring around the bezel area of the display panel to dissipate static electricity accumulated during the manufacturing process, thereby enhancing the panel's electrostatic protection capability. However, during the assembly of the display panel, a seal gum is applied via screen printing or dispensing processes to bond the pixel array substrate and the color filter substrate into place, sealing the two substrates together. This prevents moisture and other contaminants from entering the liquid crystal cell, isolates the liquid crystal molecules from external exposure, avoids leakage, and ensures product reliability.

After the seal gum is applied to the bezel area of the display panel, UV light scanning is used to improve curing efficiency. However, traditional electrostatic discharge rings are designed to be relatively wide, which blocks a large portion of the UV light intended to assist in curing the seal gum. This reduces the seal gum's curing rate, leading to issues such as liquid leakage in the LCD panel, moisture ingress causing corrosion, and other adverse effects on panel display performance.

Typically, a substrate will only have test circuit lines configured when used with large-sized display panels. When arranging a greater number of small-sized display panels on the substrate, the configuration of test circuit lines is omitted. In such cases, since the substrate lacks test circuit lines, the display panel becomes unable to avoid electrostatic discharge. On the other hand, as market demands for narrower panel bezels increase, the distance from the electrostatic discharge ring to the cutting line becomes smaller, which may cause the cutting wheel to slice into the metal layer, resulting in poor conductivity of the electrostatic discharge ring.

Therefore, for those skilled in the art, when configuring small-sized display panels on the substrate, achieving electrostatic protection while increasing the number of display panels that can be arranged is also a critical challenge in this field.

On the other hand, in the manufacturing process of display devices, packaging technology is a key step that affects the performance and reliability of the equipment. The primary goal of packaging technology is to effectively integrate the microelectronic components of the display screen onto the display panel. Among these, Chip on Glass (COG) packaging technology involves directly mounting the integrated driving circuit (i.e., the driver chip or driver IC) of the display device onto the glass substrate, enabling the driver IC to directly output the required voltage or signals to each pixel in the display module. COG packaging technology is relatively mature, cost-effective, and allows for easy production capacity adjustment. However, because it requires placing the driver IC on the glass substrate, limitations such as IC size and line requirements make it difficult to achieve narrow-bezel designs in display devices using COG packaging.

In COG packaging technology, integrating the scan driving circuit on the glass substrate can be referred to as Gate Driver on Panel (GOP). In GOP-driven designs, the scan driving circuit (or scan driver circuit) is fabricated using the same process as the thin film transistors (TFTs) in the pixel array, relying on only a few timing control signals provided by external circuits. This approach eliminates the need for additional integrated circuits related to scan driving, thereby reducing the manufacturing cost of liquid crystal displays. Moreover, since GOP-driven designs require fewer timing control signals to operate, they optimize the space needed for signal lines in external circuits, thereby increasing the effective display region.

With technological advancements, Chip on Film (COF) packaging has emerged, enabling the direct mounting of driver ICs onto flexible circuit boards that are then bent and arranged on the back of the display panel. Since there is no need to place the driver IC on the glass substrate, the bezel area can be effectively reduced, making it easier to meet the demand for narrow bezels. However, although COF packaging can shrink the bezel size, it comes with higher technical barriers, relatively elevated production costs, and limitations on production capacity. Both of the aforementioned technologies face constraints when achieving narrow-bezel designs, making it difficult to balance cost and performance considerations.

For example, in COF-packaged display panel designs, the scan lines of the pixel array are typically connected to the driver IC via fan-out lines. The line layout generally employs either single-layer metal or staggered double-layer metal arrangements. Yet, regardless of the chosen design, it remains challenging to simultaneously meet both narrow-bezel requirements and line corrosion resistance reliability needs.

On the other hand, in GOP-packaged display panel designs, the scan line voltage is generated by the gate circuits on the panel rather than provided by the integrated circuit, while the data line voltage is still directly supplied by the driver IC. Since GOP packaging only requires a few driver IC pins to drive the gate circuits on the panel to generate scan line voltage signals, it reduces reliance on the integrated circuit chip, optimizing edge design. This offers relatively better advantages for small-sized device designs.

During the panel design process from the array to the cell stage, the pixel array portion of the panel and the color filter are bonded using seal gum. Ultraviolet (UV) light is applied during bonding to facilitate seal gum curing and ensure panel adhesion reliability. However, in most current panel gate circuit designs, capacitors use opaque metals on both sides, occupying a relatively large edge area, which significantly reduces UV light transmittance. This compromises seal gum curing effectiveness and ultimately diminishes panel reliability.

Additionally, as market demands for higher resolution continue to grow, pixel sizes in display panel designs are shrinking. Although pixel dimensions decrease, the line width and pitch of scan and data lines do not scale down accordingly. Consequently, smaller pixels result in reduced overlapping area between the pixel electrode and the common electrode. Under these constraints, conventional pixel designs often suffer from insufficient storage capacitance, making it difficult to meet requirements for pixel voltage stabilization and leakage current reduction.

To integrate touch functionality into a display device, it is typically necessary to embed a touch panel onto the display panel in an on-cell or in-cell manner to form a touch control display panel. The advantage of an on-cell touch control display panel lies in its simple structure, relatively low manufacturing cost, and the fact that touch electrodes only need to be added to the upper layer of the existing display panel, eliminating the need for complex modifications to the display panel's structure, resulting in higher production yield. However, in on-cell touch control display panels, the distance between the touch sensing electrodes and the finger is relatively large (usually separated by encapsulation glass or a color filter), leading to weaker capacitive signals and affecting touch recognition sensitivity. Additionally, since the touch electrodes are added onto the display panel, it becomes difficult to reduce the overall thickness of the device, which is unfavorable for the current trend toward slim and lightweight designs.

In-cell touch control display panels integrate touch electrodes directly inside the display panel, coexisting with the pixel structure of the display panel, thereby reducing the overall panel thickness. However, because the touch electrodes in in-cell touch control display panels coexist with the display pixel electrodes, display driving signals may interfere with touch signals, causing noise. In general designs, to avoid interference, precise timing design for touch sensing is required, ensuring that touch scanning and display refresh alternate to prevent signal aliasing, making the driving design of the display device more complex. Furthermore, in display panels with high refresh rates (such as 120 Hz, 240 Hz), coordinating the scanning cycles of touch control and display to ensure high-precision touch control while avoiding display flickering presents a significant technical challenge.

### SUMMARY

One of the objects of the present application is to provide an electrostatic protection structure for a display panel, as well as a display panel and display device incorporating the same, to address the aforementioned issues, including but not limited to the impact of electrostatic discharge on display panel manufacturing yield, poor electrostatic protection effectiveness and insufficient storage capacitance in small-sized display panels, low reliability in the seal gum curing process, excessively high complexity in the driving design of display driver panels leading to difficulty in cost reduction, and challenges in ensuring surface flatness during the manufacturing process of display panels.

An embodiment of the present application provides a display panel. The display panel comprises a substrate, a pixel array, a plurality of scan lines, a plurality of data lines, and an electrostatic protection structure. The substrate has a display region and a non-display region, wherein the non-display region comprises a bezel area. The pixel array is arranged on the display region of the substrate and comprises a plurality of pixel units arranged in an array. The plurality of scan lines are formed on the substrate and electrically connected to each row of pixel units in the pixel array. The plurality of data lines are formed on the substrate and electrically connected to each column of pixel units in the pixel array. The electrostatic protection structure is disposed in at least a portion of the bezel area and comprises a first metal layer, a first insulating layer, a second metal layer, and a second insulating layer stacked in sequence, wherein at least one of the first metal layer and the second metal layer has a porous structure to form a discontinuous island structure in the cross-section of the electrostatic protection structure.

In some embodiments of the present application, the display panel further comprises a first fan-out transmission part and a second fan-out transmission part. The first fan-out transmission part is disposed on one side of the non-display region and comprises a plurality of fan-out lines, wherein the plurality of fan-out lines of the first fan-out transmission part are electrically connected to the odd-numbered scan lines respectively. The second fan-out transmission part is arranged on the opposite side of the non-display region relative to the first fan-out transmission part and comprises a plurality of fan-out lines, wherein the plurality of fan-out lines of the second fan-out transmission part are electrically connected to the even-numbered scan lines respectively. The plurality of scan lines comprise a first scan line group and a second scan line group. The plurality of fan-out lines electrically connected to the first scan line group are formed on the substrate in a first line structure, and the plurality of fan-out lines electrically connected to the second scan line group are formed on the substrate in a second line structure.

In some embodiments of the present application, the plurality of pixel units comprises a first pixel unit, and the first pixel unit comprises a thin film transistor, a third insulating layer, a third metal layer, a fourth insulating layer, a common electrode, and an extended metal layer. The thin film transistor has a first terminal, a second terminal, and a control terminal, wherein the first terminal is electrically connected to a corresponding data line, and the control terminal is electrically connected to a corresponding scan line. The third insulating layer is formed on the substrate. The third metal layer is formed on the third insulating layer and is electrically connected to the second terminal of the thin film transistor. The fourth insulating layer covers the third metal layer. The common electrode has a grid structure and is formed on the fourth insulating layer, wherein the common electrode comprises a first portion and a second portion. The orthographic projection region of the first portion of the common electrode at least partially overlaps with that of the third metal layer, while the orthographic projection region of the second portion of the common electrode substantially does not overlap with that of the third metal layer. The extended metal layer is electrically connected to the third metal layer and is covered by the fourth insulating layer, wherein at least a portion of the extended metal layer is formed within the orthographic projection region of the second portion of the common electrode.

In some embodiments of the present application, the plurality of pixel units comprises a first pixel unit and a second pixel unit. The first pixel unit is electrically connected to the n^{th} scan line, and the second pixel unit is electrically connected to the n+1^{th} scan line, where n is a natural number. The second pixel unit comprises a thin film transistor, a third insulating layer, a third metal layer, a fourth insulating layer, and a common electrode. The thin film transistor has a first terminal, a second terminal, and a control terminal, wherein the first terminal is electrically connected to a corresponding data line, and the control terminal is electrically connected to the n+1^{th} scan line. The third insulating layer is formed on the substrate and covers the n^{th} scan line. The third metal layer is formed on the third insulating layer and is electrically connected to the second terminal of the thin film transistor, wherein the third metal layer comprises a first portion and a second portion. The fourth insulating layer covers the third metal layer. The common electrode has a grid structure and is formed on the fourth insulating layer, and comprises a first portion and a second portion. The orthographic projection region of the first portion of the third metal layer at least partially overlaps with that of the first portion of the common electrode. The orthographic projection regions of the second portion of the third metal layer, the second portion of the common electrode and the n^{th} scan line at least partially overlap.

In some embodiments of the present application, the display panel further comprises a scan driving circuit disposed on the non-display region and comprising a plurality of scan units electrically connected to the plurality of scan lines. Each scan unit comprises at least one holding capacitor, and the structure of the holding capacitor comprises the first metal layer, the first insulating layer, the second metal layer, the second insulating layer, a third conducting layer, and a fourth conducting layer. The third conducting layer and the fourth conducting layer are light-transmitting conducting layers. The third conducting layer is disposed on the second insulating layer, and the fourth conducting layer is disposed on the first insulating layer and is partially covered by the second insulating layer, where one end of the fourth conducting layer is connected to the second metal layer. At least a partial region of the first metal layer is formed with a through hole to expose the at least partial region of the first metal layer from the first insulating layer and the second insulating layer. The third conducting layer is connected to the exposed at least partial region of the first metal layer through the through hole.

In some embodiments of the present application, the display panel further comprises a third metal layer, a plurality of light-emitting elements, a protective layer, and a fourth metal layer. The third metal layer is formed in the display region on the substrate and comprises a plurality of first electrode regions and a plurality of second electrode regions, where the plurality of first electrode regions and the plurality of second electrode regions are electrically independent from each other and alternately arranged at intervals on the substrate. Each light-emitting element comprises a first electrode and a second electrode formed on opposite sides, with the first electrode electrically connected to the corresponding first electrode region. The protective layer is filled between the plurality of light-emitting elements and covers at least a portion of the surface of each light-emitting element. The fourth metal layer is formed on the protective layer and comprises a plurality of third electrode regions, where the plurality of third electrode regions are respectively formed on the plurality of light-emitting elements and electrically connected to the second electrodes of the corresponding light-emitting elements. Each pixel unit comprises a display unit and a touch control sensing unit, where the display unit comprises a corresponding light-emitting element and the first electrode region and third electrode region electrically connected to the corresponding light-emitting element, and the touch control sensing unit comprises a second electrode region and a fourth electrode region adjacent to the display unit.

An embodiment of the present application provides an electrostatic protection structure for a display panel, which comprises a mother substrate and a plurality of display panels. The mother substrate contains a plurality of array blocks. The plurality of display panels are sequentially arranged on the respective array blocks of the mother substrate, wherein each array block comprises a first metal layer, a first insulating layer, a second metal layer, a second insulating layer, and a first conducting layer. The first metal layer is formed on each array block in a manner of surrounding at least two of the plurality of display panels, thereby forming a plurality of first electrostatic discharge lines on each array block. The first insulating layer covers the first metal layer and exposes at least a portion of the first metal layer. The second metal layer is formed on the first insulating layer in a manner of surrounding at least two of the plurality of display panels, thereby forming a plurality of second electrostatic discharge lines corresponding to the plurality of first electrostatic discharge lines on each array block. The second insulating layer covers the second metal layer and exposes at least a portion of the second metal layer. The first conducting layer is formed in a bridge region, wherein at least a portion of the first conducting layer is connected to the first metal layer through the portion exposed by the first insulating layer, and at least another portion of the first conducting layer is connected to the second metal layer through the portion exposed by the second insulating layer, thereby electrically connecting the plurality of first electrostatic discharge lines and the plurality of second electrostatic discharge lines in the bridge region.

An embodiment of the present application provides a display panel, which comprises a substrate, a pixel array, a plurality of scan lines, a first fan-out transmission part, and a second fan-out transmission part. The substrate has a display region and a non-display region. The pixel array is arranged on the display region of the substrate. The plurality of scan lines are sequentially formed on the substrate and electrically connected to the pixel array. The first fan-out transmission part is arranged on one side of the non-display region and has a plurality of fan-out lines, wherein the plurality of fan-out lines of the first fan-out transmission part are electrically connected to the odd-numbered scan lines, respectively. The second fan-out transmission part is arranged on the opposite side of the non-display region relative to the first fan-out transmission part and has a plurality of fan-out lines, wherein the plurality of fan-out lines of the second fan-out transmission part are electrically connected to the even-numbered scan lines, respectively. The plurality of scan lines comprise a first scan line group and a second scan line group. The plurality of fan-out lines electrically connected to the first scan line group are formed on the substrate in a first line structure, and the plurality of fan-out lines electrically connected to the second scan line group are formed on the substrate in a second line structure.

In some embodiments of the present application, the display panel sequentially comprises a first metal layer, a first insulating layer, a second metal layer, and a second insulating layer formed on the substrate. The plurality of scan lines are formed by the first metal layer. The first line structure comprises a single-layer metal line structure formed by the first metal layer, and the second line structure comprises a double-layer metal line structure formed by alternating the first metal layer and the second metal layer.

In some embodiments of the present application, the fan-out line formed by the second metal layer is connected to the corresponding scan line via a bridge architecture.

In some embodiments of the present application, the bridge architecture comprises a first through hole, a second through hole, and a conducting layer. The first through hole is formed on a partial region of the second insulating layer covering the second metal layer. The second through hole is formed on partial regions of the first insulating layer and the second insulating layer covering the first metal layer. The conducting layer covers the second insulating layer, and is connected to the second metal layer through the first through hole and connected to the first metal layer through the second through hole. The first metal layer and the second metal layer are electrically connected via the conducting layer.

The present application provides a display panel comprising a substrate, a pixel array, a plurality of scan lines, and a scan driving circuit. The substrate has a display region and a non-display region. The pixel array is arranged on the display region of the substrate. The plurality of scan lines are sequentially formed on the substrate and electrically connected to the pixel array. The scan driving circuit comprises a plurality of scan units for electrically connecting the plurality of scan lines, wherein each scan unit contains at least one holding capacitor. The structure of the holding capacitor comprises a first metal layer, a second metal layer, a first insulating layer, a second insulating layer, a first light-transmitting conducting layer, and a second light-transmitting conducting layer. The first metal layer is formed on the substrate. The first insulating layer is disposed on the first metal layer. The second metal layer is disposed on the first insulating layer. The first light-transmitting conducting layer is disposed on the first insulating layer, with one end electrically connected to the second metal layer. The second insulating layer is disposed on the second metal layer and the first light-transmitting conducting layer. The second light-transmitting conducting layer is disposed on the second insulating layer. At least a partial region of the first metal layer is formed with a through hole to expose the at least partial region of the first metal layer from the first insulating layer and the second insulating layer. The second light-transmitting conducting layer is electrically connected to the exposed at least partial region of the first metal layer via the through hole.

In some embodiments of the present application, a portion of the second metal layer extends to form on the second light-transmitting conducting layer, such that the second metal layer and the second light-transmitting conducting layer at least partially overlap in the normal direction of the substrate.

In some embodiments of the present application, the holding capacitor is the sum of a first capacitor, a second capacitor, and a third capacitor, wherein the first capacitor is constituted based on a first overlapping region between the first metal layer and the second metal layer and the first insulating layer located in the first overlapping region, the second capacitor is constituted based on a second overlapping region between the second metal layer and the first light-transmitting conducting layer and the second insulating layer located in the second overlapping region, and the third capacitor is constituted based on a third overlapping region between the first light-transmitting conducting layer and the second light-transmitting conducting layer and the second insulating layer located in the third overlapping region.

An embodiment of the present application provides a display panel comprising a substrate, a pixel array, a plurality of scan lines, and a plurality of data lines. The substrate has a display region and a non-display region. The pixel array is disposed on the display region of the substrate and comprises a plurality of pixel units arranged in an array. The plurality of scan lines are formed on the substrate and electrically connected to each row of pixel units in the pixel array. The plurality of data lines are formed on the substrate and electrically connected to each column of pixel units in the pixel array. The plurality of pixel units comprise a first pixel unit, which comprises a thin film transistor, a first insulating layer, a first metal layer, a second insulating layer, a common electrode, and an extended metal layer. The thin film transistor has a first terminal, a second terminal, and a control terminal, wherein the first terminal is electrically connected to a corresponding data line, and the control terminal is electrically connected to a corresponding scan line. The first insulating layer is formed on the substrate. The first metal layer is formed on the first insulating layer and electrically connected to the second terminal of the thin film transistor. The second insulating layer covers the first metal layer. The common electrode has a grid structure and is formed on the second insulating layer, wherein the common electrode comprises a first portion and a second portion, the orthographic projection region of the first portion of the common electrode at least partially overlaps with that of the first metal layer, and the orthographic projection region of the second portion of the common electrode substantially does not overlap with that of the first metal layer. The extended metal layer is electrically connected to the first metal layer and covered by the second insulating layer, wherein at least a portion of the extended metal layer is formed within the orthographic projection region of the second portion of the common electrode.

In some embodiments of the present application, the first pixel unit further comprises a counter substrate, a liquid crystal layer, and a black matrix. The liquid crystal layer is formed between the common electrode and the counter substrate. The black matrix is formed on the side of the counter substrate facing the substrate, wherein at least a portion of the orthographic projection region of the black matrix overlaps with the orthographic projection region of the second portion of the common electrode. The extended metal layer is located within the orthographic projection region of at least the portion of the black matrix.

In some embodiments of the present application, the pixel unit further comprises a second pixel unit, and the second pixel unit comprises an extended metal layer, wherein the extended metal layer of the first pixel unit and the extended metal layer of the second pixel unit are both located within the orthographic projection region of the second portion of the common electrode.

An embodiment of the present application provides a display panel, comprising a substrate, a pixel array, a plurality of scan lines, and a plurality of data lines. The substrate has a display region and a non-display region. The pixel array is disposed on the display region of the substrate and comprises a plurality of pixel units arranged in an array. The plurality of scan lines are formed on the substrate and electrically connected to each row of pixel units in the pixel array. The plurality of data lines are formed on the substrate and electrically connected to each column of pixel units in the pixel array. The plurality of pixel units comprise a first pixel unit and a second pixel unit. The first pixel unit is electrically connected to a n^{th} scan line, and the second pixel unit is electrically connected to a (n+1)^{th} scan line, where n is a natural number. The second pixel unit comprises a thin film transistor, a first insulating layer, a first metal layer, and a common electrode. The thin film transistor has a first terminal, a second terminal, and a control terminal, wherein the first terminal is electrically connected to a corresponding data line, and the control terminal is electrically connected to the (n+1)^{th} scan line. The first insulating layer is formed on the substrate and covers the n^{th} scan line. The first metal layer is formed on the first insulating layer and electrically connected to the second terminal of the thin film transistor, wherein the first metal layer has a first portion and a second portion. The common electrode has a grid structure and is formed on the second insulating layer, wherein the common electrode has a first portion and a second portion. The orthographic projection region of the first portion of the first metal layer at least partially overlaps with the orthographic projection region of the first portion of the common electrode, and the orthographic projection regions of the second portion of the first metal layer, the second portion of the common electrode and the n^{th} scan line at least partially overlap.

In some embodiments of the present application, the n^{th} scan line located between two adjacent rows of pixel units comprises a first line segment and a second line segment connected to each other, wherein the first line segment and the second line segment are not parallel to each other.

In some embodiments of the present application, the overlapping area between the orthographic projection regions of the second portion of the first metal layer and the first line segment of the n^{th} scan line is substantially the same as the overlapping area between the orthographic projection regions of the second portion of the first metal layer and the second line segment.

In some embodiments of the present application, the overlapping area between the orthographic projection regions of the second portion of the first metal layer and one of the first line segment and the second line segment of the n^{th} scan line is greater than the overlapping area between the orthographic projection regions of the second portion of the first metal layer and the other one of the first line segment and the second line segment.

An embodiment of the present application proposes an electrostatic protection structure for an array substrate, comprising a glass substrate and a plurality of display panels. The plurality of display panels are adjacently arranged on the glass substrate, wherein the common electrode of each display panel is connected to the common electrode of an adjacent display panel.

In some embodiments of the present application, the display panels are all arranged in the same direction.

In some embodiments of the present application, adjacent two rows or two columns of the display panels are arranged in opposite directions based on a virtual symmetric line.

In some embodiments of the present application, the common electrode of each display panel is connected to the common electrode of an adjacent display panel via at least one circuit.

An embodiment of the present application provides an electrostatic protection structure for an array substrate, characterized by comprising: a glass substrate divided into a plurality of array blocks; and a plurality of display panels adjacently arranged on each array block of the glass substrate. Each of the array blocks comprises: at least one first metal layer configured on the glass substrate to surround at least two of the plurality of display panels; a first insulating layer covering the first metal layer and exposing at least a portion of the first metal layer; at least one second metal layer configured on the first insulating layer in a manner of surrounding at least two of the plurality of display panels; a second insulating layer covering the second metal layer and exposing at least a portion of the second metal layer; and a plurality of conducting layers electrically connecting the first metal layer and the second metal layer by penetrating through the first insulating layer and the second insulating layer at least in a plurality of bridge regions of the first metal layer.

In some embodiments of the present application, when there are a plurality of first metal layers, the bridge region is at least located at the turning points of the first metal layers.

In some embodiments of the present application, when there are a plurality of first metal layers, the first insulating layer separates the plurality of first metal layers.

In some embodiments of the present application, when there are a plurality of second metal layers, the second insulating layer separates the plurality of second metal layers.

In some embodiments of the present application, in a top view, the spacing from the side of the first metal layer near the second metal layer electrically connected through the conducting layer to the side of the second metal layer away from the first metal layer electrically connected through the conducting layer is 200-300 μm.

In some embodiments of the present application, in a top view, the spacing between the parallel sides of the first metal layer electrically connected through the conducting layer is 150-300 μm.

An embodiment of the present application further provides an electrostatic protection structure, comprising: a glass substrate divided into a plurality of array blocks; and a plurality of display panels adjacently arranged in each of the array blocks of the glass substrate. Each of the array blocks respectively comprises: a plurality of metal layers sequentially stacked on the glass substrate in a manner of surrounding at least two of the plurality of display panels; a plurality of insulating layers separating the plurality of metal layers and exposing at least a portion of the plurality of metal layers; and a plurality of conducting layers electrically connecting the stacked a plurality of metal layers by penetrating the plurality of insulating layers at least in a plurality of bridge regions of the plurality of metal layers.

An embodiment of the present application provides a pixel array substrate, comprising a substrate, a pixel array, and an electrostatic protection structure. The substrate has a display region and a non-display region. The pixel array is disposed in the display region of the substrate. The electrostatic protection structure is disposed in the non-display region of the substrate and surrounds at least a portion of the bezel area of the substrate, wherein the electrostatic protection structure has a plurality of sequentially spaced light-transmitting parts, and the light-transmitting parts are at least formed by stacking an insulating layer and a transparent conducting layer.

An embodiment of the present application provides an electrostatic protection structure suitable for placement in a non-display region of a pixel array substrate of a display panel. The electrostatic protection structure comprises a plurality of metal stripe patterns. The plurality of metal stripe patterns are respectively disposed in a plurality of bezel areas of the non-display region, wherein each metal stripe pattern has a plurality of sequentially spaced light-transmitting parts, and the light-transmitting parts are at least formed by stacking an insulating layer and a transparent conducting layer.

An embodiment of the present application provides a display device, comprising a display panel, a display driver chip, and a touch control sensing chip. The cross-sectional structure of the display panel along a cutting line direction further comprises a substrate, a first metal layer, a plurality of light-emitting elements, a protective layer, and a second metal layer. The first metal layer is formed on the substrate and comprises a plurality of first electrode regions and a plurality of second electrode regions, wherein the plurality of first electrode regions and the plurality of second electrode regions are electrically independent from each other and alternately arranged at intervals on the substrate. Each of the light-emitting elements comprises a first electrode and a second electrode formed on opposite sides, with the first electrode electrically connected to the corresponding first electrode region. The protective layer is filled between the plurality of light-emitting elements and covers at least a portion of the surface of each light-emitting element. The second metal layer is formed on the protective layer and comprises a plurality of third electrode regions, wherein the plurality of third electrode regions are respectively formed on the plurality of light-emitting elements and electrically connected to the second electrode of the corresponding light-emitting element. The orthographic projection regions of the plurality of third electrode regions on the substrate do not completely overlap with the orthographic projection regions of the plurality of second electrode regions on the substrate.

An embodiment of the present application provides a display panel, comprising a substrate, a first metal layer, a plurality of light-emitting elements, a protective layer, and a second metal layer. The first metal layer is formed on the substrate and comprises a plurality of first electrode regions and a plurality of second electrode regions, wherein the plurality of first electrode regions and the plurality of second electrode regions are electrically independent from each other and alternately arranged at intervals on the substrate. Each of the light-emitting elements comprises a first electrode and a second electrode formed on opposite sides, with the first electrode electrically connected to the corresponding first electrode region. The protective layer is filled between the plurality of light-emitting elements and covers at least a portion of the surface of each light-emitting element. The second metal layer is formed on the protective layer and comprises a plurality of third electrode regions, wherein the plurality of third electrode regions are respectively formed on the plurality of light-emitting elements and electrically connected to the second electrode of the corresponding light-emitting element. The orthographic projection regions of the plurality of third electrode regions on the substrate do not overlap at all with the orthographic projection regions of the plurality of second electrode regions on the substrate.

In some embodiments, the second metal layer further comprises a plurality of fourth electrode regions, wherein the plurality of third electrode regions and the plurality of fourth electrode regions are electrically independent from each other, and the plurality of fourth electrode regions are respectively electrically connected to the corresponding a plurality of second electrode regions.

An embodiment of the present application provides a display panel, which comprises the aforementioned pixel array substrate or electrostatic protection structure.

Through one or more technical solutions described in the present application, the display panel and its pixel array proposed in the embodiments of the present application expand the equivalent area of the pixel electrode by forming an additional extended metal layer. Since the extended metal layer is formed under the region covered by the common electrode and black matrix, it can increase the pixel storage capacitance while maintaining the aperture ratio/transmittance of the display panel.

In addition, through one or more technical solutions described in the present application, the electrostatic protection structure of the array substrate and the liquid crystal display panel proposed in the embodiments of the present application can connect the capacitances of a plurality of display panels on the array substrate in series, thereby forming a larger capacitance to help absorb static electricity generated during the process. This prevents the glass substrate of the array substrate from easily experiencing electrostatic discharge (ESD damage), avoiding high temperatures that could cause electrostatic damage to the metal lines in the TFT array substrate. It also prevents indium tin oxide (ITO) electrodes from becoming opaque, reduces defects in the insulating layer, and ensures accurate voltage settings between electrodes. Furthermore, the embodiments of the present application can effectively prevent structural damage to the array substrate. Moreover, regardless of how a plurality of display panels are arranged on the glass substrate of the array substrate, the embodiments of the present application remain applicable.

Additionally, through one or more technical solutions described in the present application, the electrostatic protection structure of the array substrate proposed in the embodiments of the present application can achieve electrostatic protection even when small-sized display panels are configured on the array substrate without test circuit lines. Moreover, since the first metal layer and the second metal layer form a double-layer structure, the horizontal area occupied on the array substrate can be reduced, thereby increasing the number of display panels that can be configured on the array substrate. Furthermore, the double-layer structure of the first metal layer and the second metal layer reduces the overall impedance of the array substrate, making it easier to achieve the effects of absorbing and dissipating static electricity.

In addition, through one or more technical solutions described in the present application, the electrostatic protection structure of the pixel array substrate proposed in the embodiments of the present application features a design with a plurality of light-transmitting parts. This reduces large-area metal shielding, allowing UV light to pass through the light-transmitting parts and reach the sealant FP coating region during the display panel's bezel lamination process. As a result, the UV light can better irradiate the sealant, thereby improving its curing rate and further enhancing the yield and reliability of panel assembly. Furthermore, since the light-transmitting parts of the electrostatic protection structure are formed from transparent conductive materials, they do not reduce the equivalent area of the metal stripe pattern. Thus, the electrostatic dissipation capability of the electrostatic protection structure is maintained and not compromised by the presence of the light-transmitting parts.

On the other hand, compared to traditional electrostatic discharge ring designs, the electrostatic protection structure proposed in the embodiments of the present application, which features an inner ring structure and an outer ring structure, has a greater width in the cross-sectional direction. This increases the effective conductive region of the electrostatic protection structure, thereby further enhancing its electrostatic dissipation capability.

Additionally, through one or more technical solutions described in the embodiments of the present application, the proposed display device and display panel can form independent electrodes within the display panel for touch sensing. This allows the signal timing during display and touch sensing periods to operate independently, avoiding the need for trade-offs.

Furthermore, through one or more technical solutions described in the embodiments of the present application, the proposed display device and display panel can maintain the upper surfaces of all light-emitting elements at essentially the same level without height variations. As a result, subsequent processes are unaffected by the flatness of the display panel, effectively improving process yield and reliability.

### BRIEF DESCRIPTION OF DRAWINGS

FIG. 1 is a schematic configuration diagram of the display device according to an embodiment of the present application;

FIGS. 2A and 2B are schematic diagrams of component configurations for the display device and its display panel in some embodiments of the present application;

FIGS. 3A and 3B are schematic diagrams of the scan driving circuit in some embodiments of the present application;

FIGS. 4A to 6B are circuit schematic diagrams of the scan driving circuit in different embodiments of the present application;

FIGS. 7A to 8B are schematic diagrams of the structural configuration of the holding capacitor in the scan driving circuit for different embodiments of the present application;

FIGS. 9A to 12 are schematic diagrams of the configuration of the display panel and its fan-out lines in different embodiments of the present application;

FIG. 13 is an equivalent circuit schematic of the pixel array in an embodiment of the present application;

FIGS. 14A to 18C are schematic diagrams of the structural configuration of the pixel array in different embodiments of the present application;

FIG. 19 is a voltage-current relationship diagram of the thin film transistor in a pixel unit for some embodiments of the present application;

FIG. 20 is a schematic configuration diagram of the array substrate in some embodiments of the present application;

FIG. 21 is a schematic diagram of the configuration of adjacent display panels on the array substrate in some embodiments of the present application;

FIGS. 22A and 22B are schematic diagrams of the display panel configuration on the array substrate in the present application;

FIGS. 23A to 24B are schematic diagrams of electrostatic protection structures configured within array blocks of array substrates in different embodiments of the present application;

FIGS. 25A and 25B are schematic diagrams of configurations of pixel array substrates in different embodiments of the present application;

FIGS. 26A and 26B are schematic diagrams of a pixel array substrate and its electrostatic protection structure from different perspectives in embodiments of the present application;

FIGS. 27A to 27C are top and cross-sectional schematic diagrams of a display panel;

FIGS. 28A to 30G are top and cross-sectional schematic diagrams of display panels in different embodiments of the present application; and

FIG. 31 is a schematic diagram of signal waveforms of a display device in some embodiments of the present application.

### DESCRIPTION OF EMBODIMENTS

To make the objectives, features, and advantages of the technical solution more apparent and easier to understand, detailed descriptions of specific embodiments of the proposed technical solution are provided below with reference to the accompanying drawings. The descriptions of various embodiments of the technical solution of the present invention are for illustrative purposes only and do not represent all embodiments of the invention or limit the invention to specific embodiments. Based on the embodiments in the present application, all other embodiments obtained by those of ordinary skill in the art without creative effort shall fall within the scope of protection of this disclosure.

It should be noted that the terms “vertical,” “left,” “right,” “up,” “down,” and similar expressions used herein are only intended to indicate relative positional relationships based on the drawings and do not limit the components described by these terms to be implemented only in the manner shown. When the absolute position of the described object changes, the description of the relative position may also change accordingly.

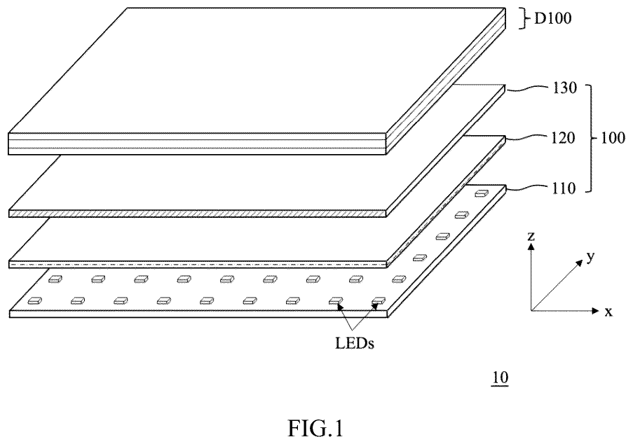

FIG. 1 is a schematic diagram of the configuration of a display device in an embodiment of the present application. Referring first to FIG. 1, the display device 10 in this embodiment may be, for example, a liquid crystal display device (LCD device), which includes a backlight module 100 and a display panel D100. The backlight module 100 and the display panel D100 are arranged on the x-y plane, with the display panel D100 positioned along the z-axis on the backlight module 100. The backlight module 100 is used to provide sufficient brightness and uniformly distributed light toward the display panel D100. The display panel D100 is used to adjust and control the passing light to display corresponding images. In this embodiment, the display device 10 can be any electronic device with display functionality, such as a television, screen, laptop, or mobile phone, and the present application is not limited thereto.

The backlight module 100 includes a light-emitting layer 110, which includes an array of a plurality of light-emitting components LEDs. The light-emitting components LEDs can emit light toward the display panel D100. In some embodiments, the light-emitting components LEDs may be white, red, green, or blue light-emitting diodes (or diodes emitting light in the wavelength ranges of white, red, green, or blue light), or combinations thereof, and the present application is not limited thereto.

Furthermore, in some embodiments, the backlight module 100 may further include a quantum dot film 120 and an optical adjustment layer 130, wherein the quantum dot film 120 is disposed on the light-emitting layer 110, and the optical adjustment layer 130 is disposed on the quantum dot film 120, meaning the quantum dot film 120 is positioned between the light-emitting layer 110 and the optical adjustment layer 130. In embodiments where the quantum dot film 120 is provided, the light-emitting components LEDs may, for example, be blue light-emitting diodes.

The quantum dot film 120 is located on the light transmission path of the light-emitting layer 110 and is used to adjust the wavelength of a portion of the light emitted by the light-emitting components LEDs, while allowing another portion of the light emitted by the LEDs to pass through unadjusted. For instance, when the light-emitting components LEDs emit light within the blue wavelength range (e.g., 400 nm-520 nm), the quantum dot film 120 can adjust the wavelength of the received first portion of light to the red wavelength range (e.g. 610 nm-720 nm), adjust the wavelength of the received second portion of light to the green wavelength range (e.g., 520 nm-610 nm), and maintain the received third portion of light unadjusted, directly outputting it within the blue wavelength range. Thus, the first to third portions of light emitted by the light-emitting layer 110 can mix to form white light after passing through the quantum dot film 120.

The optical adjustment layer 130 is also located on the light transmission path of the light-emitting layer 110 and is used to adjust the direction of the received light, making the transmitted light source more uniform. In some embodiments, the optical adjustment layer 130 includes a plurality of optical microstructures (not shown) and/or optical films (not shown) for adjusting the light direction, but the application is not limited thereto.

The display panel D100 includes, for example, a pixel array, a counter substrate, and a non-self-emissive display medium, wherein the pixel array and the counter substrate are arranged opposite each other, and the non-self-emissive display medium is disposed between the pixel array and the counter substrate. In some embodiments, the non-self-emissive display medium may, for example, be liquid crystal, but the application is not limited thereto. Specific configuration embodiments of the pixel array will be further explained later.

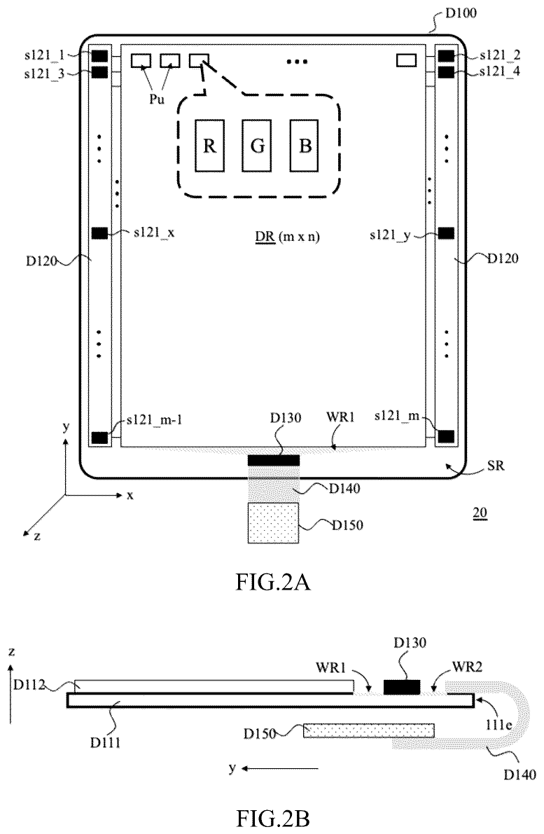

From the perspective of circuit configuration and display driving, in some embodiments, the configuration of the display device 20 and its display panel D100 can be as shown in FIGS. 2A and 2B, where FIG. 2A is a top-view schematic of the display device 20, and FIG. 2B is a side-view schematic of the display device 20. For clarity, FIG. 2A illustrates the internal components of the display device 20 unfolded on the x-y plane, while FIG. 2B depicts the arrangement of these internal components within the housing. From a packaging perspective, this embodiment involves a display device utilizing GOP packaging technology.

Referring to FIGS. 2A and 2B, in this embodiment, the display device 20 includes not only the aforementioned backlight module and display panel D100 but also a scan driving circuit D120, a data driving circuit D130, a connection module D140, and a control circuit D150 for driving the display panel D100. The display panel D100 has a display region DR and a non-display region SR, where the display region DR is the region for displaying images, and the non-display region SR is the region of the display panel D100 that does not display images. The non-display region SR typically surrounds the display region DR and can also be regarded as the bezel area of the display panel D100. The scan driving circuit D120 and data driving circuit D130 are located in the non-display region SR of the display panel D100. In the illustration, the scan driving circuit D120 is placed in the non-display region SR on both the left and right sides of the display panel D100, while the data driving circuit D130 is placed in the non-display region SR on the lower side of the display panel D100, though the present application is not limited thereto arrangement. One end of the connection module D140 is positioned on the side of the non-display region SR near the data driving circuit D130, and the control circuit D150 is coupled to the other end of the connection module D140.

Specifically, the display panel D100 may include a substrate D111 and a pixel array D112 located in the display region DR. The pixel array D112 is arranged on the substrate D111 and, for example, consists of pixel units Pu arranged in an array of m×n, i.e., m rows and n columns, where m and n can be natural numbers selected according to design requirements, with no limitation imposed by the present application.

From the perspective of electrical relationships between components, the scan driving circuit D120 is electrically connected to the display panel D100 through lines on the substrate D111. The data driving circuit D130 is electrically connected to the display panel D100 via the first transmission section WR1 and is also electrically connected to the connection module D140 through the second transmission section WR2. On the other hand, the control circuit D150 is electrically connected to the data driving circuit D130 via the connection module D140 and the second transmission section WR2. Here, the first transmission section WR1 and the second transmission section WR2 may be transmission lines formed on the substrate D111.

The scan driving circuit D120 is used to generate scan signals that sequentially enable/activate pixels row by row based on timing control signals. In this embodiment, the scan driving circuit D120 is illustrated as two configurations for enabling odd-row pixels and even-row pixels, respectively. For example, the left scan driving circuit D120 includes scan units s121_1, s121_3, . . . , s121_m−1 connected to odd-numbered scan lines, while the right scan driving circuit D120 includes scan units s121_2, s121_4, . . . , s121_m connected to even-numbered scan lines, though the present application is not limited thereto. In this embodiment, the scan unit s121_x represents any one of the left scan units s121_1, s121_3, . . . , s121_m−1, and the scan unit s121_y represents any one of the right scan units s121_2, s121_4, . . . , s121_m. In other words, x can be any odd number less than m, and y can be any even number less than or equal to m, where m is even, but the present application is not limited thereto.

The data driving circuit D130 is used to generate driving signals for the pixel array D112 based on data control signals. Although the diagram of this embodiment illustrates a single data driving circuit D130 for simplicity, the present application is not limited thereto. In some embodiments, the data driving circuit D130 may be integrated as a plurality of driver chips, which can collaboratively drive pixels in different sections/regions of the pixel array D112.

More specifically, pixels in the same row of the pixel array D112 correspond to the same scan line, and pixels in the same column of the pixel array D112 correspond to the same data line. The pixel array D112 can be electrically connected to the scan driving circuit D120 via scan lines to receive scan signals and to the data driving circuit D130 via data lines and the first transmission section WR1 to receive data driving signals provided by the data driving circuit D130. The data driving circuit D130 supplies data driving signals in coordination with the activation timing of the pixel array D112, enabling the pixel array D112 to adjust transmitted light based on the data driving signals, thereby displaying corresponding images in the display region DR.

The connection module D140 is used to provide a signal transmission path between the data driving circuit D130 and the control circuit D150, enabling the data control signals generated by the control circuit D150 to be transmitted to the data driving circuit D130 via the connection module D140 and the second transmission portion WR2. In some embodiments, the connection module D140 may be a bendable flexible circuit board (hereinafter referred to as the flexible circuit board D140). As shown in FIG. 1C, both ends of the flexible circuit board D140 are equipped with a plurality of connection terminals. The connection terminals on the side of the flexible circuit board D140 near the data driving circuit D130 are arranged on the substrate D111, while those near the control circuit D150 are placed on the circuit board of the control circuit D150. The portion of the flexible circuit board D140 near the data driving circuit D130, where the connection terminals are located, is attached to the substrate D111. The width of the attached portion is approximately the distance from the top of the connection terminals of the flexible circuit board 140 to the edge 111e of the substrate.

During the assembly of the display device 20, the flexible circuit board D140 is bent to position the control circuit D150 on the backside of the display panel D100 (i.e., the side of the substrate D111 opposite to the display region DR). In other words, in the assembled state of the display device 20, the control circuit D150, the substrate D111, and the data driving circuit D130 inside the display device 20 are sequentially arranged along the z axis.

The pixel array D112 in the display panel D100 includes a plurality of thin film transistors (not shown). These thin film transistors turn on or off in response to received signals, thereby controlling the operation of corresponding pixels to adjust the transmitted light based on the data driving signals, achieving the effect of displaying corresponding images in the display region DR. From another perspective, the display panel D100 also includes a common electrode (not shown). The display region DR can be regarded as the region where the common electrode overlaps with the pixel array D112, while (at least a portion of) the non-display region SR can be considered the region where the common electrode does not overlap with the pixel array D112.

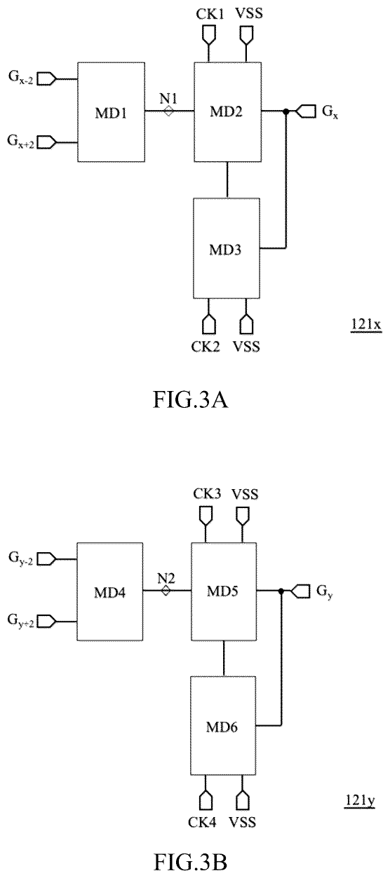

The functional module configuration of each scan unit s121_1-s121_m in the scan driving circuit D120 described in this embodiment can be as shown in FIGS. 3A and 3B. FIG. 3A illustrates the circuit schematic of a scan unit s121_x connected to an odd-numbered scan line (i.e., x can be any odd number between 1 and m, such as s121_1, s121_3, . . . s121_m−1), while FIG. 3B shows the circuit schematic of a scan unit s121_y connected to an even-numbered scan line (i.e., x can be any even number between 1 and m, such as s121_2, s121_4, . . . s121_m).

Please first refer to FIG. 3A. In this embodiment, the scanning unit 121x includes a first module MD1, a second module MD2, and a third module MD3. The first module MD1 is electrically connected to the scan output terminals Gₓ₋₂ of the preceding two-stage scanning units and the scan output terminals Gₓ₊₂ of the subsequent two-stage scanning units, and generates a drive signal at node N1 based on the scan signals from the scan output terminals Gₓ₋₂ and Gₓ₊₂. The second module MD2 is electrically connected to the first module MD1 via node N1 and determines the pull-up timing of the scan signal output from the scan output terminal Gₓ based on the drive signal at node N1, the clock signal CK1, and the reference signal VSS. The third module MD3 is electrically connected to the second module MD2 and the scan output terminal Gₓ, and determines the pull-down timing of the scan signal output from the scan output terminal Gₓ based on the clock signal CK2 and the reference signal VSS.

Next, please refer to FIG. 3B. In this embodiment, the scanning unit 121y includes a fourth module MD4, a fifth module MD5, and a sixth module MD6, where the connection relationships and relative configurations of the fourth to sixth modules MD4-MD6 may be similar to those of the first to third modules MD1-MD3 in the aforementioned embodiment, respectively. The only difference between them may lie in the timing of the received clock signals CK3 and CK4.

In some embodiments, the clock signals CK1 and CK2 are inverted relative to each other, and the clock signals CK3 and CK4 are also inverted relative to each other. In some embodiments, the phase of clock signal CK3 is approximately 90 degrees behind that of clock signal CK1, the phase of clock signal CK2 is approximately 90 degrees behind that of clock signal CK3, and the phase of clock signal CK4 is approximately 90 degrees behind that of clock signal CK2.

In addition, for relevant descriptions of the fourth to sixth modules MD4-MD6 of the scanning unit 121y, please refer to the aforementioned descriptions of the first to third modules MD1-MD3, which will not be repeated here.

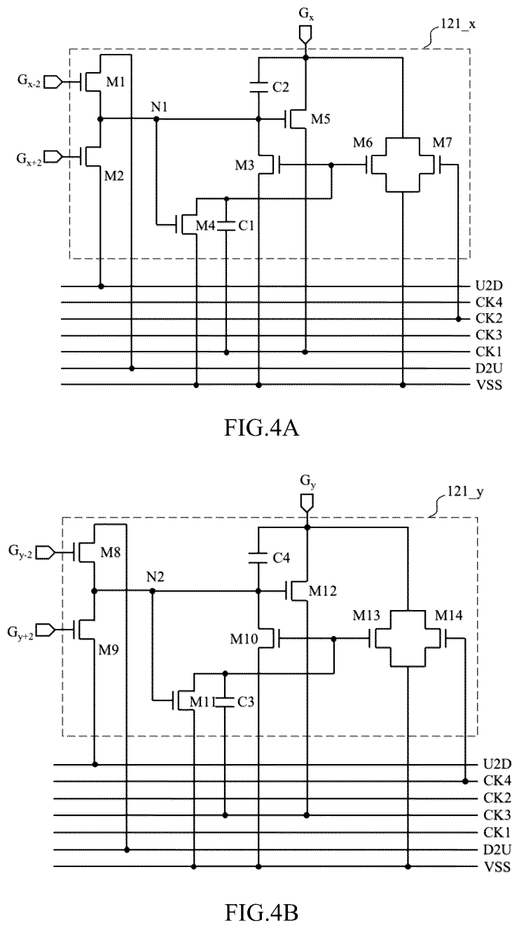

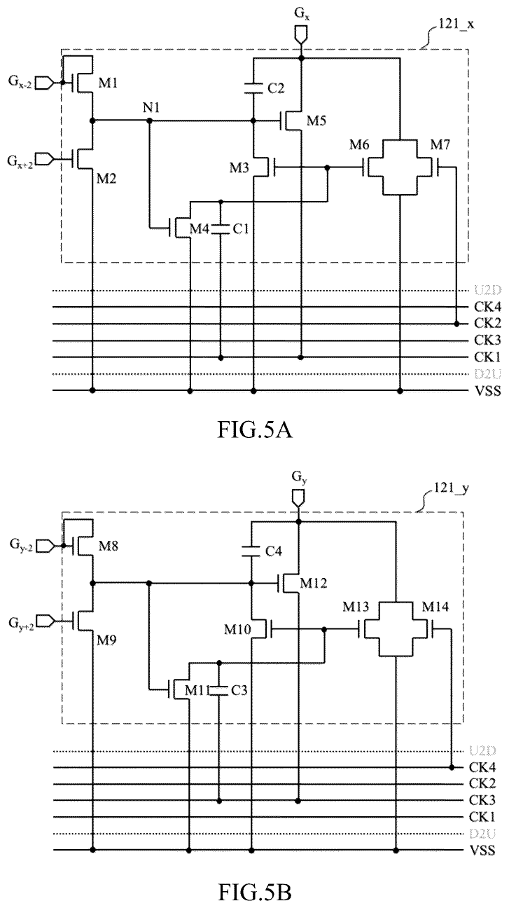

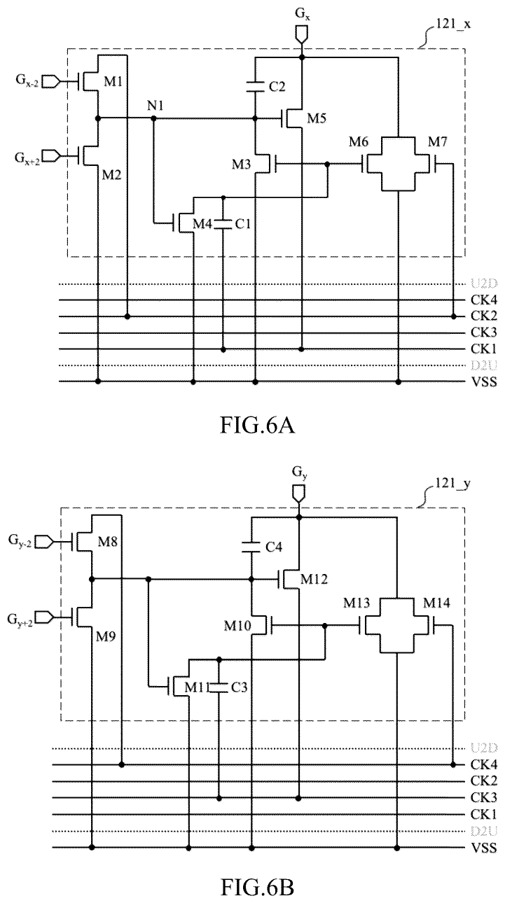

The specific circuit configuration embodiments of the aforementioned scan driving circuit D120 are further illustrated below with reference to FIGS. 4A to 6B. FIGS. 4A and 4B depict a circuit configuration embodiment of scan units 121_x and 121_y, FIGS. 5A and 5B depict another circuit configuration embodiment of scan units 121_x and 121_y, and FIGS. 6A and 6B depict yet another circuit configuration embodiment of scan units 121_x and 121_y.

Please first refer to FIG. 4A. The scan unit 121_x in this embodiment includes transistors M1-M7 and capacitors C1 and C2. Here, transistors M1 and M2 can form the first module MD1 as described in FIG. 3A, transistors M3-M5 along with capacitors C1 and C2 can form the second module MD2 as described in FIG. 3A, and transistors M6 and M7 can form the third module MD3 as described in FIG. 3A. In other words, the first module MD1 in FIG. 3A may include, for example, transistors M1 and M2, the second module MD2 may include, for example, transistors M3-M5 and capacitors C1 and C2, and the third module MD3 may include, for example, transistors M6 and M7. However, the present application is not limited thereto.

In this embodiment, transistors M1-M7 each have a first terminal, a second terminal, and a control terminal, and the transistor M1-M7 may, for example, be a N-type transistor or a P-type transistor, though the present application is not limited thereto. If the transistor is a N-type transistor, the first terminal may, for example, be the drain, the second terminal may be the source, and the control terminal may be the gate. If the transistor is a P-type transistor, the first terminal may, for example, be the source, the second terminal may be the drain, and the control terminal may be the gate.

The first terminal of transistor M1 is used to receive the first scan control signal D2U, the second terminal of transistor M1 is electrically connected to node N1, and the control terminal of transistor M1 is used to receive the scan output terminals Gₓ₋₂ of the scan units in the previous two stages. The first terminal of transistor M2 is electrically connected to the second terminal of transistor M1, the second terminal of transistor M2 is used to receive the second scan control signal U2D, and the control terminal of transistor M2 is used to receive the scan output terminals Gₓ₊₂ of the scan units in the subsequent two stages.

The first terminal of transistor M3 is electrically connected to the second terminal of transistor M1 and the first terminal of transistor M2 via node N1, and the second terminal of transistor M3 is configured to receive the clock signal CK1. The first terminal of transistor M4 is electrically connected to the control terminal of transistor M3, the second terminal of transistor M4 is configured to receive the reference signal VSS, and the control terminal of transistor M4 is electrically connected to node N1. In this embodiment, the reference signal VSS is exemplified as a reference low level. The first terminal of transistor M5 is electrically connected to the scan output terminal Gₓ of scan unit 121_x, the second terminal of transistor M5 is configured to receive the clock signal CK1, and the control terminal of transistor M5 is electrically connected to the first terminal of transistor M3 and node N1. The first terminal of capacitor C1 is electrically connected to the control terminal of transistor M3 and the first terminal of transistor M4, and the second terminal of capacitor C1 is configured to receive the clock signal CK1. The first terminal of capacitor C2 is electrically connected to the first terminal of transistor M5 and the scan output terminal Gₓ, and the second terminal of capacitor C2 is electrically connected to the first terminal of transistor M3, the control terminal of transistor M5, and node N1.

The first terminal of transistor M6 is electrically connected to the scan output terminal Gₓ, the second terminal of transistor M6 is configured to receive the reference signal VSS, and the control terminal of transistor M6 is electrically connected to the control terminal of transistor M3, the first terminal of transistor M4, and the first terminal of capacitor C1. The first terminal of transistor M7 is electrically connected to the first terminal of transistor M6 and the scan output terminal Gₓ, the second terminal of transistor M7 is configured to receive the reference signal VSS, and the control terminal of transistor M7 is configured to receive the clock signal CK2.

Please refer to FIG. 4B. The scan unit 121_y in this embodiment includes transistors M8-M14 and capacitors C3 and C4, wherein transistors M8 and M9 may form the fourth module MD5 as described in FIG. 3B, transistors M10-M12 and capacitors C3 and C4 may form the fifth module MD5 as described in FIG. 3B, and transistors M13 and M14 may form the sixth module MD6 as described in FIG. 3B. In other words, the fourth module MD4 in FIG. 3B may, for example, include transistors M8 and M9, the fifth module MD5 may, for example, include transistors M10-M12 and capacitors C3 and C4, and the sixth module MD6 may, for example, include transistors M13 and M14. However, the present application is not limited thereto.

In this embodiment, transistors M8-M14 each have a first terminal, a second terminal, and a control terminal, and the transistors M8-M14 may, for example, be N-type transistors or P-type transistors, though the application is not limited thereto. If the transistor is a N-type transistor, the first terminal may, for example, be a drain, the second terminal may, for example, be a source, and the control terminal may, for example, be a gate; if the transistor is a P-type transistor, the first terminal may, for example, be a source, the second terminal may, for example, be a drain, and the control terminal may, for example, be a gate.

The first terminal of transistor M8 is configured to receive a first scan control signal D2U, the second terminal of transistor M1 is electrically connected to node N2, and the control terminal of transistor M8 is configured to receive the scan output terminals G_{y-2} of the scan units from the previous two stages. The first terminal of transistor M9 is electrically connected to the second terminal of transistor M8, the second terminal of transistor M9 is configured to receive a second scan control signal U2D, and the control terminal of transistor M9 is configured to receive the scan output terminals G_{y+2} of the scan units from the subsequent two stages.

The first terminal of transistor M10 is electrically connected via node N2 to the second terminal of transistor M8 and the first terminal of transistor M9, and the second terminal of transistor M10 is configured to receive a clock signal CK3. The first terminal of transistor M11 is electrically connected to the control terminal of transistor M10, the second terminal of transistor M11 is configured to receive a reference signal VSS, and the control terminal of transistor M11 is electrically connected to node N2. In this embodiment, the reference signal VSS is exemplified as a reference low level. The first terminal of transistor M12 is electrically connected to the scan output terminal G_{y} of scan unit 121_y, the second terminal of transistor M12 is configured to receive the clock signal CK3, and the control terminal of transistor M12 is electrically connected to the first terminal of transistor M10 and node N2. The first terminal of capacitor C3 is electrically connected to the control terminal of transistor M10 and the first terminal of transistor M11, and the second terminal of capacitor C3 is configured to receive clock signal CK3. The first terminal of capacitor C4 is electrically connected to the first terminal of transistor M12 and scan output terminal G_{y}, and the second terminal of capacito C4 is electrically connected to the first terminal of transistor M10, the control terminal of transistor M12, and node N2.

The first terminal of transistor M13 is electrically connected to the scan output terminal G_{y}, the second terminal of transistor M13 is configured to receive the reference signal VSS, and the control terminal of transistor M13 is electrically connected to the control terminal of transistor M10, the first terminal of transistor M11, and the first terminal of capacitor C3. The first terminal of transistor M14 is electrically connected to the first terminal of transistor M13 and the scan output terminal G_{y}, the second terminal of transistor M14 is configured to receive the reference signal VSS, and the control terminal of transistor M14 is configured to receive the clock signal CK4.

In other words, the configuration of transistors M8-M14 in this embodiment is similar to that of transistors M1-M7 in the aforementioned FIG. 4A embodiment, and the configuration of capacitors C3 and C4 is similar to that of capacitors C1 and C2 in the aforementioned embodiment in FIG. 4A. The difference between this embodiment and the aforementioned embodiment in FIG. 4A lies in that transistors M10-M12 primarily operate based on the clock signal CK3, while transistor M14 operates based on the clock signal CK4. In the above embodiments, capacitors C1-C4 may also be referred to as holding capacitors, which can stabilize the voltage at the connected nodes. Structurally, the holding capacitors can be formed through the arrangement between the metal layer and insulating layer on the display panel. This will be further explained in subsequent embodiments.

Under the driving architecture of FIGS. 4A and 4B above, a DC voltage is required to control the operation of the transistors. However, applying a DC voltage to the transistors for an extended period can easily cause a shift in their characteristics, leading to display abnormalities in the display panel during prolonged use or aging tests. For example, as seen in FIGS. 4A and 4B, transistor M1/M8 continuously receives a DC voltage from the first scan control signal D2U during operation. Over time, the current-voltage characteristic curve (I-V curve) of transistor M1/M8 gradually shifts to the right, causing the leakage current of transistor M1/M8 to increase gradually, which eventually results in display abnormalities.

Additionally, with the configurations in FIGS. 4A and 4B, the display panel must be equipped with at least 7 signal lines to provide the control signals and clock signals (such as U2D, D2U, CK1-CK4, VSS, etc.) required for the operation of scan units 121_x/121_y. This limits the size of the non-display region of the display panel, making it difficult to achieve a narrow bezel design.

The driving architecture illustrated in FIGS. 5A to 6B can address the issues of the aforementioned embodiments, effectively improve the quality of the display panel, extend the lifespan of the display panel, and further achieve a narrow bezel design.

Referring to FIGS. 5A and 5B, the configuration of transistors M1-M7 is similar to that of transistors M1-M7 in the embodiment of FIG. 4A, and the configuration of capacitors C1 and C2 is similar to that of capacitors C1 and C2 in the embodiment of FIG. 4A; transistors M8-M14, and the configuration of capacitors C3 and C4 is similar to that of capacitors C3 and C4 in the embodiment of FIG. 4B.

The main difference between this embodiment and the embodiments of FIGS. 4A and 4B lies in that the first terminal of transistor M1/M8 is electrically connected to its control terminal, thereby utilizing the scan signal from the scan output terminals Gₓ₋₂/G_{y-2} of the previous two stages to replace the original first scan control signal Gₓ₋₂/G_{y-2}. Additionally, the second terminal of transistor M2/M9 is electrically connected to a signal line carrying the reference signal VSS, thereby using the reference signal VSS to replace the original second scan control signal U2D.

From another perspective, transistor M1 is equivalently formed as a diode element through the connection configuration shown in FIG. 5A. Therefore, when the control terminal of transistor M1 is applied with an enable-level (e.g., high-level) scan signal, transistor M1 can directly transmit the enable level to its second terminal. Similarly, transistor M8 is equivalently formed as a diode element through the connection configuration shown in FIG. 5B. Thus, when the control terminal of transistor M8 is applied with an enable-level (e.g., high-level) scan signal, transistor M8 can directly transmit the enable level to its second terminal.

FIGS. 6A and 6B are schematic circuit diagrams of a scan driving circuit according to another embodiment of the present application. Referring to FIGS. 6A and 6B, the configuration of transistors M1-M7 is similar to that of capacitors C1 and C2 in the embodiment of FIG. 4A; transistors M8-M14, and the configuration of capacitors C3 and C4 is similar to that of capacitors C3 and C4 in the embodiment of FIG. 4B.

The main difference between this embodiment and the previous embodiments in FIGS. 4A and 4B lies in that the first terminal of transistor M1 is electrically connected to the signal line of clock signal CK2, thereby using clock signal CK2 to replace the originally DC high-level first scan control signal D2U. Additionally, the second terminal of transistor M2 is electrically connected to the signal line carrying reference signal VSS, thereby using reference signal VSS to replace the original second scan control signal U2D. Similarly, the first terminal of transistor M8 is electrically connected to the signal line of clock signal CK4, thereby using clock signal CK4 to replace the originally DC high-level first scan control signal D2U. Furthermore, the second terminal of transistor M9 is electrically connected to the signal line carrying reference signal VSS, thereby using reference signal VSS to replace the original second scan control signal U2D.

More specifically, with the above configuration, scan circuit 121_x/121_y can apply a DC high level to the first terminal of transistor M1/M8 via clock signal CK2/CK4 when transistor M1/M8 is turned on (i.e., when the control terminal receives an enabled scan signal), without affecting the operation of transistors M1/M8. Similarly, for transistors M2/M9, their second terminals being electrically connected to reference signal VSS achieves the same effect as connecting to the second scan control signal U2D. Therefore, by electrically connecting the first terminal of transistor M1/M8 to the signal line of clock signal CK2/CK4 to use it as the first scan control signal U2D, and electrically connecting the second terminal of transistor M2/M9 to the signal line transmitting reference signal VSS, the signal lines for transmitting the first scan control signal D2U and the second scan control signal D2U can be omitted, thereby further reducing the width of the non-display region of the display panel.

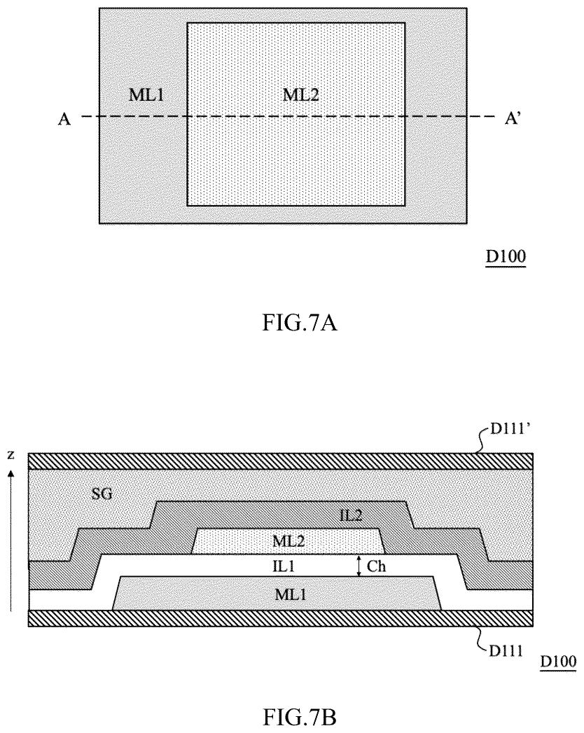

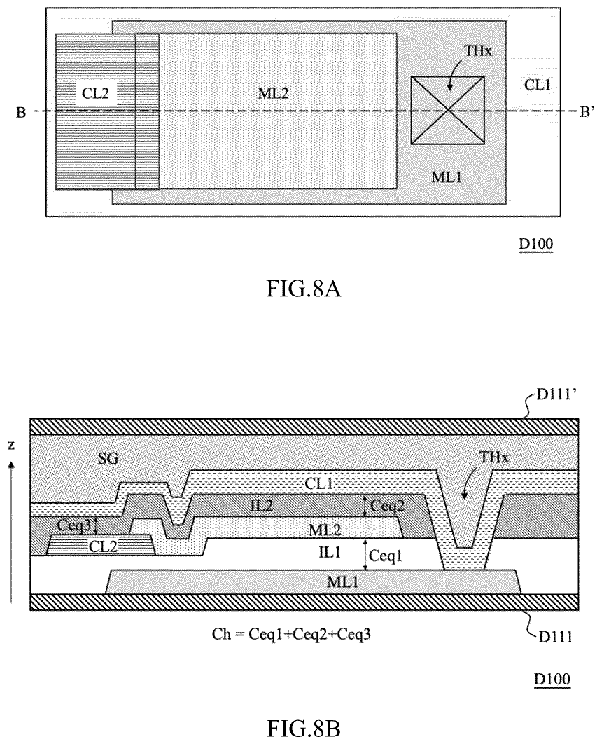

FIGS. 7A to 8B are schematic diagrams of the structural configurations of holding capacitors in scan driving circuits according to different embodiments of the present application, where FIGS. 7A and 7B illustrate one structure of the holding capacitor, and FIGS. 8A and 8B illustrate another structure of the holding capacitor.

Please refer to both FIG. 7A and FIG. 7B, where FIG. 7A is a top-view schematic of the display panel D100 in the holding capacitor region of this embodiment, and FIG. 7B is a cross-sectional schematic of the display panel D100 along the cutting line AA′. In this embodiment, the display panel D100 includes a first metal layer ML1, a first insulating layer IL1, a second metal layer ML2, and a second insulating layer IL2 sequentially stacked on the substrate D111. The first metal layer ML1 is covered by the first insulating layer IL1, the second metal layer ML2 is disposed on the first insulating layer IL1, and the second insulating layer IL2 covers both the first insulating layer IL1 and the second metal layer ML2. The stacked structure of the display panel D100 is bonded to the upper substrate D11l′ via a seal gum SG. In other words, the first metal layer ML1, the first insulating layer IL1, the second metal layer ML2, and the second insulating layer IL2 are fixed between the substrates D111 and D111′by the seal gum SG.

In this embodiment, the first metal layer ML1, the second metal layer ML2, and the first insulating layer IL1 spaced therebetween form the holding capacitor Ch. The capacitance value of the holding capacitor Ch is related to the overlapping area of the first metal layer ML1 and the second metal layer ML2, as well as the equivalent distance between the first metal layer ML1 and the second metal layer ML2 (i.e., the thickness of the first insulating layer IL1 in the overlapping portion of the first metal layer ML1 and the second metal layer ML2).

Specifically, during the assembly of the display device, the display panel D100 and the color filter (not shown) configured thereon are typically bonded using a seal gum, and ultraviolet light is applied to cure the seal gum during the bonding process. However, as seen from the top-view structure in FIG. 7A, most of the region of the holding capacitor Ch consists of opaque overlapping metal layers ML1 and ML2, and the holding capacitor Ch is usually placed near the bezel area of the display panel D100 in the corresponding scanning unit s121_1-s121_m. Therefore, during the ultraviolet curing process, the opaque holding capacitor blocks the ultraviolet light, affecting the curing effectiveness of the seal gum and thereby reducing the assembly reliability of the display device.

To address the issues in the above embodiment, the present application proposes a holding capacitor structure as shown in FIGS. 8A and 8B, where FIG. 8A is a top-view schematic of the display panel D100 in the holding capacitor region of this embodiment, and FIG. 8B is a cross-sectional schematic of the display panel D100 along the cutting line BB′.

Please also refer to FIGS. 8A and 8B. In this embodiment, the display panel D100 includes a first metal layer ML1, a first insulating layer IL1, a second metal layer ML2, and a second insulating layer IL2 sequentially stacked on the substrate D111. The first metal layer ML1 is covered by the first insulating layer IL1, the second metal layer ML2 is disposed on the first insulating layer IL1, and the second insulating layer IL2 covers both the first insulating layer IL1 and the second metal layer ML2. Additionally, at least a portion of the first metal layer ML1 is formed with through holes THx, allowing the first metal layer ML1 to be exposed from the first insulating layer IL1 and the second insulating layer IL2 through the through holes THx.

The display panel D100 further includes a first conducting layer CL1 and a second conducting layer CL2. The first conducting layer CL1 is formed on the second insulating layer IL2 and is electrically connected to the first metal layer ML1 through the through hole THX. Specifically, the first conducting layer CL1 extends from the upper surface of the second insulating layer IL2 to the sidewall of the through hole THx and covers the first metal layer ML1 exposed at the bottom of the through hole THx through the second insulating layer IL2 and the first insulating layer IL1. The second conducting layer CL2 is formed on the first insulating layer IL1 and is electrically connected to the second metal layer ML2. In this embodiment, the first conducting layer CL1 and the second conducting layer CL2 are implemented using a light-transmitting conductive material, such as an ITO conductive film. Therefore, the first conducting layer CL1 and the second conducting layer CL2 in this embodiment can also be referred to as a first light-transmitting conducting layer CL1 and a second light-transmitting conducting layer CL2.

In this embodiment, the side of the second metal layer ML2 electrically connected to the second conducting layer CL2 may have a portion of the second metal layer ML2 extending onto the second conducting layer CL2, ensuring that the second metal layer ML2 and the second conducting layer CL2 overlap at least partially in the z direction (i.e., the normal direction of the substrate D111). However, the present application is not limited thereto.

Specifically, the first metal layer ML1, the second metal layer ML2, and the first insulating layer IL1 spaced therebetween form the capacitor Ceq1; the second metal layer ML2, the first conducting layer CL1, and the second insulating layer IL2 spaced therebetween form the capacitor Ceq2; and the first conducting layer CL1, the second conducting layer CL2, and the second insulating layer IL2 spaced therebetween form the capacitor Ceq3. Since the first metal layer ML1 and the first conducting layer CL1 are short-circuited together, and the second metal layer ML2 and the second conducting layer CL2 are short-circuited together, the holding capacitor Ch in this embodiment can be equivalently represented as the sum of capacitors Ceq1, Ceq2 and Ceq3. In other words, the capacitor Ceq1 is formed based on the first overlapping area of the first metal layer ML1 and the second metal layer ML2 and the first insulating layer IL1 located in the first overlapping area. The capacitor Ceq2 is formed based on the second overlapping area of the second metal layer ML2 and the first conducting layer CL1 and the second insulating layer IL2 located in the second overlapping area. The capacitor Ceq3 is formed based on the third overlapping area of the first light-transmitting conducting layer CL1 and the second light-transmitting conducting layer CL2 and the second insulating layer IL2 located in the third overlapping area.

Furthermore, the capacitance value of the holding capacitor Ch depends on the overlapping area of the first metal layer ML1 and the second metal layer ML2, the equivalent distance between the first metal layer ML1 and the second metal layer ML2 (i.e., the thickness of the first insulating layer IL1 in the overlapping area of the first metal layer ML1 and the second metal layer ML2), the overlapping area of the second metal layer ML2 and the first conducting layer CL1, the equivalent distance between the second metal layer ML2 and the first conducting layer CL1 (i.e., the thickness of the second insulating layer IL2 in the overlapping area of the second metal layer ML2 and the first conducting layer CL1), the overlapping area of the first conducting layer CL1 and the second conducting layer CL2 (excluding the portion overlapping with the second metal layer ML2), and the equivalent distance between the first conducting layer CL1 and the second conducting layer CL2 (i.e., the thickness of the second insulating layer IL2 in the overlapping area of the first conducting layer CL1 and the second conducting layer CL2).

Compared to the embodiments in FIGS. 7A and 7B mentioned earlier, this embodiment is equivalent to forming additional parallel capacitors Ceq2 and Ceq3 using the light-transmitting first conducting layer CL1 and second conducting layer CL2. This ensures that even if the capacitance Ceq1 between the original first metal layer ML1 and the second metal layer ML2 decreases due to a reduced area, the overall capacitance value can still be maintained at the design value.

In this way, during the curing process using ultraviolet light irradiation, the transmittance of ultraviolet light through the scan driving circuit can be effectively improved, thereby enhancing the curing effect of the seal gum during the assembly of the display device and increasing the reliability of the display device.

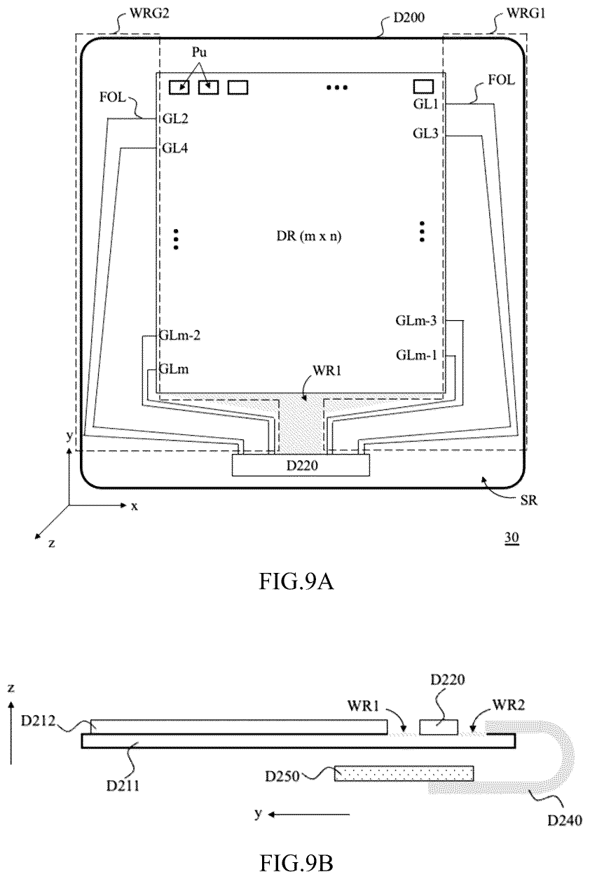

In other embodiments, the configuration of the display device 30 and its display panel D100 can also be as shown in FIGS. 9A and 9B, where FIG. 9A is a top-view schematic of the display device 30, and FIG. 9B is a side-view schematic of the display device 30. For clarity, FIG. 9A illustrates the internal components of the display device 30 unfolded on the x-y plane, while FIG. 9B shows the arrangement of the internal components within the housing of the display device 30.

Referring to FIGS. 9A and 9B, the display device 30 in this embodiment, in addition to the aforementioned backlight module and display panel D200, may also include a driver chip D220 for driving the display panel D200, a connection module D240, and a control circuit D250. Here, the display panel D200 includes a substrate D211 and a pixel array D212. This embodiment is largely similar to the configurations shown in FIGS. 2A and 2B, and redundant details can be referenced from the descriptions of the aforementioned embodiments and will not be repeated here.

The difference between this embodiment and the embodiments shown in FIGS. 2A and 2B lies in the fact that the scan driving circuit D120 and the data driving circuit D130 from the previous embodiments are integrated into the driver chip D220 in this embodiment. The driver chip D220 is positioned on the lower side of the non-display region SR of the display panel D200. To accommodate the connection configuration of the driver chip D220, the display panel D220 also includes fan-out transmission parts WRG1 and WRG2, which are arranged in the left and right non-display regions SR (relative to the display region DR). The fan-out transmission part WRG1 is used to electrically connect the odd-numbered scan lines GL1, GL3, . . . , GLm−1 to the driver chip D220, while the fan-out transmission part WRG2 is used to electrically connect the even-numbered scan lines GL2, GL4, . . . , GLm to the driver chip D220. Here, the fan-out transmission parts WRG1 and WRG2 include a plurality of fan-out lines FOLs for connecting the scan lines GL1-GLm.

On the other hand, in the embodiments of display devices 10/20/30 integrated with touch functionality (which may be referred to as touch display devices), the touch display devices 10/20/30 further include a touch control sensing chip (not shown) disposed on the substrate D111. Additionally, the upper side (On-cell) or interior (In-cell) of the display panel D100/D200 is integrated with a plurality of touch control sensing units (not shown) formed by an array of touch electrodes. The touch control sensing chip is used to drive these touch control sensing units to detect capacitance changes on the panel, enabling touch sensing functionality.

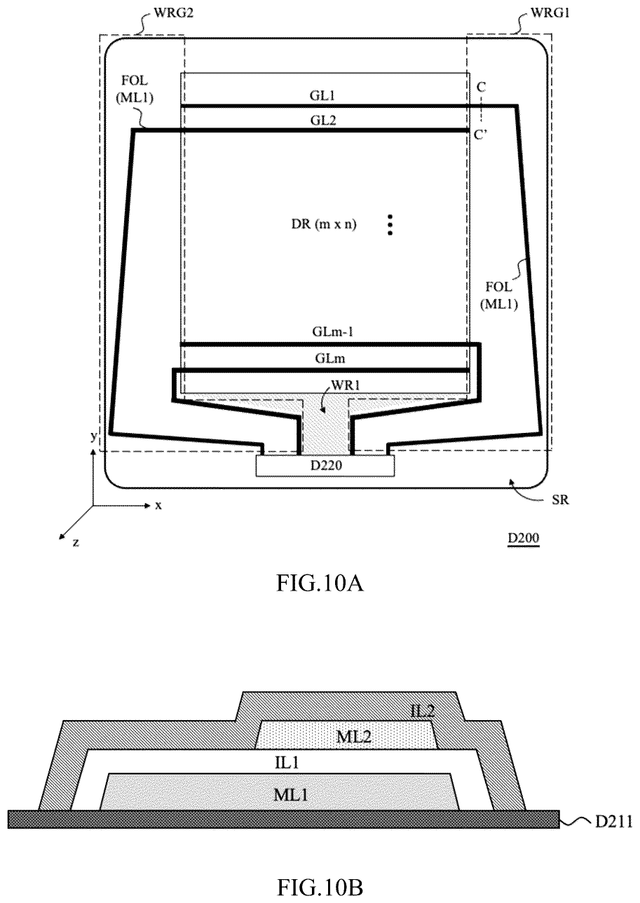

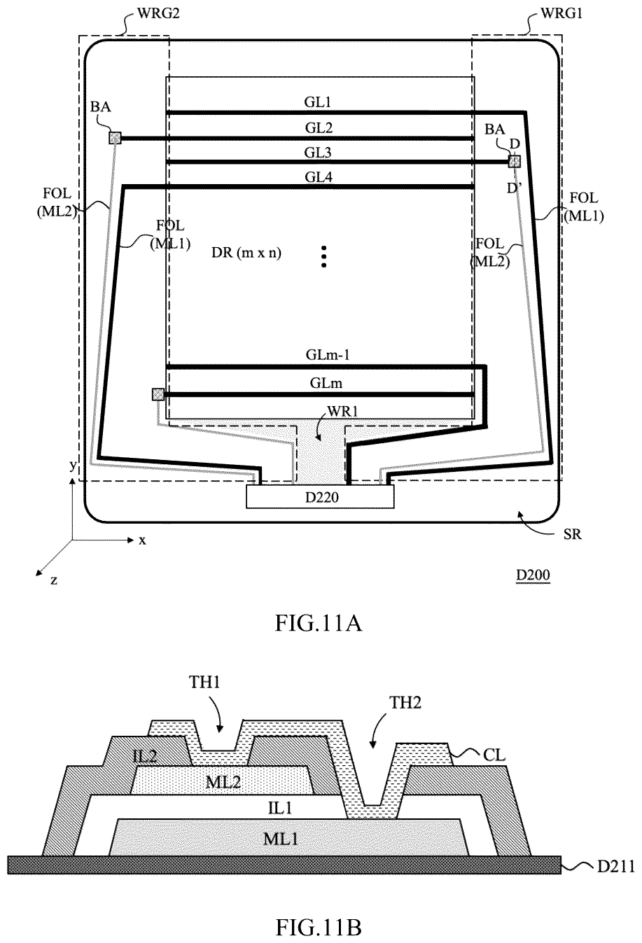

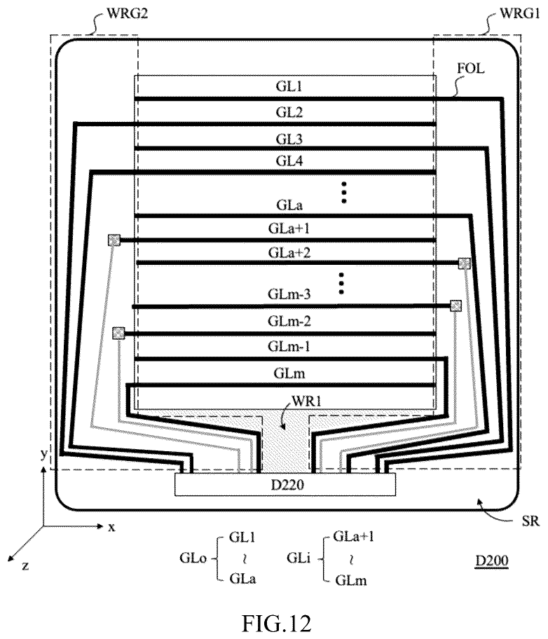

Below, different embodiment designs of the fan-out lines FOLs in the display panel D200 are further explained with reference to FIGS. 10A to 12. FIGS. 10A and 10B illustrate embodiments of line designs with a single-layer metal structure, FIGS. 11A and 11B illustrate embodiments of line designs with a double-layer metal interlace structure, and FIG. 12 illustrates an embodiment of a line design with a mixed single-layer and double-layer interlace structure.

Please refer to FIGS. 10A and 10B simultaneously. The cross-sectional structure of the display panel D200 along the line CC′ is shown in FIG. 10B. The wiring structure of the display panel D200 includes a first metal layer ML1, a first insulating layer IL1, a second metal layer ML2, and a second insulating layer IL2 sequentially formed on the substrate D211. The first metal layer ML1 is covered by the first insulating layer IL1, the second metal layer ML2 is disposed on the first insulating layer IL1, and the second insulating layer IL2 covers the first insulating layer IL1 and the second metal layer ML2. In the display region DR, the first metal layer ML1 is used as scan lines GL1-GLm to transmit signals.

In the single-layer metal structure line design of this embodiment, the fan-out lines FOLs of the fan-out transmission parts WRG1 and WRG2 are formed on the substrate D211 and directly connected to the first metal layer ML1 of the corresponding scan lines GL1-GLm. In other words, the fan-out lines FOLs are essentially the first metal layer ML1 line patterns formed on the substrate D211, electrically connecting the scan lines GL1-GLm to the driver chip D220.

Since the fan-out lines FOLs in this embodiment are implemented using the first metal layer ML1 directly formed on the substrate D211 and covered by two insulating layers IL1 and IL2, the first metal layer ML1 can be fully encapsulated, thereby enhancing its corrosion resistance and moisture resistance and extending the service life of the display panel D200.

However, since the fan-out lines FOLs are composed of a single metal layer, to avoid short circuits between lines, the spacing between fan-out lines FOLs must adhere to certain design specifications. Consequently, adopting the single-layer fan-out line FOL design of this embodiment inevitably makes it difficult to reduce the width of the non-display region SR, which is unfavorable for the current narrow-bezel design requirements of small-sized display devices.

Please refer to both FIG. 11A and FIG. 11B. The circuit structure of the display panel D200 in this embodiment is similar to that in the embodiment of FIG. 10B, where each scan line GL1-GLm is also implemented using the first metal layer ML1. The main difference between this embodiment and the previous embodiments in FIG. 10A and FIG. 10B lies in the fan-out lines FOLs of the fan-out transmission parts WRG1 and WRG2, which are composed of a double-layer metal interlace arrangement structure.

Specifically, in this embodiment, the fan-out lines FOLs of each fan-out transmission part WRG1 and WRG2 are alternately arranged and connected to the corresponding scan lines GL1-GLm using the first metal layer ML1 and the second metal layer ML2. Taking the line design of the fan-out transmission part WRG1 as an example, the fan-out line FOL connected to scan line GL1 is formed by the first metal layer ML1, the fan-out line FOL connected to scan line GL3 is formed by the second metal layer ML2, the fan-out line FOL connected to scan line GL5 is formed by the first metal layer ML1, and so on. Similarly, in the fan-out transmission part WRG2, the fan-out line FOL connected to scan line GL2 is formed by the second metal layer ML2, the fan-out line FOL connected to scan line GL4 is formed by the first metal layer ML1, and so on.

In other words, in each fan-out transmission part WRG1 and WRG2, adjacent lines of each fan-out line FOL are located on different metal layers. Observing the fan-out connection configuration of the overall scan lines GL1-GLm, scan lines GL2 and GL3 are electrically connected to the driver chip D220 through fan-out lines FOLs formed on the second metal layer ML2, scan lines GL4 and GL5 are electrically connected to the driver chip D220 through fan-out lines FOLs formed on the first metal layer ML1, and so on.

More specifically, since the scan line GL1-GLm transmits signals through the first metal layer ML1, in the configuration where the second metal layer ML2 serves as the fan-out line FOL, the fan-out line FOL and the corresponding scan line are also electrically connected via the bridge architecture BA. The cross-sectional structure of the bridge architecture BA at the cutting line DD′ is shown in FIG. 11B. In the bridge architecture BA, the regions where the first insulating layer IL1 and the second insulating layer IL2 cover the first metal layer ML1 and the second metal layer ML2 are respectively formed with through holes TH1 and TH2. The through hole TH1 exposes the second metal layer ML2, while the through hole TH2 exposes the first metal layer ML1. The bridge architecture BA also includes a conducting layer CL. The conducting layer CL covers the second insulating layer IL2 and the through holes TH1 and TH2, enabling the first metal layer ML1 and the second metal layer ML2 to be electrically connected through the conducting layer CL. In some embodiments, the conducting layer CL may be implemented, for example, as an ITO conductive film, but the present application is not limited thereto.

In the double-layer metal interlace line design of this embodiment, since the fan-out lines FOLs are arranged in an interlace configuration using the first metal layer ML1 and the second metal layer ML2 of different layers, with the first insulating layer IL1 serving as isolation between the lines, the design specifications for the line spacing of the fan-out lines FOLs can be smaller than those of a single-layer metal structure. This better meets the narrow bezel design requirements of current small-sized display devices.

However, conversely, in the configuration where the second metal layer ML2 serves as the fan-out line FOL, since it has only a single insulating layer IL2 on top, when the edge angle of the second metal layer ML2 is too steep, the second insulating layer IL2 covering the second metal layer ML2 may experience fractures or discontinuities at the edges of the second metal layer ML2 (also known as “undercut”). This exposes the second metal layer ML2, resulting in lower corrosion resistance and moisture resistance compared to the first metal layer ML1. Such issues may lead to poor image display on the display panel D200.

To address the respective issues in the line designs shown in FIGS. 10A to 11B, the embodiments of the present application propose a line design with a single-layer and double-layer staggered hybrid structure, as illustrated in FIG. 12. In this embodiment, the scan lines GL1-GLm can be divided into a first scan line group GLo and a second scan line group GLi, where the first scan line group GLo includes scan lines GL1-GLa, and the second scan line group GLi includes scan line GLa+1-GLm, 2≤a<m. In other words, at least two scan lines from top to bottom in the display panel D200 belong to the first scan line group GLo, and the subsequent (m−a) scan lines belong to the second scan line group GLi.

In the fan-out transmission parts WRG1 and WRG2, the fan-out lines FOLs connected to the first scan line group GLo will adopt the single-layer metal structure line design as shown in FIG. 10A, while the fan-out lines FOLs connected to the second scan line group GLi will adopt the double-layer metal staggered arrangement line design as shown in FIG. 11A.

In other words, the fan-out lines FOLs electrically connected to the scan lines GL1-GLa from the 1^{st} to the a^{th} will all be formed on the substrate D211 by the first metal layer (e.g., FIG. 10B and ML1 in FIG. 10B). On the other hand, the fan-out lines FOLs electrically connected to the scan lines GLa+1-GLm from the (a+1)^{th} to the m^{th} will be formed on the substrate D211 by alternating the first metal layer and the second metal layer (e.g., ML2 in FIGS. 10B and 11B), ensuring that each fan-out line FOL within the fan-out transmission parts WRG1 and WRG2 is formed on a different metal layer from its adjacent fan-out lines FOLs.

In some embodiments, a is, for example, 4. That is, the fan-out lines FOLs for the 1 st to 4th scan lines GL1-GL4 of the display panel D200 are formed using the first metal layer, while the fan-out lines FOLs for the 5th to m-th scan lines GL5-GLm of the display panel D200 are formed by alternating the first and second metal layers.

Specifically, due to the layout characteristics of the fan-out lines FOLs, which are arranged from top to bottom and from outer to inner (i.e., the scan lines GL1-GLm connected closer to the upper side are placed nearer to the edge of the substrate D211), the regions closer to the edge of the substrate D211 in the display panel D200 face a higher risk of undercut.

Therefore, this embodiment minimizes the risk of undercut by configuring the gate fan-out lines FOLs near the edge of the substrate D211 (i.e., the fan-out lines FOLs connected to the first scan line group GLo) as a single-layer metal structure, while arranging the fan-out lines near the display region DR (i.e., the fan-out line FOLs connected to the second scan line group GLi) as a double-layer metal alternating structure. This approach minimizes the risk of undercut to the greatest extent while maintaining minimal spacing for some fan-out lines, thereby balancing the design requirements for both narrow bezels and reliability in the display panel D200.

In some embodiments, the line width of the fan-out lines FOLs electrically connected to the first scan line group GLo will be greater than that of the fan-out lines FOLs electrically connected to the second scan line group Gli.

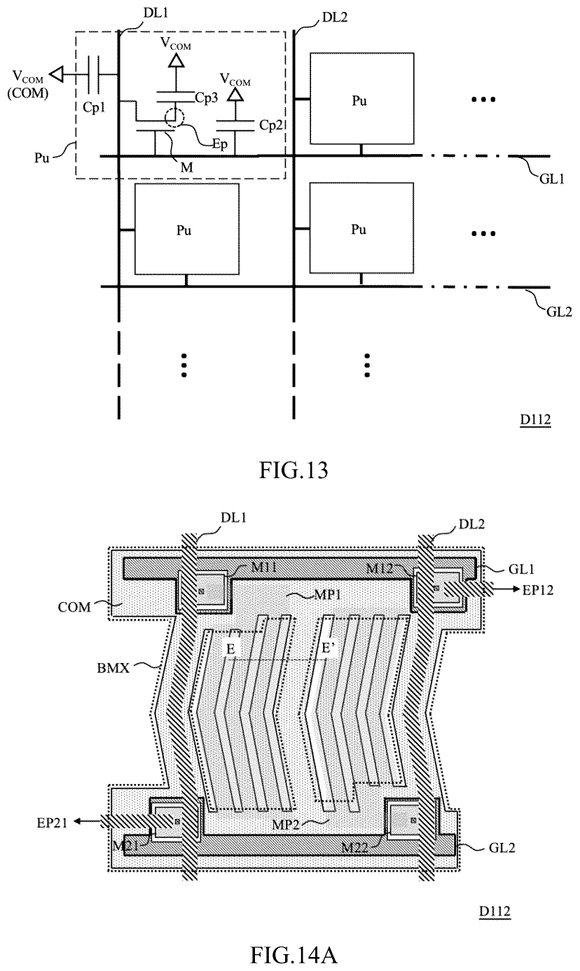

Below, the configuration of the pixel array in the aforementioned display panels D100/D200 is further explained with reference to FIGS. 13 to 18B. For clarity, the following description uses the display panel D100 and its components as the main subject, but the application is not limited thereto.

FIG. 13 is a schematic diagram of the equivalent circuit of the pixel array in the present application embodiment. Referring to FIG. 13, the pixel array D112 includes a plurality of pixel units Pu arranged in an array. The first row of pixel units Pu are commonly electrically connected to the first scan line GL1, the second row of pixel units Pu are commonly electrically connected to the second scan line GL2, the first column of pixel units Pu are commonly electrically connected to the first data line DL1, and the second column of pixel units Pu are commonly electrically connected to the second data line DL2. The connection relationships of other pixel units can be deduced accordingly.

From the equivalent circuit perspective, taking the pixel unit Pu in the first row and first column as an example, the pixel unit Pu includes a thin film transistor M, as well as capacitors Cp1, Cp2 and Cp3. The capacitor Cp1 is formed by the common electrode COM and the data line DL1, and can be considered as electrically connected between the data line DL1 and the common voltage V_{COM}. The capacitor Cp2 is formed by the common electrode COM and the scan line GL1, and can be considered as electrically connected between the scan line GL1 and the common voltage V_{COM}. The capacitor Cp3 is formed by the common electrode COM and the pixel electrode Ep of the thin film transistor M, and can be considered as electrically connected between the pixel electrode Ep and the common voltage V_{COM}, and is connected in parallel with the liquid crystal unit LC.

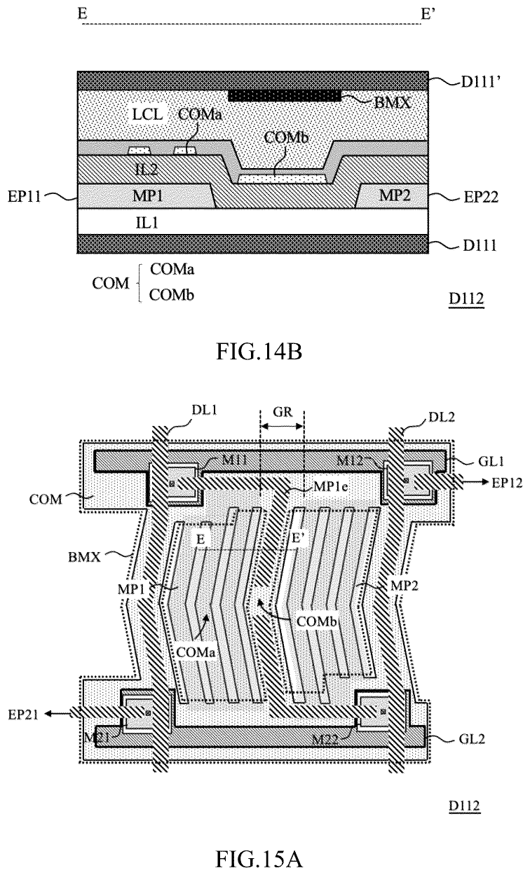

FIGS. 14A and 14B are schematic diagrams illustrating the structural configuration of a pixel array in some embodiments of the present application. Here, FIG. 14A and FIG. 14B depict a pixel structure with dual gates as an example, FIG. 14A is a top view of the pixel array D112, and FIG. 14B is a cross-sectional view of the pixel array D112. Referring to both FIGS. 14A and 14B, the pixel array D112 includes thin film transistors M11, M12, M21, and M22. The control terminals of thin film transistors M11 and M12 are electrically connected to the scan line GL1, while the control terminals of thin film transistors M21 and M22 are electrically connected to the scan line GL2. The first terminals of thin film transistors M11 and M21 are electrically connected to the data line DL1, and the first terminals of thin film transistors M12 and M22 are electrically connected to the data line DL2. The second terminals of thin film transistors M11, M12, M21, and M22 are electrically connected to corresponding pixel electrodes EP11, EP12, EP21, and EP22, respectively. In this embodiment, the control terminals of thin film transistors M11-M22 may, for example, be gates, the first terminals may, for example, be one of the source and drain, and the second terminals of thin film transistors M11-M22 may, for example, be the other of the source and drain, but the present application is not limited thereto.

Taking the pixel unit Pu corresponding to the thin film transistor M11 as an example for explanation. From a top-view structure, the overlapping portion between the common electrode COM and the pixel electrode EP11 formed by the panel-shaped metal layer MP1 constitutes part of the pixel storage capacitance (i.e., capacitor Cp3 in the equivalent circuit) of the pixel unit Pu. Here, the pixel electrode EP11 is arranged in a region overlapping with the grid structure of the common electrode COM. On the other hand, the pixel array D112 in this embodiment also includes a black matrix BMX, whose shape is designed to roughly correspond to that of the common electrode COM and is stacked on one side of the common electrode COM, while largely exposing the grid structure region of the common electrode COM.

From the cross-sectional structure at the intercept line EE′, in the pixel array D112, the first insulating layer IL1 is formed on the substrate D111. The metal layers MP1 and MP2 are spaced apart and formed on the first insulating layer IL1, covered by the second insulating layer IL2. The grid-structured common electrode COM is formed on the second insulating layer IL2, where the width of the first portion of the common electrode COMa covering the metal layer MP1 is smaller than that of the second portion of the common electrode COMb covering the gap between the metal layers MP1 and MP2. In other words, the orthographic projection regions of the first portion of the common electrode COMa and the metal layer MP1 at least partially overlap, while the orthographic projection regions of the second portion of the common electrode COMb and the metal layer MP1 largely substantially do not overlap. In this embodiment, the metal layer MP1 constitutes the pixel electrode EP11 corresponding to the thin film transistor M11. From the perspective of the black matrix configuration, the orthographic projection regions of the common electrode COM and the black matrix BMX largely overlap. The orthographic projection regions of the black matrix BMX and the first portion of the grid-structured common electrode COMa largely substantially do not overlap, and the orthographic projection region of the black matrix BMX partially located in the corresponding region with the second portion of the common electrode COMb will overlap with the orthographic projection region of the second portion of the common electrode COMb.

The liquid crystal layer LCL can be formed between the common electrode COM and the upper substrate D111′ by injecting liquid crystal material. The black matrix BMX is arranged on the side of the substrate D111′ facing the substrate D111 and located above the second portion of the common electrode COMb. The stacked structures on the left and right sides of the black matrix BMX can be regarded as adjacent pixel units Pu.

Specifically, the size of the pixel storage capacitance is primarily determined by the overlapping area between the metal layer MP1 and the common electrode COM, as well as the thickness of the insulating layer IL2 between them. A larger overlapping area or a thinner insulating layer IL2 results in a higher capacitance value for the pixel storage capacitor. A larger pixel storage capacitor can effectively maintain display quality, reducing issues such as flicker and crosstalk in the display panel.

However, in conventional pixel array designs, the thickness of the insulating layer IL2 is limited, and increasing the area of the metal layer MP1 would lead to a reduction in the aperture ratio and transmittance of the display panel. In other words, under existing designs, it is difficult to simultaneously achieve an increase in pixel storage capacitance while maintaining aperture ratio and transmittance.

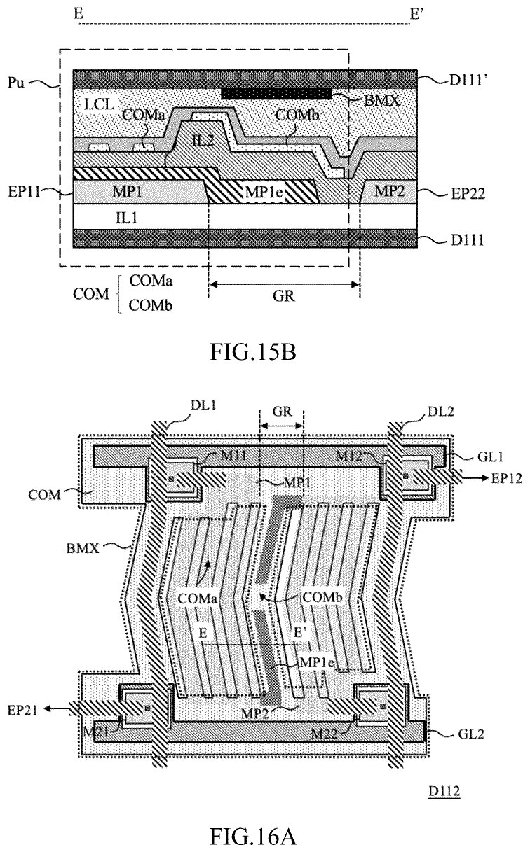

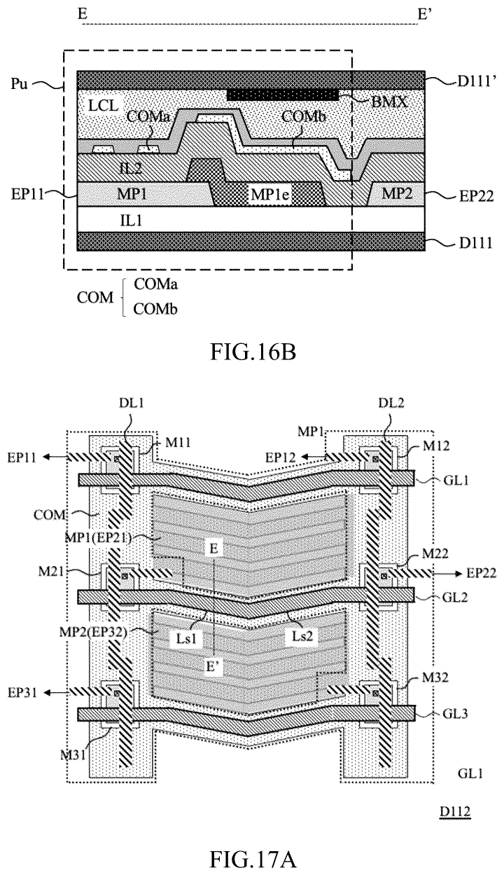

To address the aforementioned issues, the embodiments of the present application propose the structural configuration of the pixel array as shown in FIGS. 15A to 16B. FIGS. 15A and 15B are schematic top and cross-sectional views of the structural configuration of the pixel array in one embodiment of the present application, while FIGS. 16A and 16B are schematic top and cross-sectional views of the structural configuration of the pixel array in another embodiment of the present application.

Referring to FIGS. 15A and 15B simultaneously, the pixel array D112 in this embodiment includes thin film transistors M11, M12, M21 and M22. From the stacking structure of the pixel unit Pu corresponding to the thin film transistor M11, similar to the aforementioned FIG. 14B, the pixel array D112 includes substrates D111 and D111′, a first insulating layer IL1, a metal layer MP1, a second insulating layer IL2, a liquid crystal layer LCL, and a black matrix BMX. The configuration of these components can be referred to the descriptions of FIGS. 14A and 14B above, and thus will not be repeated here.

The main difference from the aforementioned FIGS. 14A and 14B lies in that the pixel array D112 in this embodiment further includes an extended metal layer MP1e. The extended metal layer MP1e is electrically connected to the drain of the thin film transistor M11 and also electrically connected to the metal layer MP1. The extended metal layer MP1e extends from the metal layer MP1 into the gap region GR between metal layers MP1 and MP2, and is at least partially formed within the orthographic projection region of the black matrix BMX (or alternatively referred to as being formed within the orthographic projection region of the second portion of the common electrode COMb).

Through the configuration of the extended metal layer MP1e described above, the area of the pixel electrode EP11 of the thin film transistor M11 can be equivalently regarded as the sum of the orthographic projection areas of the metal layer MP1 and the extended metal layer MP1e, thereby effectively enhancing the pixel storage capacitance of the pixel unit Pu. Additionally, since the extended metal layer MP1e is largely located within the shielding region/orthographic projection region of the black matrix BMX, it does not reduce the aperture ratio/light transmittance by increasing the shielding area. Thus, the effects of increasing pixel storage capacitance while maintaining aperture ratio/light transmittance are simultaneously achieved.

More specifically, in this embodiment, from the top-view structure in FIG. 15A, the first portion of the extended metal layer MP1e extends horizontally from the drain of the thin film transistor M11 to the gap region GR located between the metal layers MP1 and MP2, while the second portion of the extended metal layer MP1e extends along the orthographic projection region of the second portion of the common electrode COMb, roughly parallel to the grid structure of the common electrode COM. In other words, the first and second portions of the extended metal layer MP1e form a “7”-shaped structure in the top view.

In this embodiment, the extended metal layer MP1e may be formed in the same layer as the data lines DL1 and DL2 and composed of an opaque metal material, but the application is not limited thereto. When using the extended metal layer MP1e in the same layer as the data lines DL1 and DL2, the width of the extended metal layer MP1e is designed to be less than or equal to the width of the data lines DL1 and DL2 to prevent short circuits between the extended metal layer MP1e and adjacent pixel electrodes.

In some embodiments, the pixel unit corresponding to the diagonally adjacent thin film transistor M22 also includes an extended metal layer MP1e similar to those shown in FIG. 15A and FIG. 15B. Moreover, the extended metal layer of the thin film transistor M22 and the extended metal layer MP1e of the thin film transistor M11 are formed within the same orthographic projection region of the second portion of the common electrode COMb.

Please refer to FIGS. 16A and 16B. Since the structural configuration and functionality of this embodiment are largely the same as those in FIGS. 15A and 15B, similar details will not be repeated. The main difference between this embodiment and the aforementioned FIGS. 15A and 15B is that the extended metal layer MP1e in the embodiment of FIGS. 15A and 15B is implemented with metal in the same layer as the data lines DL1 and DL2 and extends from the drain of the thin film transistor M11. Thus, the second portion of the extended metal layer MP1e extends from the upper side to the lower side of the pixel array, closer to the scan line GL1 connected to the thin film transistor M11.

In contrast, in FIGS. 16A and 16B, the extended metal layer MP1e is formed by extending from the metal layer MP1 into the gap region GR, meaning the extended metal layer MP1e is arranged in the same layer as the metal layer MP1 and extends from the lower side to the upper side of the pixel array. In other words, the extended metal layer MP1e in this embodiment is positioned closer to the next scan line GL2 connected to the thin film transistor M11.

In some embodiments, the pixel unit corresponding to the diagonally adjacent thin film transistor M22 also includes an extended metal layer MP1e similar to that shown in FIGS. 16A and 16B. Moreover, the extended metal layer of the thin film transistor M22 and the extended metal layer MP1e of the thin film transistor M11 are formed within the orthographic projection region of the same second portion of the common electrode COMb.

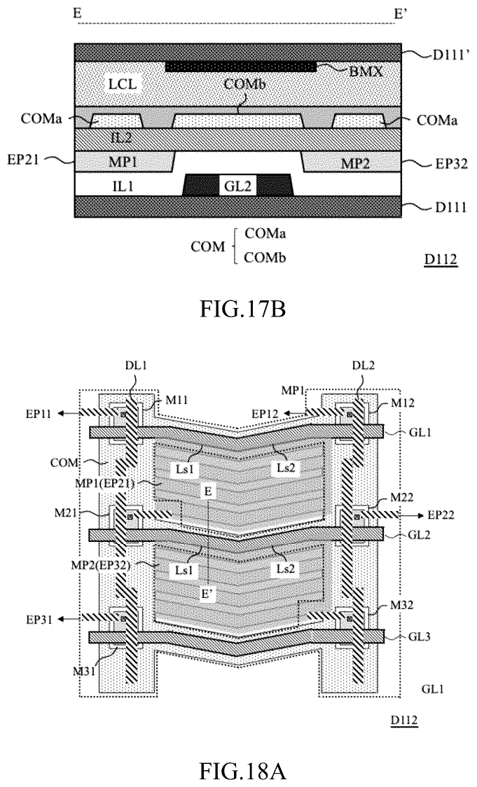

FIGS. 17A and 17B are schematic diagrams illustrating the structural configuration of a pixel array in some embodiments of the present application. Here, FIGS. 17A and 17B depict a pixel structure with three gates as an example. FIG. 17A is a top view of the pixel array D112, and FIG. 17B is a cross-sectional view of the pixel array D112. Referring to both FIGS. 17A and 17B, the pixel array D112 includes thin film transistors M11, M12, M21, M22, M31, and M32. The control terminals of the thin film transistors M11 and M12 are electrically connected to the scan line GL1, those of M21 and M22 to the scan line GL2, and those of M31 and M32 to the scan line GL3. The first terminals of the thin film transistors M11, M21, and M31 are electrically connected to the data line DL1, while the first terminals of M12, M22, and M32 are electrically connected to the data line DL2. The second terminals of the thin film transistors M11, M12, M21, M22, M31, and M32 are electrically connected to their corresponding pixel electrodes EP11, EP12, EP21, EP22, EP31, and EP32, respectively. In this embodiment, the control terminals of the thin film transistors M11-M32 may, for example, be gates, the first terminals may be one of the source or drain, and the second terminals of thin film transistors M11-M32 may be the other of the source or drain, though the present application is not limited to such a configuration.

Additionally, in some embodiments of the triple-gate pixel structure, the scan line segments connected to the thin film transistors of two adjacent columns can be divided into two interconnected line segments, where the extending directions of these two segments are not parallel to each other. Taking scan line GL2 as an example, the scan line segment connected between thin film transistors M21 and M22 can be divided into a first line segment Ls1 near one side's thin film transistor M21 and a second line segment Ls2 near the other side's thin film transistor M22, where the extending direction of the first line segment Ls1 and the extending direction of the second line segment Ls2 are not parallel. Other scan lines GL1 and GL3 can also be configured in a similar manner, which will not be repeated here.

Using the pixel unit Pu corresponding to thin film transistor M21 as an example for illustration. From a top-view structure, the overlapping portion between the common electrode COM and the pixel electrode EP21 formed by the panel-shaped metal layer MP1 constitutes part of the pixel storage capacitance (i.e., the capacitor Cp3 in the equivalent circuit) of the pixel unit Pu, where the pixel electrode EP21 is arranged in the region overlapping with the grid structure (i.e., the first portion of the common electrode COMa) of the common electrode COM. On the other hand, the pixel array D112 of this embodiment also includes a black matrix BMX, where the shape of the black matrix BMX is designed to roughly correspond to the shape of the common electrode COM and is stacked on one side of the common electrode COM, while largely exposing the region of the common electrode COM's grid structure.

From the cross-sectional structure at the cutting line EE′, in the pixel array D112, the scan line GL2 is arranged on the substrate D111, and the first insulating layer IL1 is formed on the substrate D111, covering the scan line GL2. The metal layers MP1 and MP2 are spaced apart and formed on the first insulating layer IL1. In some embodiments, the metal layers MP1 and MP2 and the first insulating layer IL1 form a coplanar structure. The second insulating layer IL2 is formed on the metal layers MP1 and MP2 and the first insulating layer IL1, and the common electrode COM is formed on the second insulating layer IL2, where the width of the first portion of the common electrode COMa located on the metal layers MP1 and MP2 is smaller than that of the second portion of the common electrode COMb located at the gap between the metal layers MP1 and MP2.

In other words, the orthographic projection regions of the first portion of the common electrode COMa at least partially overlaps with that of the metal layer MP1, while the orthographic projection region of the second portion of the common electrode COMb substantially does not overlap with that of the metal layer MP1/MP2. In this embodiment, the metal layer MP1 constitutes the pixel electrode EP21 corresponding to the thin film transistor M21. From the perspective of the configuration relative to the black matrix BMX, the orthographic projection regions of the common electrode COM and the black matrix BMX substantially overlap with each other. The orthographic projection regions of the black matrix BMX and the first portion of the common electrode COMa of the grid structure substantially do not overlap, and the orthographic projection region of the black matrix BMX partially located in the corresponding region with the second portion of the common electrode COMb will overlap with that of the second portion of the common electrode COMb.

The liquid crystal layer LCL can be formed between the common electrode COM and the upper substrate D111′ by injecting liquid crystal material. The black matrix BMX is disposed on the side of substrate D111′ facing substrate D111 and located above the second portion of the common electrode COMb, where the stacked structures on the left and right sides of the black matrix BMX can be regarded as adjacent pixel units Pus.

Specifically, for the pixel unit Pu corresponding to transistor M21, the size of the pixel storage capacitance is primarily determined by the overlapping area between the metal layer MP1 and the common electrode COM, as well as the thickness of the insulating layer IL2 between them. A larger overlapping area or a thinner insulating layer IL2 can result in a higher capacitance value for the pixel storage capacitance.

However, similar to the issues described in FIGS. 14A and 14B, under the design of a conventional triple-gate pixel structure's pixel array, the thickness of the insulating layer IL2 also has its limitations. Increasing the area of the metal layer MP1 would lead to a reduction in the aperture ratio and transmittance of the display panel. In other words, under existing designs, it is difficult to simultaneously achieve an increase in pixel storage capacitance while maintaining aperture ratio/transmittance. Insufficient pixel storage capacitance can result in unstable pixel voltage.

Additionally, in a double-layer staggered fan-out line design, when transistor M21 switches from on to off, the charge on the pixel electrode EP21 no longer flows to the data line, entering a charge conservation state. This causes a capacitive coupling effect between overlapping scan lines, increasing the coupling amount and thereby relatively raising leakage current.

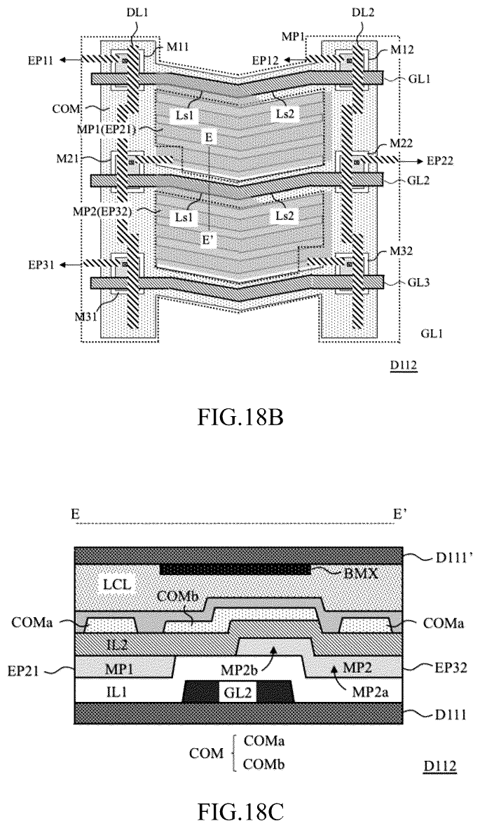

To address the aforementioned issues, the embodiments of the present application propose the structural configuration of the pixel array as shown in FIGS. 18A to 18C, where FIG. 18A and FIG. 18B are top-view schematic diagrams of the structural configuration of the pixel array in different embodiments of the present application, and FIG. 18C is a cross-sectional schematic diagram of the structural configuration of the pixel array according to the embodiment of FIG. 18A or FIG. 18B.

Please refer to FIGS. 18A and 18C simultaneously. The pixel array D112 in this embodiment includes thin film transistors M11, M12, M21, M22, M31, and M32. From the perspective of the stacked structure of the pixel unit Pu corresponding to thin film transistors M21 and M32, similar to the aforementioned FIG. 17B, the pixel array D112 includes substrates D111 and D111′, the first insulating layer IL1, the metal layer MP1, the second insulating layer IL2, the liquid crystal layer LCL, and the black matrix BMX. The configuration of the above components can be referred to the descriptions in FIGS. 17A and 17B, which will not be repeated here.

The main difference from the aforementioned FIGS. 17A and 17B lies in that the pixel electrodes EP21/EP32 in this embodiment extend to the region of the scan line GL1/GL2 of the pixel unit in the previous stage. For example, the metal layer MP1 serving as the pixel electrode EP21 extends to the region of scan line GL1, and the metal layer MP2 serving as the pixel electrode EP32 extends to the region of scan line GL2. In this embodiment, the coverage area of the pixel electrode EP21/EP32 on the first line segment Ls1 will be roughly the same as the coverage area of the pixel electrodes EP21/32 on the second line segment Ls2. In other words, in this embodiment, the pixel electrodes EP21/EP32 will simultaneously cover the first line segment Ls1 and the second line segment Ls2 of the corresponding scan lines GL1/GL2 (also referred to as the “full coverage configuration”). From another perspective, the full coverage configuration means that the orthographic projection region of the metal layer MP1/MP2 serving as the pixel electrodes EP21/EP32 at least partially overlaps with the orthographic projection regions of the first line segment Ls1 and the second line segment Ls2 of the corresponding scan line GL1/GL2, where the overlapping area between the orthographic projection regions of the metal layer MP1/MP2 and the first line segment Ls1 is roughly the same as the overlapping area between the orthographic projection regions of the metal layer MP1/MP2 and the second line segment Ls2.

More specifically, as shown in FIG. 18C, from the cross-sectional structure at the intercept EE′, the metal layer MP2 extends to cover the first insulating layer IL1 above the scan line GL2. Here, the metal layer MP2 can be divided into a first portion MP2a and a second portion MP2b. The first portion MP2a is located below the first portion of the common electrode COMa and does not overlap with the scan line GL2. The second region MP2b of the metal layer MP2 has at least a part located above the scan line GL2 and below the second portion of the common electrode COMb. In other words, in this embodiment, the orthographic projection regions of the first portion MP2a of the metal layer MP2 and the first portion of the common electrode COMa at least partially overlap. The orthographic projection regions of the second portion MP2b of the metal layer MP2, the second portion of the common electrode COMb, and the scan line GL2 at least partially overlap with each other.

Through the above configuration of the metal layer MP2, the pixel storage capacitance corresponding to the pixel electrode EP32 of the thin film transistor M11 can be regarded as the capacitance formed by the first portion MP2a of the metal layer MP2 and the first portion of the common electrode COMa, combined with the capacitance formed by the second portion MP2b of the metal layer MP2 and the second portion of the common electrode COMb. In other words, the area of the pixel electrode EP32 can be considered as the sum of the orthographic projection areas of the first portion MP2a and the second portion MP2b of the metal layer MP2. Compared to the pixel structures in FIGS. 17A and 17B, this embodiment increases the area of the pixel electrode EP32, effectively enhancing the pixel storage capacitance of the pixel unit Pu.

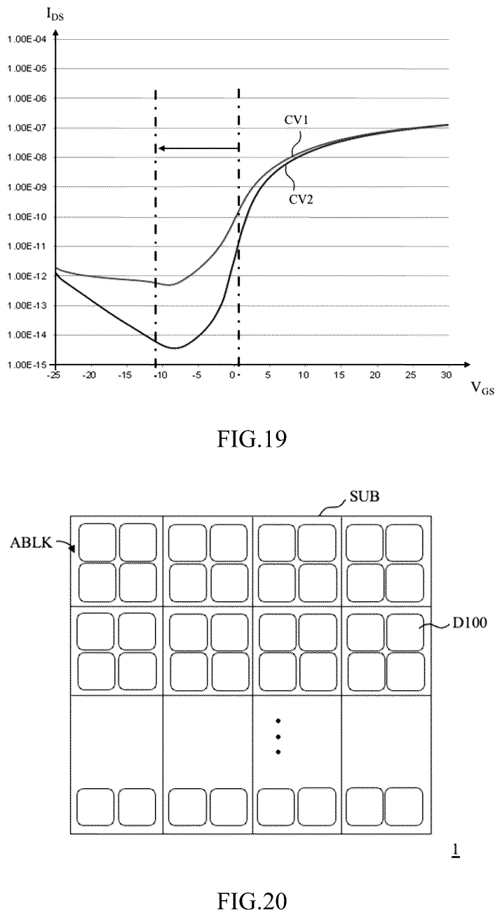

Experimental verification shows that the fully covered pixel structure in FIG. 18A, compared to the traditional pixel structure, can increase the capacitance value of the pixel capacitor (i.e., capacitor Cp3 in FIG. 13) by approximately 13% when no process deviation occurs, and can increase the capacitance value of the scan line capacitor (i.e., capacitor Cp2 in FIG. 13) by about 8.2%. Additionally, the overlapping area between the second portion MP2b of the metal layer MP2 and the scan line GL2 of the previous stage can equivalently increase the scan line capacitor Cp2. Since, in the double-layer staggered fan-out line design, the coupling amount between the upper and lower lines is essentially inversely proportional to the capacitance value of the scan line capacitor Cp2, this embodiment increases the scan line capacitor Cp2 to reduce line coupling, thereby lowering the gate-source voltage of the transistor M32. As shown in FIG. 19, compared to the voltage-current characteristic curve CV1 of the pixel array configuration in FIGS. 17A and 17B, the voltage-current characteristic curve CV2 of this embodiment exhibits a distinct leftward shift, effectively reducing the gate-source voltage Vos and the leakage current IDS.

Please also refer to FIGS. 18B and 18C. The pixel structure of the embodiment in FIG. 18B is largely the same as that in FIG. 18A, so related or similar parts can be understood by referring to the description of the aforementioned embodiment, which will not be repeated here. The main difference between this embodiment and the embodiment of the previous FIG. 18A lies in the fact that the pixel electrode EP21/EP32 in this embodiment only covers one side of the corresponding scan line GL1/GL2's first line segment Ls1/second line segment Ls2 (also referred to as the “single-side coverage configuration”).

Taking the configuration illustrated in FIG. 18B as an example, the pixel electrode EP21 covers most of the first line segment Ls1 and part of the second line segment Ls2 of the scan line GL1, while the pixel electrode EP32 covers most of the first line segment Ls1 and part of the second line segment Ls2 of the scan line GL2. That is, in this embodiment, the coverage area of the pixel electrode EP21/EP32 on the first line segment Ls1 is greater than its coverage area on the second line segment Ls2 (i.e., left-side single-side coverage configuration), but the present application is not limited thereto. In other embodiments, the pixel structure can also be designed such that the coverage area on the first line segment Ls1 is smaller than that of the pixel electrode EP21/32 on the second line segment Ls2 (i.e., right-side single-side coverage configuration).

In other words, in this embodiment, the coverage area of the pixel electrode EP21/EP32 on one of the first line segment Ls1 and the second line segment Ls2 of the corresponding scan line GL1/GL2 will be larger than its coverage area on the other of the first line segment Ls1 and the second line segment Ls2. From another perspective, the single-sided coverage configuration means that the overlapping area between the orthographic projection regions of the metal layer MP1/MP2, which serves as the pixel electrode EP21/EP32, and one of the first line segment Ls1 and the second line segment Ls2 of the corresponding scan line GL1/GL2 will be larger than the overlapping area between the orthographic projection regions of the metal layer MP1/MP2 and the other of the first line segment Ls1 and the second line segment Ls2.

From the cross-section at the intersection EE′ passing through the first line segment Ls1, the cross-sectional structures of both FIG. 18A and FIG. 18B will appear as shown in FIG. 18C. If viewed from the cross-section passing through the second line segment Ls2, the cross-sectional structure of FIG. 18A will appear as shown in 18C, while the cross-sectional structure of FIG. 18B will appear as shown in FIG. 17B.

Experimental verification shows that the pixel structure with the single-sided coverage configuration in FIG. 18B, compared to the traditional pixel structure, can increase the capacitance value of the pixel capacitor (i.e., capacitor Cp3 in FIG. 13) by approximately 10.4% when no process deviation occurs, and can increase the capacitance value of the scan line capacitor (i.e., capacitor Cp2 in FIG. 13) by approximately 15%.

More specifically, since the process deviation of the pixel electrode EP21/EP32 during the manufacturing of the pixel array D112 typically ranges between 1.35 μm (3 sigma) and 2.7 μm (6 sigma), if the pixel electrode EP21/EP32 is to cover the scan line GL1/GL2, the overlapping width between the pixel electrode EP21/EP32 and the scan line GL1/GL2 must be at least between 1.35 μm-2.7 μm to avoid failing to achieve the intended coverage structure due to process deviation. Additionally, in the pixel structures of FIG. 18A and FIG. 18B, the process deviation of the pixel electrode EP21/EP32 simultaneously affects the capacitance value estimation of capacitors Cp2 and Cp3. If the resulting capacitance variation is too large, it may impact the design considerations for various performance aspects of the display panel.

The embodiment in FIG. 18B adopts a single-sided coverage configuration design compared to the embodiment in FIG. 18A, which can effectively reduce the impact of process deviation of the pixel electrode EP21/EP32 on the capacitance values. Experimental verification shows,

In the case of vertical offset in pixel electrodes EP21/EP32, calculated based on a 3 sigma offset, the pixel capacitance offset of the pixel structure with the single-sided overlap configuration shown in FIG. 18B is 5.3%, which is approximately half the 10.9% pixel capacitance offset of the fully overlapped configuration in FIG. 18A. On the other hand, the scan line capacitance offset of the pixel structure with the single-sided overlap configuration shown in FIG. 18B is 10.5%, which is approximately half the 20.2% pixel capacitance offset of the fully overlapped configuration in FIG. 18A.

As demonstrated above, compared to the fully overlapped configuration, the single-sided overlap configuration not only effectively increases the capacitance values of both pixel capacitance and scan line capacitance but also further reduces the impact of process offsets on pixel capacitance and scan line capacitance. This results in better uniformity of the common electrode voltage within the display panel and significantly optimizes the panel's flicker issue.

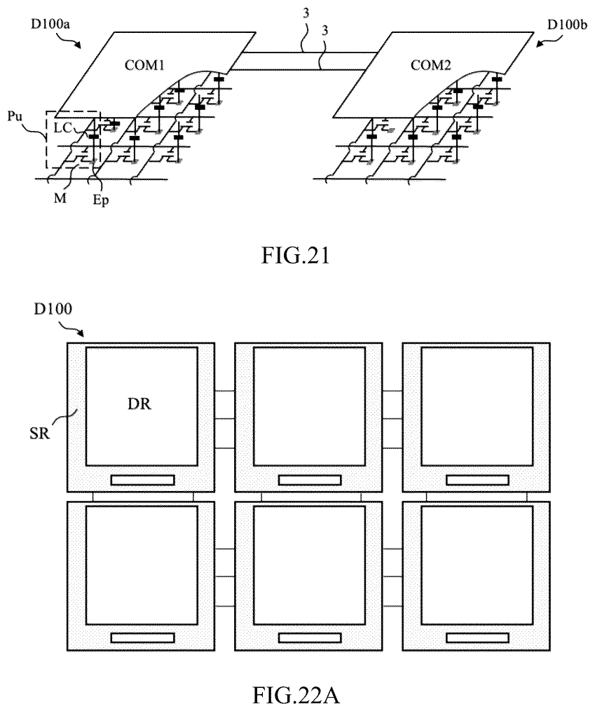

Below, FIGS. 20 to 24B are used to further illustrate some technical features of the aforementioned display devices 10/20/30 and display panels D100/D200 during assembly and manufacturing. For clarity, the following description focuses on display device 10 and display panel D100, but the present application is not limited thereto examples.

FIG. 20 is a schematic diagram of the configuration of an array substrate according to an embodiment of the present application. Referring to FIG. 20, the array substrate 1 of the present application includes a glass substrate SUB (or mother substrate SUB) and a plurality of display panels D100. The region of the glass substrate SUB where the display panels D100 are formed can be divided into a plurality of array blocks ABLK. In some embodiments, within each array block ABLK, the edges of the display panels D100 are arranged adjacent to each other, preventing the placement of test circuit lines between them. Preferably, the plurality of display panels D100 are arranged on the array substrate 1 without gaps. In this embodiment, the common electrode on each display panel D100 overlaps with metals such as scan lines, data lines, and pixel electrodes in the display region to form corresponding capacitors. During the manufacturing of display panel D100, it is first formed on the array substrate 1 and then segmented and assembled into independent display devices 20 as shown in FIGS. 2A and 2B, or independent display devices 30 as shown in FIG. 9A and FIG. 9B.

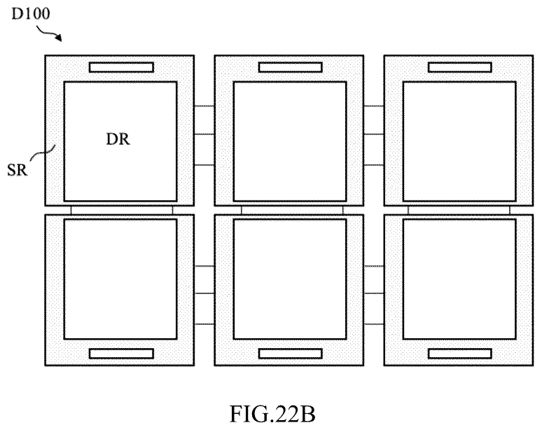

Taking the configuration of adjacent display panels D100a and D100b in FIG. 21 as an example for illustration, where FIG. 21 is a schematic diagram of the configuration of adjacent display panels on an array substrate in an embodiment of the present application, the common electrode COM1 of display panel D100a overlaps with metals such as the scan line GL, data line DL, and pixel electrode Ep of the thin film transistor M in the display region. Similarly, display panel D100b also has a similar configuration. From the perspective of an equivalent circuit, as shown in FIG. 13, the pixel unit Pu on display panel D100a is again used as an example for explanation. The pixel unit Pu can be equivalently considered to have a thin film transistor M and capacitors Cp1, Cp2 and Cp3. The specific connection relationships can be referred to the description in the aforementioned FIG. 13 embodiment and will not be repeated here. Therefore, within the display region of each display panel D100a/D100b, the equivalent capacitance of each pixel unit Pu on display panel D100a/D100b will equal the sum of the capacitance values of capacitors Cp1, Cp2, and Cp3. Thus, the total capacitance of the display region of display panel D100a/D100b will be equivalent to the sum of the capacitance values of capacitors Cp1, Cp2, and Cp3 multiplied by the number of pixel units Pu in the display region.

In this embodiment, adjacent display panels D100a and D100b are electrically connected to each other's common electrodes COM1 and COM2 through at least one line 3. In this embodiment, display panels D100a and D100b are illustrated as being connected to each other's common electrodes COM1 and COM2 through two of the lines 3, but the present application is not limited thereto. In some embodiments, display panels D100a and D100b may also use more of the lines 3 to electrically connect each other's common electrodes COM1 and COM2.

Referring to FIGS. 20 and 21, in this embodiment, each display panel D100 within every array block ABLK of the array substrate 1 features an electrical connection configuration similar to the aforementioned common electrode COM. This ensures that the total capacitance Ctotal within the same array block ABLK equals the sum of the equivalent capacitances of all display panels D100, effectively forming a large equivalent capacitance among the display panels D100. In some embodiments, all adjacent display panels in the array substrate 1 are interconnected via at least one line 3, linking their respective common electrodes COM, thereby increasing the overall equivalent capacitance of the array substrate 1. Typically, static electricity generated by friction or handling is absorbed by the common electrode COM. The design of this large equivalent capacitance further enhances electrostatic absorption, achieving optimized electrostatic protection.

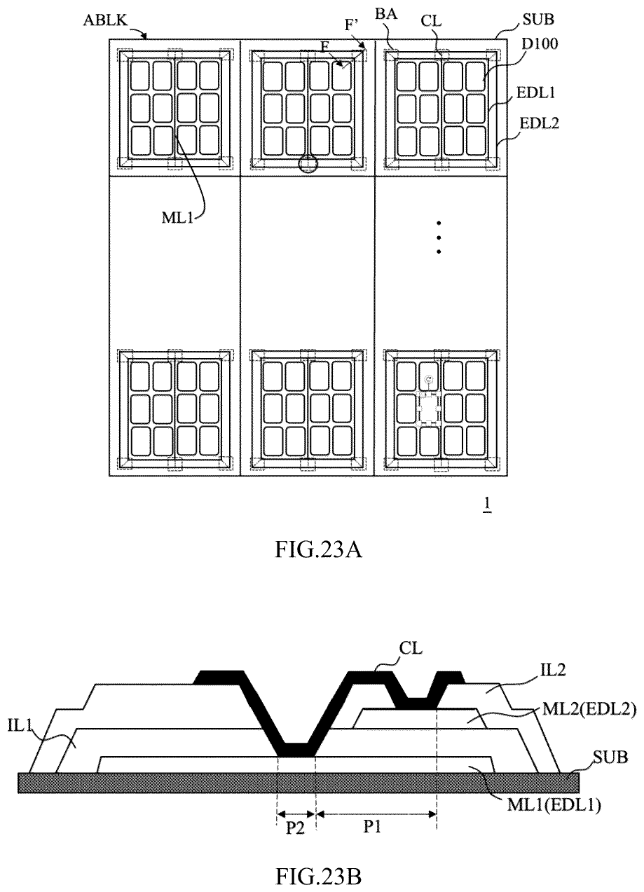

FIGS. 22A and 22B illustrate the configuration of the display panels on the array substrate in the present application. In this embodiment, the display panel D100 is arranged similarly to the previous embodiments, featuring a display region DR and a non-display region SR. For specific structural details, refer to the descriptions in the aforementioned embodiments, which will not be repeated here. In FIG. 22A, the display panels D100 are aligned in the same orientation. That is, in the vertical direction, the foot region of a display panel D100 (the lower side of the figure, where the non-display region SR is wider, or the side configured for the data driver circuit D130) adjoins the head region of the adjacent display panel D100 (the upper side of the figure, where the non-display region SR is narrower). Additionally, the display panels D100 are interconnected via a plurality of lines 3. For example, the top-left display panel D100 in FIG. 22A is connected to the adjacent panel below it by two lines 3, while it is linked to the panel to its right by three lines 3. In other words, the arrangement in FIG. 22A can be described as a head-to-tail configuration.

Alternatively, in FIG. 22B, the upper row of display panels D100 and the lower row are arranged facing opposite directions. Specifically, the head region of an upper-row display panel D100 adjoins the head region of the adjacent lower-row display panel D100. Moreover, the display panels D100 are interconnected via a plurality of lines 3. For instance, the top-left display panel D100 in FIG. 22B is connected to the panel below it by two lines 3, while it is linked to the panel to its right by three lines 3. In other words, the arrangement in FIG. 22B can be termed a head-to-head configuration.

Experimental tests show, as indicated in the table below, that when there are no test circuit lines on the array substrate and the common electrodes of adjacent display panels are not interconnected, there is a 4.38% probability of electrostatic damage to the metal lines in the array substrate. In contrast, the embodiments of the present application, through the aforementioned structural configuration, can reduce the probability of electrostatic damage to 0%.

| | Whether | | | |
|---|---|---|---|---|
| | the common | | | Electrostatic |
| | electrodes are | Array | Input | damage |
| | interconnected | block | part | rate |
| Glass substrate of | No | 12 | 2213 | 4.38% |
| an array substrate | Yes | 6 | 1080 | 0% |
| without test | | | | |
| circuit lines | | | | |

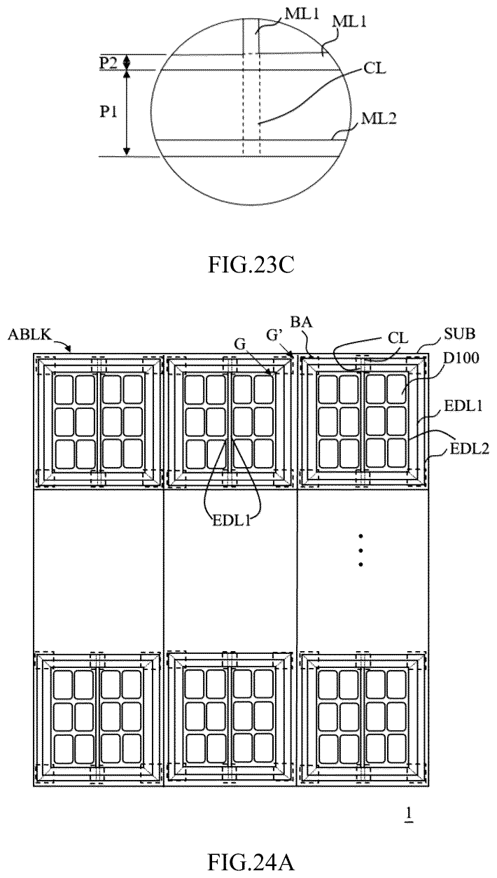

In another embodiment of the present application, FIG. 23A is a schematic diagram of an electrostatic protection structure configured within an array block of the array substrate according to the embodiments of the present application. Referring to FIG. 23A, the array substrate 1 of the present application includes a glass substrate SUB and a plurality of display panels D100 as described earlier. The glass substrate SUB can be divided into a plurality of array blocks ABLK, and the display panels D100 may be arranged edge-adjacent within each array block ABLK. In this embodiment, each array block ABLK has, for example, twelve display panels D100, but is not limited thereto and may be configured with more or fewer, such as four, six, eight, etc. The present application is not limited in this regard.

Next, referring to FIGS. 23A, 23B and 23C, where FIG. 23B is a cross-sectional view along line FF′ of FIG. 23A, and also a cross-sectional view of the electrostatic protection structure in the embodiments of the present application. FIG. 23C is a partial enlarged schematic diagram of the electrostatic protection structure in FIG. 23A.

Each of the array blocks ABLK has a metal layer ML1 and ML2, an insulating layer IL1 and IL2, and a plurality of conducting layers CL.

As shown in FIGS. 23A and 23B, within each array block ABLK, the metal layer ML1 is arranged on the glass substrate SUB to surround at least six of the plurality of display panels D100, forming a plurality of electrostatic discharge lines EDL1 on each array block ABLK. The insulating layer IL1 covers the metal layer ML1 while exposing at least a portion of the metal layer ML1. The metal layer ML2 is arranged on the insulating layer IL1 to surround at least six of the plurality of display panels D100, forming a plurality of electrostatic discharge lines EDL2 corresponding to the plurality of electrostatic discharge lines EDL1 on each array block ABLK. The insulating layer IL2 covers the metal layer ML2 while exposing at least a portion of the metal layer ML2.

In the embodiment of FIG. 23A, the metal layer ML2 is located on the outer side of the metal layer ML1. More specifically, the metal layer ML2 is closer to the edge of the array block ABLK than the metal layer ML1, but this is not limited thereto. Although not shown in the figure, the opposite arrangement is also possible, where the metal layer ML1 is on the outer side of the metal layer ML2. Whether the metal layer ML1 or ML2 is closer to the plurality of display panels D100, both can effectively dissipate static electricity. The key point is that the metal layer ML1 and the metal layer ML2 form a stacked structure. In the embodiment of FIG. 23A, the metal layer ML1 surrounds two display panels D100, while the metal layer ML2 surrounds six of the display panels D100. However, this is not limited thereto; it could also surround two, four, eight, or more of the display panels D100.

As indicated by the dashed lines between the metal layers ML1 and ML2 in FIG. 23A, they represent the conducting layer CL. The region enclosed by the dashed lines in FIG. 23A is the bridge architecture BA (or bridge region BA). The conducting layer CL is formed within the bridge architecture BA, and the bridge architecture BA is at least located at the turning points of the metal layer ML1 (i.e., the corners of the array block ABLK). Additionally, as shown by the dashed lines in 23B, at least a portion of the conducting layer CL is connected to the metal layer ML1 through the exposed portion of the insulating layer IL1, and at least another portion of the conducting layer CL is connected to the metal layer ML2 through the exposed portion of the insulating layer IL2. This allows the conducting layer CL to pass through the insulating layers IL1 and IL2, electrically connecting the metal layers ML1 and ML2. In other words, the conducting layer CL ensures that the metal layers ML1 and ML2 are electrically interconnected.

By using a plurality of conducting layers CL to electrically connect the metal layers ML1 and ML2 in a plurality of bridge architectures BA, the corresponding electrostatic discharge lines EDL1 and EDL2 can be interconnected. In this embodiment, although the illustration shows the bridge architecture BA positioned at the turning points of the metal layer ML1, the present application is not limited thereto. The bridge architecture BA can also be placed at other locations besides the turning points of the metal layer ML1, as long as it ensures electrical interconnection between the metal layers ML1 and ML2. Additionally, it should be understood that when the bridge architecture BA is positioned at the turning point of the metal layer ML1, the effect of dissipating static electricity is better.

With the above configuration, even when small-sized display panels D100 are arranged on the array substrate 1 without test circuit lines, the effect of electrostatic protection can still be achieved. Moreover, since the metal layers ML1 and ML2 form a double-layer structure, the horizontal area occupied on the array substrate 1 can be reduced, thereby increasing the number of display panels D100 that can be arranged per array block ABLK on the mother substrate SUB. Additionally, because the electrostatic protection structure includes the double-layer metal layers ML1 and ML2, the overall impedance of the mother substrate SUB is lower, and the equivalent area is larger, making it easier to achieve the functions of attracting and dissipating static electricity.

As shown in FIG. 23C, in this embodiment, the spacing P1 (or pitch) between two adjacent electrostatic discharge lines EDL1/EDL2 may be greater than 200 μm. More specifically, the pitch may be, for example, the spacing P1 of 200-300 μm when viewed from above, measured from the side of the metal layer ML1 near the metal layer ML2, electrically connected via the conducting layer CL, to the side of the metal layer ML2 far from the metal layer ML1, also electrically connected via the conducting layer CL (i.e., the pitch between adjacent electrostatic discharge lines EDL1/EDL2 may range between 200-300 μm). Furthermore, the spacing P2 between the parallel sides electrically connected to the metal layer ML1 via the conducting layer CL may be 150-300 μm.

Through the above embodiments of the present application, combined with the dimensions of spacing P1 and spacing P2, the required arrangement space for the electrostatic protection structure of one array block ABLK is only 900-1500 μm, saving a significant amount of space compared to conventional techniques. As a result, more small-sized display panels D100 can be arranged.

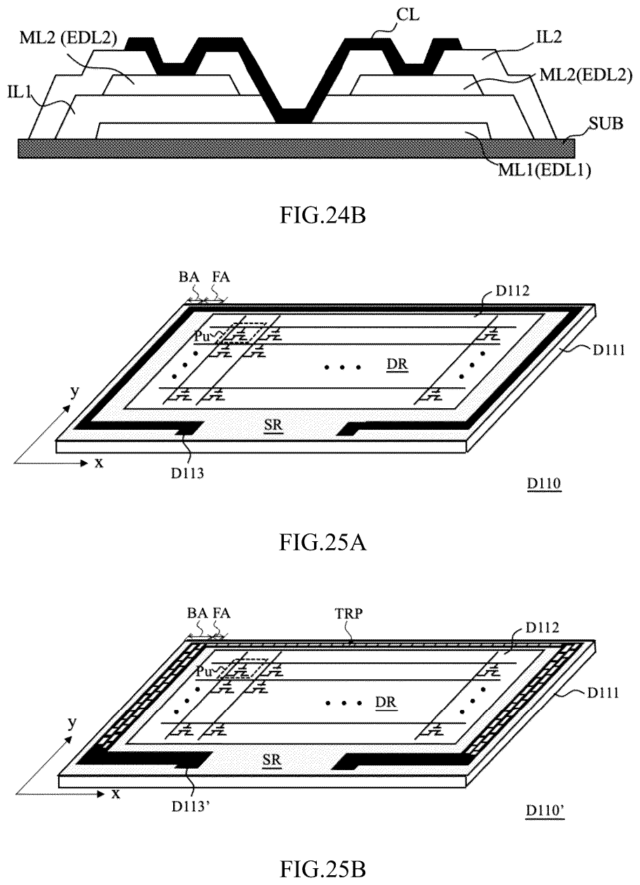

Please refer to FIGS. 24A and 24B, where FIG. 24B is a schematic cross-sectional view along the GG′ section line of FIG. 24A and also represents a cross-sectional diagram of the electrostatic protection structure in another embodiment of the present application. As shown in FIGS. 24A and 24B, there are two metal layers ML2, positioned on either side of metal layer ML1 and located at different heights from ML1. Additionally, metal layer ML1 also consists of two layers in certain regions on the glass substrate SUB. When a plurality of metal layers ML1 are present, they form a plurality of electrostatic discharge lines EDL1, and insulating layer IL1 electrically isolates each EDL1 in the non-bridge region. Similarly, when a plurality of metal layers ML2 are present, they form a plurality of electrostatic discharge lines EDL2, and the insulating layer IL2 electrically isolates each EDL2 in the non-bridge region. This configuration eliminates the need for additional insulating layers and reduces the thickness of the array substrate 1.

Furthermore, in another embodiment of the present application (though not illustrated), each array block ABLK contains a plurality of metal layers, a plurality of insulating layers, and a plurality of conducting layers. The plurality of metal layers are sequentially stacked on the glass substrate SUB, surrounding at least two of the display panels D100. The plurality of insulating layers separate the metal layers while exposing at least a portion of them. The plurality of conducting layers, at least in the bridge architectures of the metal layers, penetrate the insulating layers to electrically connect the stacked metal layers across different layers.

Through the above embodiments of the present application, electrostatic protection can be achieved on the array substrate 1 even when small-sized display panels D100 are configured without test circuit lines.

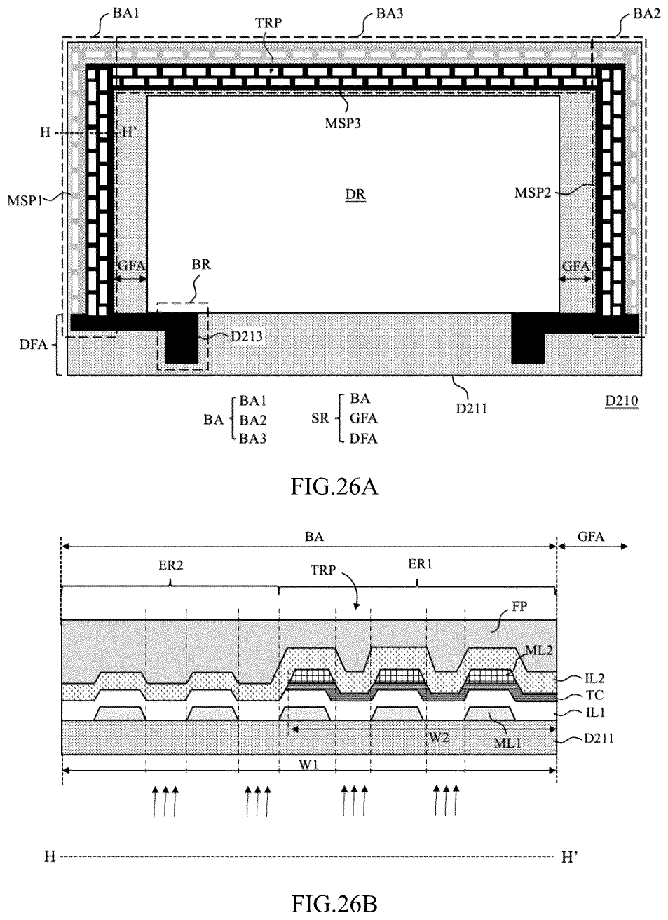

FIGS. 25A and 25B are schematic diagrams of pixel array substrate configurations in different embodiments of the present application. Referring first to FIG. 25A, the pixel array substrate D110 in this embodiment is similar to the configurations shown in FIGS. 1A to 2B, including a display region DR and a non-display region SR. The display region DR is the region on the substrate D111 where the pixel array D112 is arranged, while the non-display region SR is the region of the substrate D111 outside the display region DR. The non-display region SR can further be divided into a bezel area BA and a circuit fan-out area FA. The bezel area BA is used for applying the seal gum, and the circuit fan-out area FA is designated for configuring scan driving circuits (e.g., D120) and/or data driving circuits (e.g., D130).

In some embodiments, the non-display region SR may be arranged in an offset manner on the substrate D111, meaning the widths of the non-display regions SR on opposite sides of the display region SR may differ. For example, as seen in FIG. 25A, the width of the non-display region SR on the lower side of the substrate D111 is greater than that on the upper side, where the lower non-display region SR can serve as the circuit fan-out area FA for the data driver circuit, though the application is not limited thereto. Additionally, the non-display regions SR on the left and right sides of the display region DR may be symmetrically configured, meaning both non-display regions SR have the same width.

On the other hand, from the relative arrangement of the pixel array substrate D110, the bezel area BA is closer to the edge of the substrate D111 compared to the circuit fan-out region FA. In other words, the circuit fan-out region FA is closer to the display region DR than the bezel area BA.

In this embodiment, the pixel array substrate D110 includes not only the substrate D111 and the pixel array D112 but also an electrostatic protection structure D113, which is formed by a metal stripe pattern on the substrate D111. The metal stripe pattern surrounds the perimeter of the substrate D111 and is at least partially located within the bezel area BA, forming an annular structure with an opening. In other words, when the sealant is applied to the display panel, at least a portion of it will be applied to the area where the electrostatic protection structure is arranged.

Taking FIG. 25A as an example, the metal stripe pattern of the electrostatic protection structure D113 surrounds the left, top, and right sides of the substrate D111. Only the side regions of the lower side of the substrate D111 are provided with the metal stripe pattern, while the central region of the lower side is not, the area where no metal stripe pattern is arranged is the opening of the annular structure. However, the application is not limited thereto.

To ensure the effectiveness of electrostatic discharge, in some embodiments, the width of the metal stripe pattern is greater than or equal to 40 micrometers. Additionally, to prevent damage to the electrostatic protection structure D113 during the cutting of the display panel, in some embodiments, the metal stripe pattern may be spaced from the edge of the substrate D111 (e.g., by 20 millimeters).

In the process of sealant application and lamination for the display panel using the pixel array substrate D110, when the UV light source irradiates the display panel from the backside of the pixel array substrate D110, the electrostatic discharge structure D113, made of opaque metal, blocks some of the UV light that aids in curing the sealant, reducing the curing rate and thereby compromising the display performance of the liquid crystal display panel.

Please refer to FIG. 25B. The pixel array substrate D110′ of this embodiment is similar to the pixel array substrate D110 shown in the aforementioned FIG. 25A. The main difference between the two lies in the design of the electrostatic protection structure D113′ in this embodiment, which differs from the electrostatic protection structure D113 of the previous embodiment.

Specifically, the electrostatic protection structure D113′ in this embodiment is also exemplified as being formed by a metal stripe pattern surrounding the substrate D111. The primary difference from the electrostatic protection structure D113 is that the metal stripe pattern of the electrostatic protection structure D113′ includes a plurality of light-transmitting parts TRP. These light-transmitting parts TRP can be made of a transparent conductive material (e.g., ITO) and are sequentially spaced along the extending direction of the metal stripe pattern, allowing the electrostatic protection structure D113′ to form an annular structure with holes created by the light-transmitting parts TRP in appearance.

Through the design of the electrostatic protection structure D113′, during the curing of the sealant, UV light irradiated from the backside of the substrate D111 can pass through the light-transmitting parts TRP to reach the sealant on the front side of the substrate D111, thereby improving the curing rate of the sealant. This further enhances the yield and reliability of panel assembly. Additionally, since the light-transmitting parts TRP of the electrostatic protection structure D113′ are made of a transparent conductive material, they do not reduce the equivalent area of the metal stripe pattern. Thus, the electrostatic dissipation capability of the electrostatic protection structure can be maintained without being compromised by the presence of the light-transmitting parts TRP.

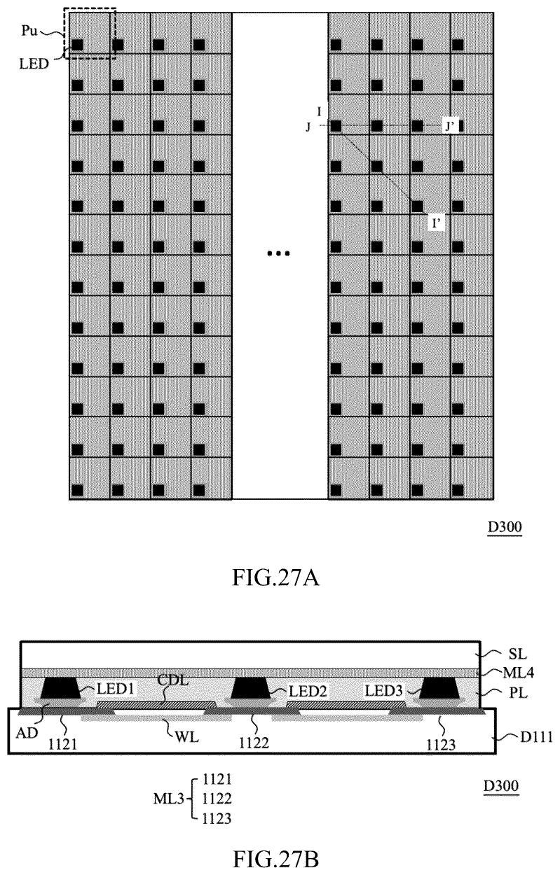

Below, FIGS. 26A and 26B are further used to illustrate the design of the electrostatic protection structure D113′ in the embodiment of the present application. FIG. 26A is a top view of the pixel array substrate D210 in the embodiment of the present application, and FIG. 26B is a partial cross-sectional view of the pixel array substrate D210 in the embodiment of the present application.

Please first refer to FIG. 26A. The configuration of the pixel array substrate D210 in this embodiment is similar to the pixel array substrate D110′ in the previous embodiment. The pixel array substrate D210 includes a substrate D211 and an electrostatic protection structure D213. The region of the substrate D211 configured with the pixel array is the display region DR, and the region of the substrate D211 other than the display region DR is the non-display region SR. Within the non-display region SR, it can be divided into the bezel area BA, the scan circuit fan-out area GFA, and the data circuit fan-out area DFA. The bezel area BA is the area used for applying sealant, the scan circuit fan-out area GFA is the area for configuring the scan driving circuit (e.g., D120), and the data circuit fan-out area DFA is the area for configuring the data driving circuit (e.g., D130). The bezel area BA includes a first bezel area BA1 and a second bezel area BA2 located on opposite sides of the substrate D211, as well as a third bezel area BA3 located between the first bezel area BA1 and the second bezel area BA2.

In this embodiment, the electrostatic protection structure D213 includes a first metal stripe pattern MSP1, a second metal stripe pattern MSP2, and a third metal stripe pattern MSP3. The first metal stripe pattern MSP1 is configured in the first bezel area BA1, the second metal stripe pattern MSP2 is configured in the second bezel area BA2, and the third metal stripe pattern MSP3 is configured in the third bezel area BA3.

Specifically, the first metal stripe pattern MSP1, the second metal stripe pattern MSP2, and the third metal stripe pattern MSP3 are electrically connected to each other to form a metal pattern surrounding the first to third bezel areas BA1-BA3. In this embodiment, the first metal stripe pattern MSP1, the second metal stripe pattern MSP2, and the third metal stripe pattern MSP3 are continuously and integrally formed, although the present application is not limited thereto.

Please also refer to FIGS. 26A and 26B. In this embodiment, the electrostatic protection structure D213 is, for example, composed of the metal layer ML1, the insulating layer IL1, the transparent conducting layer TC, the metal layer ML2, and the insulating layer IL2 that are arranged in a stacked manner, thereby forming the aforementioned first to third metal stripe patterns MSP1-MSP3.

Taking the cross-sectional structure of the first metal stripe pattern MSP1 along the cutting line HH′ as an example, as shown in FIG. 26B, the metal layer ML1 and the second metal layer ML2 of the electrostatic protection structure D213 will have a porous structure, causing the metal layer ML1 and the second metal layer ML2 to form a discontinuous island structure in their cross-sectional profile. At least some of these island structures are arranged sequentially at approximately fixed intervals. The spacing between adjacent island structures forms the aforementioned porous structure.

It should be noted here that although the cross-section along the cutting line HH′ shows the island structures in the metal layer ML1/second metal layer ML2 as independent from each other, in reality, the island structures in the metal layer ML1/second metal layer ML2 are electrically connected on different cross-sections, thereby forming the porous structure. This porous structure corresponds to the shape of the light-transmitting part TRP. FIG. 26A uses rectangular pores as an example, but the present application is not limited thereto.

The metal layer ML1 is formed on the first side of the substrate D211 (the upper side of the substrate in the direction shown in FIG. 26B). The insulating layer IL1 is formed and covers the metal layer ML1, and the transparent conducting layer TC is formed on the insulating layer IL1 and electrically connected to the second metal layer ML2. The gap region (i.e., the porous structure) between the island structures in the metal layer ML1 and the second metal layer ML2, along with the insulating layer IL1, the transparent conducting layer TC, and the insulating layer IL2 covering these gap region, forms the light-transmitting part TRP of the electrostatic protection structure D213.

When the display panel undergoes the bezel bonding process, the sealant FP is applied onto the insulating layer IL2, and UV light is irradiated from the second side of the substrate D211 (the lower side of the substrate in the direction shown in FIG. 26B) toward the first side. At this time, UV light can pass through each light-transmitting part TRP in the electrostatic protection structure D213 to reach the sealant FP, causing the sealant FP to undergo a curing reaction in response to the UV light.

Compared to traditional electrostatic discharge ring designs, the structural design of the electrostatic protection structure D213 in this embodiment reduces large-area metal shielding, allowing UV light to pass through the light-transmitting part TRP and reach the coating area of the sealant FP. This results in higher UV light transmittance, better assisting in the curing of the sealant.

In some embodiments, the metal layer ML1 and the second metal layer ML2 may have different widths in the cross-sectional direction of the metal stripe pattern (e.g., the direction of the cross-section HH′). As shown in FIG. 26B, the metal layer ML1 of this embodiment has a first width W1 in the direction of the cross-section HH′, and the second metal layer ML2 has a second width W2 in the direction of the cross-section HH′, where the first width W1 is greater than the second width W2.

In some embodiments, the ratio (W2/W1) of the second width W2 to the first width W1 may, for example, range between ½ and ⅔, but the present application is not limited thereto. In some embodiments, the first width W1 may, for example, range from 50 mm to 70 mm, preferably 60 mm; the second width W2 may, for example, range from 30 mm to 50 mm, preferably 40 mm, but the present application is similarly not limited thereto.

More specifically, the portion of the electrostatic protection structure D213 of this embodiment that has the two metal layers ML1 and ML2 may be referred to as the inner ring structure ER1, and the portion of the electrostatic protection structure D213 that has only the single metal layer ML1 may be referred to as the outer ring structure ER2. The aforementioned first width W1 is the sum of the width of the inner ring structure ER1 and the width of the outer ring structure ER2, while the aforementioned second width W2 is the width of the inner ring structure ER1.

Compared to traditional electrostatic discharge ring designs, the electrostatic protection structure D213 with the inner ring structure ER1 and the outer ring structure ER2 has a greater width in the cross-sectional direction, meaning the outer ring structure ER2 extends closer to the edge of the substrate D211. This increases the effective conducting area of the electrostatic protection structure D213, thereby further enhancing its electrostatic dissipation capability.

On the other hand, in some embodiments, within the regions of the first metal stripe pattern MSP1, the second metal stripe pattern MSP2, or the third metal stripe pattern MSP3, the metal layer ML1 and the second metal layer ML2 are electrically independent of each other, i.e., they are isolated by the insulating layer IL1. The metal layer ML1, the second metal layer ML2, and the transparent conducting layer TC are electrically connected only in the bridge region BR of the electrostatic protection structure D213.

In other words, the inner ring structure ER1 (primarily composed of a metal layer ML1, a transparent conducting layer TC, and a second metal layer ML2) and outer ring structure ER2 (mainly consisting of a metal layer ML1) of the electrostatic protection structure D213 are electrically connected only through the bridge region BR located below the substrate D211. This way, during the cutting of the pixel array substrate D210, even if the outer ring structure ER2 is damaged by the cutting blade wheel due to cutting errors, the electrostatic protection structure D213 will still retain the inner ring structure ER1 to maintain a certain level of electrostatic dissipation capability, thereby reducing the risk of the cutting blade wheel compromising the panel's electrostatic protection performance.

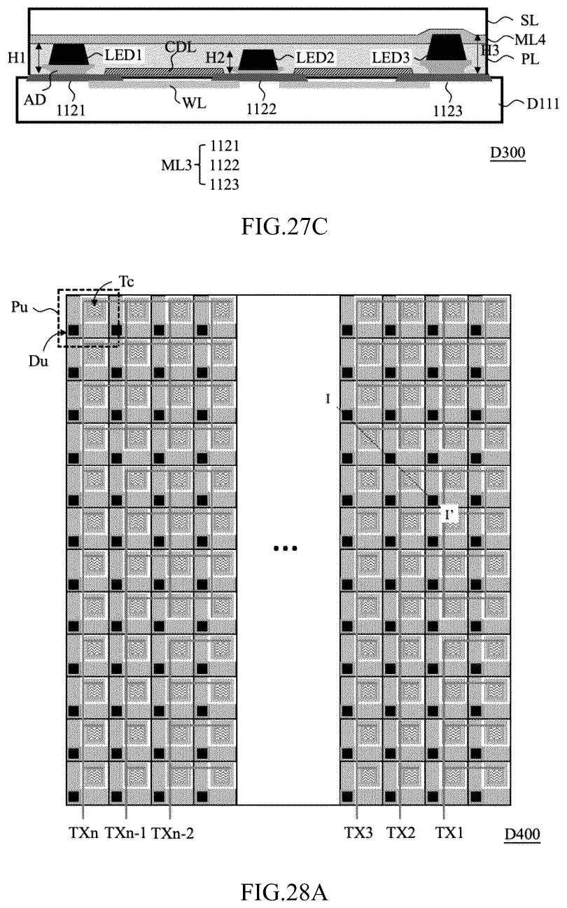

FIGS. 27A to 27C are schematic diagrams illustrating a configuration of a display panel. Referring first to FIG. 27A, in the display panel D300 of this embodiment, each pixel unit Pu may correspond to a light-emitting element LED, which could be, for example, a white-light light-emitting diode or blue-light light-emitting diode, though the application is not limited thereto. The light-emitting element LED may be a sub-millimeter light-emitting diode (mini-LED), micro light-emitting diode (micro-LED), or organic light-emitting diode (OLED), but the application is not restricted to these. In other embodiments, the light-emitting element LED may also be of other sizes and/or types. Depending on the type of light-emitting element selected, the display panel D300 could be, for example, a ULED panel, a mini-LED panel, a micro-LED panel, or an OLED panel, though the application is not limited thereto.

In some embodiments, each pixel unit Pu may include a plurality of sub-pixels, such as a first sub-pixel R, a second sub-pixel g, and a third sub-pixel B. The first sub-pixel R, the second sub-pixel G, and the third sub-pixel B are respectively controlled to emit light of different wavelengths. For example, the first sub-pixel R may include a light-emitting element with a red light wavelength range (e.g., 610 nm-720 nm), the second sub-pixel G may include a light-emitting element with a green light wavelength range (e.g., 520 nm-610 nm), and the third sub-pixel B may include a light-emitting element with a blue light wavelength range (e.g., 400 nm-520 nm). In some embodiments, the light-emitting elements of the first sub-pixel R, the second sub-pixel G, and the third sub-pixel B may respectively be a red light-emitting diode (or, in other words, a diode emitting light in the red wavelength range), a green light-emitting diode (or, in other words, a diode emitting light in the green wavelength range), and a blue light-emitting diode (or, in other words, a diode emitting light in the blue wavelength range). Similarly, the light-emitting elements of each sub-pixel R/G/B may be mini-LEDs or micro-LEDs, but the present application is not limited thereto.

Please refer to FIG. 27B, which is a schematic cross-sectional view of the display panel D100 along the section line II′. In this embodiment, the display panel D300 includes light-emitting elements LED1-LED3, a substrate D111, a metal layer ML3, a protective layer PL, a metal layer ML4, a sealing layer SL, a wiring layer WL, a bonding part AD, and an isolation layer CDL. The metal layer ML3 includes first electrode regions 1121, 1122, and 1123 formed on the substrate D111, where each electrode region 1121-1123 is electrically connected to one another via the corresponding wiring layer WL. The light-emitting elements LED1-LED3 are respectively disposed on the first electrode regions 1121-1123 of the metal layer ML3, where each light-emitting element LED has two electrodes located on opposite sides of the light-emitting elements LED1-LED3. The electrode (or lower electrode) on the side of each light-emitting element LED1-LED3 closer to the metal layer ML1 (or the lower side) is electrically connected to the corresponding first electrode region 1121-1123 via the bonding part AD. The protective layer PL is filled between the light-emitting elements LED1-LED3 and covers at least a portion of the surface of each light-emitting element LED1-LED3 to prevent unintended short circuits between them. The protective layer PL at least exposes the electrode (or upper electrode) on the other side of the light-emitting elements LED1-LED3 (i.e., the side away from the metal layer ML3, or the upper side). The metal layer ML4 is disposed on the protective layer PL and electrically connected to the upper electrodes of the light-emitting elements LED1-LED3. The light-emitting elements LEDs can receive driving signals to control their illumination through the metal layer ML3 and metal layer ML4. The sealing layer SL is formed and covers the metal layer ML4.

Specifically, in the embodiment of FIG. 27B, the light-emitting elements LED1-LED3 may, for example, be vertically packaged light-emitting diodes, where the electrodes of each diode are positioned on opposite sides, thus enabling the reception of driving signals through the metal layers ML3 and ML4 located on both sides of the light-emitting elements LED1-LED3.

In short, in the configuration of the display panel 100 in this embodiment, the first electrode regions 1121-1123 of the metal layer ML3 can be regarded as the lower electrodes of the light-emitting elements LED1-LED3 (hereinafter referred to as lower electrodes 1121-1123), while the metal layer ML4, which is fully connected to each light-emitting element LED1-LED3, can be regarded as the upper electrode of the light-emitting elements LED1-LED3 (hereinafter referred to as upper electrode ML4). Therefore, the driver chip 140 can provide signals through the upper electrode ML2 and the corresponding lower electrodes 1121-1123 of the light-emitting elements LED1-LED3 to control the illumination states of the light-emitting elements LED1-LED3.

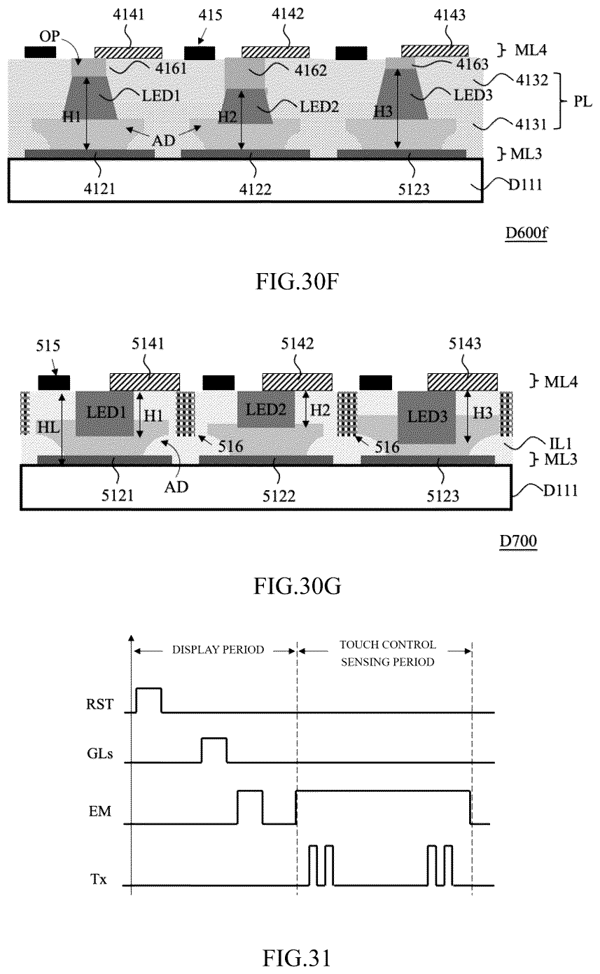

In the display panel D300 with vertically packaged light-emitting elements as shown in FIGS. 27A and 27B, to achieve an In-cell embedded touch control design, the upper and lower electrodes of each pixel unit Pu must serve as touch control electrodes for sensing capacitance changes during touch. This means the display panel D300 needs to share the upper and lower electrodes to separately achieve display and touch control functions. To enable electrode sharing, each driving cycle of the display panel D300 must be further divided into a display period and a touch control sensing period, as illustrated in FIG. 31.

In this embodiment, the display panel D300 responds to a reset signal RST to enter the display period. During the display period, the driver chip 140 provides display scan signals GLs through the upper and lower electrodes to sequentially control the lighting state of the pixel units Pu, enabling image display on the display panel 100. After the display period ends, the display panel 100 responds to a control signal EM to enter the touch control sensing period (which can also be regarded as the display blanking period within the driving cycle). During the touch control sensing period, each pixel unit Pu can be treated as a touch control sensing unit, receiving the touch scan signal TX from the touch control sensing chip (not shown) and sending back sensing signals related to electrical changes in the display panel D300 to the touch control sensing chip, thereby determining whether a touch event has occurred.

Under this control method, the driving of the display panel D300 requires periodic switching between the display period and the touch control sensing period, forcing a trade-off between pixel charging time and touch sensing time of the display panel, which complicates the driving timing design. Additionally, if the frame per second (FPS) of the display panel D300 is to be increased, the reduction in the display blanking period will inevitably lead to a decline in touch sensing sensitivity.

Furthermore, in the manufacturing process of touch control display panels using vertically packaged light-emitting elements LED1-LED3, the actual size and arrangement of each light-emitting element LEDs vary, causing the positions of the upper electrodes of each light-emitting element LEDs to be uneven and not on the same plane, as shown in FIG. 27C, which is a schematic cross-sectional view of the display panel D300 along the cutting line JJ′.

Please refer to FIG. 27C. On the left side of FIG. 27C, the light-emitting element LED1 is in an ideal configuration, meaning that when LED1 is mounted on the substrate D111 via the bonding part AD and connected to the first electrode region 1211 (or referred to as a lower electrode lead), the height H1 of both the bonding part AD and the light-emitting element LED1 (i.e., the shortest distance from the upper surface of the first electrode region 1121 to the top of LED1) is approximately equal to the height of the protective layer PL. This ensures that the upper electrode of LED1 is exposed and aligns roughly with the upper edge of the protective layer PL (i.e., the upper electrode and the upper surface of the protective layer PL lie approximately on the same plane). Therefore, under ideal conditions, the metal layer ML4 formed on the protective layer PL can easily establish an electrical connection with the exposed upper electrode, and the metal layer ML4 in the electrode region of LED1 can maintain a uniform line width to ensure proper signal transmission.

The light-emitting elements LED2 and LED3 illustrate configurations that may frequently occur in practice. In the case of LED2, both the element itself and its corresponding bonding part AD are slightly shorter in height compared to LED1 and its bonding part AD. As a result, the overall height H2 of the bonding part AD and LED2 is less than that of the protective layer PL (i.e., approximately a height H1), causing the protective layer PL to cover the upper electrode of the light-emitting element LED2 during formation. Consequently, since the upper electrode of LED2 is obscured by the protective layer PL, the metal layer ML4 cannot effectively connect electrically to it, preventing LED2 from receiving the driving signal to illuminate. The configuration of LED2 can be regarded as an over-low-arranged state.

In the configuration of LED3, the height of the light-emitting element LED3 is slightly greater than that of LED1, resulting in the overall height H3 of the bonding part AD and LED3 exceeding the height of the protective layer PL (i.e., approximately a height H1). This causes the upper side of LED3 to protrude beyond the upper surface of the protective layer PL, placing the upper electrode of LED3 and the upper surface of the protective layer PL on different planes. As a result, when forming the metal layer ML4 on the protective layer PL, since the upper electrode of LED3 is higher than the upper surface of the protective layer PL, the metal layer ML4 must bend to extend and connect electrically to the upper electrode of LED3. The line width at the bend (here referring to the width of ML4 in the x-z plane) becomes thinner, increasing the risk of wire breakage and disrupting signal transmission. The configuration of LED3 can be regarded as an over-high-arranged state.

As mentioned above, under the structural configuration of a conventional display panel, the thickness of light-emitting elements LED1-LED3 may vary during actual manufacturing, and the corresponding bonding parts ADs may also form different thicknesses/heights during the process. The cumulative differences in these processes and materials during the encapsulation of the display panel 100 can result in varying heights (e.g., H1-H3) for the upper electrodes of each light-emitting element LED1-LED3, thereby causing the aforementioned poor connectivity issues when the metal layer ML4 is formed/placed.

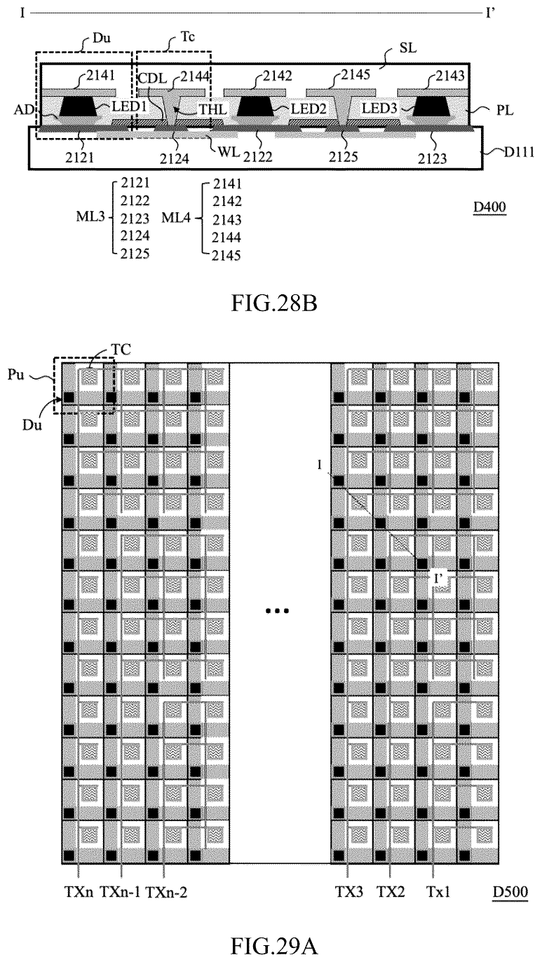

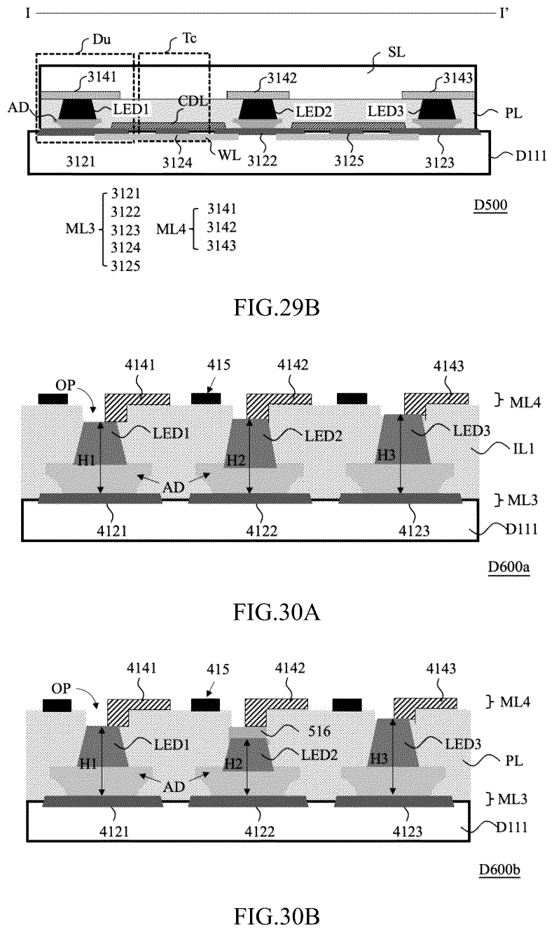

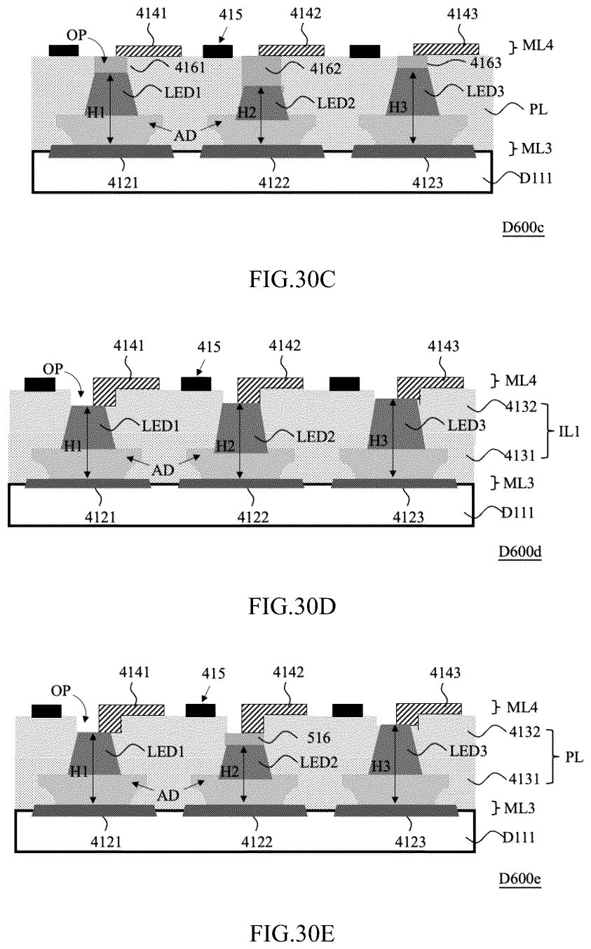

To address the above issues, the present application proposes several new structural designs for display panels, as shown in FIGS. 28A to 30G. The designs in the embodiments of FIGS. 28A to 29B can form independent electrodes within the display panel for touch control sensing, allowing the signal timing during display and touch sensing periods to operate independently, avoiding the need for trade-offs, and thereby achieving cost efficiency and reducing the complexity of touch signal processing. The designs in the embodiments of FIGS. 30A to 30G can be used to achieve surface planarization of the display panel.

Referring first to FIGS. 28A and 28B, the display panel D400 of this embodiment includes a plurality of pixel units Pu arranged in an array, where each pixel unit Pu includes a display unit Du and a touch control sensing unit Tc, and each display unit Du contains a light-emitting element (e.g., LED1-LED3). From the cross-sectional structure along the cutting line II′ in FIG. 28B, the display panel D400 includes light-emitting elements LED1-LED3, a substrate D111, a metal layer ML3, a protective layer PL, a metal layer ML4, a sealing layer SL, a wiring layer WL, a bonding part AD, and an isolation layer CDL. The metal layer ML3 includes first electrode regions 2121, 2122, and 2123 and second electrode regions 2124 and 2125 formed on the substrate D111, where the first electrode regions 2121-2123 are electrically connected to each other via corresponding wiring layers WL, while the second electrode regions 2124 and 2125 remain electrically independent from the first electrode regions 2121-2123. Structurally, the first electrode regions 2121-2123 and the second electrode regions 2124 and 2125 are alternately spaced, meaning that each pair of adjacent first electrode regions 2121-2123 is separated by a second electrode region 2124 or 2125. For example, the second electrode region 2124 is placed between the first electrode regions 2121 and 2122, and the second electrode region 2125 is placed between the first electrode regions 2122 and 2123.

The light-emitting elements LED1-LED3 are respectively disposed on the first electrode regions 2121-2123 of the metal layer ML3, wherein each light-emitting element LED1-LED3 has two electrodes located on opposite sides of the element. The electrode (or lower electrode or first electrode) on the side of each light-emitting element LED1-LED3 closer to the metal layer ML3 (or referred to as the lower side) is electrically connected to the corresponding first electrode region 2121-2123.

The protective layer PL is filled between the light-emitting elements LED1-LED3 and covers at least a portion of the surface of each element to prevent unintended short circuits between them. The protective layer PL at least ensures that the electrode (or upper electrode or second electrode) on the other side of the light-emitting elements LED1-LED3 (i.e., the side away from the first metal layer 212, or referred to as the upper side) remains exposed.

The metal layer ML4 includes third electrode regions 2141, 2142, and 2143 and fourth electrode regions 2144 and 2145 formed on the protective layer PL. The third electrode regions 2141-2143 are electrically connected to the upper electrodes of the corresponding light-emitting elements LED1-LED3, respectively. In other words, the first electrode region 2121 and the third electrode region 2141 serve as the upper and lower electrodes of the light-emitting element LED1 to receive driving signals, the first electrode region 2122 and the third electrode region 2142 serve as the upper and lower electrodes of the light-emitting element LED2, and the first electrode region 2123 and the third electrode region 2143 serve as the upper and lower electrodes of the light-emitting element LED3.

In this embodiment, the protective layer PL forms through holes THL in the regions corresponding to the second electrode regions 2124 and 2125. As a result, the fourth electrode regions 2144 and 2145 of the second metal layer 214 not only include a first portion formed on the upper side of the protective layer 213 and spaced apart from the third electrode regions 2141-2143 but also a second portion that extends through the through holes THL to be electrically connected to the second electrode regions 2124 and 2125.

Specifically, taking the configuration of the light-emitting element LED1 as an example, the portion of the substrate D111 configured for the LED1, along with the first electrode region 2121 and the third electrode region 2141 electrically connected to LED1, form a display unit Du. The second electrode region 2124 and the fourth electrode region 2144 constitute a touch control sensing unit Tc adjacent to the display unit Du where LED1 is located along the cutting line II′. The structural arrangement of the corresponding display unit Du and touch control sensing unit Tc is replicated in each pixel unit Pu.

On the other hand, from the top-view structure in FIG. 28A, this embodiment illustrates an example with 12 rows of pixel units Pu (though the application is not limited thereto). Each touch control sensing unit Tc is electrically connected to the touch control sensing chip via its corresponding touch control scan lines TX1-TXn. In some embodiments, adjacent touch control scan lines TX1-TXn have different connection configurations, and every x touch control scan lines TX1-TXn may exhibit a repeated connection configuration, where x is a natural number. For instance, the touch control scan line TX1 is electrically connected to 8 touch control sensing units Tc in rows 9 to 12 of the 2 rightmost columns of the display panel D400; the touch control scan line TX2 is electrically connected to 12 touch control sensing units Tc in rows 5 to 8 of the 3 rightmost columns and 4 touch control sensing units Tc in rows 9 to 12 of the 3rd rightmost column (i.e., the remaining 16 touch control sensing units Tc in rows 5 to 12 of the 3 rightmost columns, excluding the aforementioned 8 connected to TX1); and the touch control scan line TX3 is electrically connected to 16 touch control sensing units Tc in rows 1 to 4 of the 4 rightmost columns and 8 touch control sensing units Tc in rows 5 to 12 of the 4th rightmost column (i.e., the remaining 24 touch control sensing units Tc in the 4 rightmost columns, excluding the 8 connected to TX1 and the 16 connected to TX2). The arrangement in other regions follows similarly and will not be reiterated here.

More specifically, the cross-sectional structure of the display panel D400 in this embodiment along the cutting line II′ is largely the same as that in the embodiments of FIGS. 27A and 27B. The main difference between this embodiment and the previous ones lies in the addition of second electrode regions 2124 and 2125 in the first metal layer 212, which are electrically independent of the lower electrodes of the light-emitting elements LED1-LED3. Moreover, compared to the metal layer ML4 in the previous embodiments, the metal layer ML4 in this embodiment is etched to form fourth electrode regions 2144 and 2145, which are electrically independent of the upper electrodes of the light-emitting elements LED1-LED3. The interconnected second electrode region 2124 and fourth electrode region 2144 form a touch electrode in one touch control sensing unit Tc, while the interconnected second electrode region 2125 and fourth electrode region 2145 form a touch electrode in another touch control sensing unit Tc. In other words, this embodiment configures the second electrode regions 2124 and 2125 and the fourth electrode regions 2144 and 2145 to form touch control sensing units Tc that do not interfere with the display units Du.

Therefore, under the architecture of the display panel D400 in this embodiment, the display units Du and touch control sensing units Tc can be controlled for display and touch sensing via their respective scan lines without having to compromise between display and touch sensing durations in each driving cycle. This effectively reduces the complexity of timing control design and ensures that touch sensing sensitivity does not degrade with lower refresh rates.

In some embodiments, when viewed from the top, the first electrode regions 2121-2123 may, for example, be square regions with side lengths of approximately 10 μm, and the spacing between adjacent first electrode regions may be about 25 μm. In other words, the side lengths of the second electrode regions 2124 and 2125 and the fourth electrode regions 2144 and 2145 will range between 10 μm and 25 μm, but the present application is not limited thereto.

Please refer to FIGS. 29A and 29B. The display panel D500 of this embodiment includes a plurality of pixel units Pu arranged in an array, where each pixel unit Pu includes a display unit Du and a touch control sensing unit Tc. Each display unit Du contains a light-emitting element (such as LED1-LED3). From the cross-sectional structure along the cutting line II′ in FIG. 29B, the display panel D500 includes light-emitting elements LED1-LED3, a substrate 311, a metal layer ML3, a protective layer PL, a metal layer ML4, a sealing layer SL, a wiring layer WL, a bonding part AD, and an isolation layer CDL. The metal layer ML3 includes first electrode regions 3121, 3122, and 3123 and second electrode regions 3124 and 3125 formed on the substrate 311. The first electrode regions 3121-3123 are electrically connected to each other via corresponding wiring layers WL, while the second electrode regions 3124 and 3125 remain electrically independent from the first electrode regions 3121-3123.

Specifically, the display panel D500 of this embodiment is largely similar in structural configuration to the display panel D400 in the aforementioned FIGS. 28A and 28B. The main difference lies in the metal layer ML4 of the display panel D500, where the metal layer adjacent to the third electrode regions 3141-3143 is removed. This ensures that the second electrode regions 3124 and 3125 of the underlying metal layer ML3 are not shielded by the overlying metal layer ML4. Consequently, when a user's finger touches the corresponding position of the display panel D500, the finger capacitance can be directly coupled to the second electrode regions 3124 and 3125 of the metal layer ML3 to be detected. In other words, the primary structural difference between the display panel D500 of this embodiment and the display panel D400 of the previous embodiment is that the metal layer ML4 here does not include fourth electrode regions (such as 2144 and 2145) electrically connected to the second electrode regions 3124 and 3125. Thus, there is no need to form a through hole THL structure similar to that in FIG. 28B on the protective layer PL. Other similar aspects can be referred to the description in the aforementioned embodiment and will not be reiterated here.

Overall, the embodiments in FIGS. 28A to 29B respectively demonstrate a straightforward implementation of an independent touch electrode architecture by adding separate electrode regions (i.e., the second electrode regions 2124/2125/3124/3125) on the metal layer ML3 and adopting a segmented configuration for the metal layer ML4. In the architecture of these embodiments, the third electrode regions 2141-2143/3141-3143, which serve as the upper electrodes, do not obscure the regions of the touch control sensing unit Tc, allowing the capacitance changes caused by the touch panel to be coupled to the lower second electrode regions. In other words, in these embodiments, the orthographic projection regions of the third electrode regions 2141-2143/3141-3143 on the substrate D111 do not completely overlap with the orthographic projection regions of the second electrode regions 2124/2125/3124/3125 on the substrate 211/311 (i.e., at least partially non-overlapping). In some embodiments, the orthographic projection regions of the third electrode regions 2141-2143/3141-3143 on the substrate D111 and those of the second electrode regions 2124/2125/3124/3125 on the substrate D111 do not overlap at all.

FIGS. 30A to 30G are schematic cross-sectional views of the display panel structures in different embodiments of the present application. In some embodiments, when the protective layer of the display panel is formed, its thickness is designed to exceed the height of the light-emitting elements and their corresponding lower electrode leads and bonding parts, ensuring that the upper surface of the protective layer is higher than the upper electrodes of the light-emitting elements. Subsequently, specific processes (e.g., photolithography) are employed to expose the upper electrodes covered by the protective layer, creating an opening structure between each light-emitting element's upper electrode and the protective layer. This allows the upper electrode leads to electrically connect with the upper electrodes within the openings, achieving a flattened display panel structure (as shown in the embodiments of FIGS. 30A to 30F). In other embodiments, the light-emitting elements are subjected to a force toward the substrate during placement, where variations in their individual dimensions/heights result in different displacements and substrate spacings, thereby keeping the upper electrodes of the light-emitting elements on the same plane. This enables the display panel to form a smooth surface, facilitating the placement of upper electrode leads and electrical connections with each light-emitting element, thus realizing a flattened display panel structure (as shown in the FIG. 30G embodiment). The structures of the embodiments in FIGS. 30A to 30G are described in detail below.

Please first refer to FIG. 30A. The display panel D600a of this embodiment includes a substrate D111, a metal layer ML3, a plurality of light-emitting elements LED1-LED3, a metal layer ML4, and a light-shielding part 415. The metal layer ML3 is disposed on the substrate D111. The light-emitting elements LED1-LED3 are respectively arranged on the metal layer ML3 via corresponding bonding parts AD, so that the lower electrodes of the light-emitting elements LED1-LED3 are electrically connected to the metal layer ML3 through the bonding parts AD. A protective layer PL is formed on the substrate D111, covering the metal layer ML3, the bonding parts AD, and the peripheral regions of the light-emitting elements LED1-LED3, thereby preventing unintended short circuits between adjacent light-emitting elements LED1-LED3. The protective layer PL exposes at least part or all of the upper electrodes of the light-emitting elements LED1-LED3, and the height/thickness of the protective layer PL on the substrate D111 is greater than or equal to the corresponding heights H1-H3 of any of the light-emitting elements LED1-LED3, forming an opening OP on at least one or more of the light-emitting elements LED1-LED3. The height H1-H3 corresponding to any of the light-emitting elements LED1-LED3 may, for example, be the total height/thickness of the light-emitting element and its corresponding metal layer ML3 and bonding part AD. The metal layer ML4 is disposed on the protective layer PL and extends toward the opening OP to electrically connect to the upper electrodes of each light-emitting element LED1-LED3 through the opening OP.

More specifically, the metal layer ML3 includes lower electrode leads 4121-4123, and the metal layer ML4 includes upper electrode leads 4141-4143. The lower electrodes of the light-emitting elements LED1-LED3 are electrically connected to the lower electrode leads 4121-4123 through the corresponding bonding parts AD, respectively, while the upper electrodes of the light-emitting elements LED1-LED3 are electrically connected to the upper electrode leads 4141-4143 in the corresponding openings OP. Through this configuration, the light-emitting elements LED1-LED3 with varying heights H1-H3 can achieve optimal electrical connectivity via the upper electrode leads 4141-4143 extending into the openings OP, avoiding poor connections as described in FIG. 27C due to elements being configured too low (e.g., LED2) or too high (e.g., LED3). Additionally, since the height differences among the light-emitting elements LED1-LED3 can be compensated to the same level by the upper electrode leads 4141-4143 extending into the openings, the overall upper electrode lead 4141 (including the line segments on the upper surface of the protective layer PL) can maintain a uniform line width. This ensures reliable signal transmission while mitigating process risks such as broken leads or poor contacts caused by bending routing.

In other words, with the structural configuration shown in FIG. 30A, the upper surfaces of all light-emitting elements LED1-LED3 can be maintained at essentially the same level without height discrepancies. As a result, subsequent processes will not be affected by the flatness of the display panel, thereby effectively improving process yield and reliability.

In this embodiment, the substrate D111 may be a flexible or rigid substrate such as a printed circuit board, glass substrate, or thin-film substrate. Depending on the material selected and the intended application, the substrate D111 can be transparent or opaque, which is not limited in the present application.

In some embodiments, the material of the bonding part AD can be any material capable of providing adhesion to stably bond the light-emitting elements LED1-LED3 and the metal layer ML3, such as solder paste, anisotropic conductive film (ACF), or other adhesive materials. Additionally, the bonding process for placing the light-emitting elements LED1-LED3 on the metal layer ML3 via the bonding part AD can be implemented through methods like screen printing, inkjet printing (IJP), or exposure development followed by baking, though the present application is not limited thereto.

Referring to FIG. 30B, the display panel D600b of this embodiment is largely similar to that in FIG. 30A, including a substrate D111, a metal layer ML3, a plurality of light-emitting elements LED1-LED3, a metal layer ML4, and a light-shielding part 415. Descriptions of related components/configurations can refer to the embodiment in FIG. 30A and will not be repeated here.

The main difference between this embodiment and the previous FIG. 30A embodiment is that the display panel D600b further includes a conductive extension part 416. The conductive extension part 416 is placed within the opening OP corresponding to the light-emitting element LED2 and is electrically connected to the upper electrode of LED2. The height of the conductive extension part 416 is less than or equal to the depth of the opening OP of LED2, and the upper electrode lead 4142 is electrically connected to the upper electrode of LED2 via the conductive extension part 416.

Specifically, in this embodiment, the light-emitting element LED2 is in an overly low configuration (H2<H1), and its height may be insufficient for the upper electrode lead 4142 to directly extend through the opening OP to connect to LED2's upper electrode. In this case, by adding the conductive extension part 416, the equivalent height of LED2 (i.e., the sum of height H2 and the height of the conductive extension part 416) is increased, enabling the upper electrode lead 4142 to be electrically connected to LED2's upper electrode via the conductive extension part 416.

It should be noted that the conductive extension part 416 in this embodiment may only be placed in the openings of light-emitting elements with insufficient height. Other light-emitting elements that can directly connect to the upper electrode leads do not require such a configuration.

Please refer to FIG. 30C. The display panel D600c of this embodiment is largely the same as those in FIGS. 30A and 30B, including a substrate D111, a metal layer ML3, a plurality of light-emitting elements LED1-LED3, a metal layer ML4, and a light-shielding part 415. Descriptions of related components/configurations can be found in the embodiments of FIGS. 30A and 30B above and will not be repeated here.

The main difference between this embodiment and the previous FIG. 30B embodiment lies in the display panel D600c including a plurality of conductive extension parts 4161-4163, each corresponding to the light-emitting elements LED1-LED3. Here, the conductive extension parts 4161-4163 are respectively disposed within the openings OP of the light-emitting elements LED1-LED3 and electrically connected to the upper electrodes of the corresponding light-emitting elements LED1-LED3.

In this embodiment, each conductive extension part 4161-4163 fills the corresponding opening CP, ensuring that the upper surfaces of the conductive extension parts 4161-4163 and the upper surface of the protective layer are substantially coplanar. In other words, the heights H1-H3 of each light-emitting element LED1-LED3 plus the heights of the corresponding conductive extension parts 4161-4163 will equal the height of the protective layer PL.

It should be noted here that the conductive extension parts 4161-4163 of this embodiment can be placed in the opening OP of each light-emitting element LED1-LED3, ensuring that the equivalent height of each light-emitting element LED1-LED3 matches the height of the protective layer PL. This allows the upper electrode leads 4141-4143 formed on the protective layer PL to extend horizontally and connect to the conductive extension parts 4161-4163, thereby electrically linking to the upper electrodes of the corresponding light-emitting elements LED1-LED3. As a result, the upper electrode leads 4141-4143 in this embodiment can maintain uniform line widths for optimal electrical signal transmission characteristics.

Please refer to FIG. 30D. The display panel D600d of this embodiment is largely the same as that in FIG. 30A, including a substrate D111, a metal layer ML3, a plurality of light-emitting elements LED1-LED3, a metal layer ML4, and a light-shielding part 415. Descriptions of related components/configurations can be found in the FIG. 30A embodiment above and will not be repeated here.

The main difference between this embodiment and the aforementioned FIG. 30A embodiment lies in that the protective layer PL of the display panel D600d includes a spacing part 4131 and a planarization part 4132. The spacing part 4131 is disposed on the substrate D111 and covers the metal layer ML3, the bonding part AD, and partial regions of the light-emitting elements LED1-LED3. The planarization part 4132 is arranged on the spacing part to cover another partial region of the light-emitting elements LED1-LED3 while exposing their upper electrodes. The total height of the spacing part 4131 and planarization part 4132 in this embodiment (i.e., the height of the protective layer PL) is set to be greater than or equal to the maximum height among the light-emitting elements LED1-LED3, so as to form an opening OP on at least one or part of the light-emitting elements LED1-LED3. The metal layer ML4 is disposed on the planarization part 4132 and electrically connected to the light-emitting elements LED1-LED3 through the opening OP.

Specifically, compared to the FIG. 30A embodiment, the protective layer PL in this embodiment can be implemented using a two-layer structure. The lower layer (the spacing part 4131) primarily provides insulation and support properties, while the upper layer (the planarization part 4132) mainly offers a flat upper surface and is made of a material that can be removed via specific processes, allowing the upper electrodes of the light-emitting elements LED1-LED3 to be exposed after the removal process. Thus, the structural configuration in FIG. 30D further enhances the surface flatness of the display panel D600d.

In some embodiments, the spacing part 4131 may be made of materials with filling and insulating properties, such as silicon nitride (SiNx), silicon oxide (SiOx), acrylic, epoxy, or silicon-based organic polymers, though the application is not limited thereto. On the other hand, the planarization part 4132 may be made of materials with superior post-coating surface flatness, such as acrylic, epoxy, or silicon-based organic polymers, among others, thought the application is similarly not limited thereto.

Referring to FIG. 30E, the display panel D600e in this embodiment is largely similar to those in FIGS. 30B and 30D, including a substrate D111, a metal layer ML3, a plurality of light-emitting elements LED1-LED3, a metal layer ML4, a light-shielding part 415, and a conductive extension part 416. Descriptions of related components/configurations can be found in the aforementioned FIGS. 30B and 30D embodiments and will not be repeated here.

The main difference between this embodiment and the aforementioned FIG. 30B embodiment is that the protective layer PL of the display panel D600e adopts the dual-layer structure shown in FIG. 30D, which includes the spacing part 4131 and planarization part 4132. For details on the configuration and materials of the spacing part 4131 and planarization part 4132, refer to the FIG. 30D embodiment above, and no further elaboration will be provided here.

Referring to FIG. 30F, the display panel D600f of this embodiment is largely the same as those in FIGS. 30C and 30D. It includes a substrate D111, a metal layer ML3, a plurality of light-emitting elements LED1-LED3, a metal layer ML4, a light-shielding part 415, and a plurality of conductive extension parts 4161-4163. For descriptions of related components/configurations, please refer to the embodiments in FIGS. 30C and 30D above, which will not be reiterated here.

The main difference between this embodiment and the aforementioned FIG. 30C embodiment lies in the protective layer PL of the display panel D600f, which adopts a dual-layer structure configuration as shown in FIG. 30D. This includes a spacing portion 4131 and a planarization part 4132. For details on the configuration and materials of the spacing portion 4131 and planarization part 4132, please refer to the FIG. 30D embodiment above, which will not be repeated here.

FIG. 30G is a schematic cross-sectional structure diagram of a display panel according to an embodiment of the present application. Referring to FIG. 30G, the display panel D700 in this embodiment includes a substrate D111, a metal layer ML3, a plurality of light-emitting elements LED1-LED3, a protective layer PL, a metal layer ML4, a light-shielding part 515, and a support part 516. The metal layer ML3 is disposed on the substrate D111. The light-emitting elements LED1-LED3 are respectively arranged on the metal layer ML3 via corresponding bonding parts AD, so that the lower electrodes of the light-emitting elements LED1-LED3 are electrically connected to the metal layer ML3 through the bonding parts AD. The protective layer PL is formed on the substrate D111 and covers the metal layer ML3, the bonding parts AD, and the peripheral regions of the light-emitting elements LED1-LED3, thereby preventing unintended short circuits between adjacent light-emitting elements LED1-LED3. The protective layer PL exposes at least part or all of the upper electrodes of the light-emitting elements LED1-LED3, and the height/thickness of the protective layer PL on the substrate D111 is approximately equal to the height HL corresponding to the light-emitting elements LED1-LED3. Here, the height HL corresponding to any of the light-emitting elements LED1-LED3 may, for example, be the total height/thickness of any light-emitting element LED1-LED3 and its corresponding metal layer ML3 and bonding part AD. The metal layer ML4 and the light-shielding part 515 are disposed on the protective layer PL and the upper electrodes of the light-emitting elements LED1-LED3, wherein the metal layer ML4 is electrically connected to the upper electrodes of each light-emitting element LED1-LED3. Additionally, between adjacent light-emitting elements LED1-LED3 in the protective layer PL, a support part 516 is provided. The support part 516 is used to provide resistance against applied forces during the process where the light-emitting elements LED1-LED3 are subjected to external forces, thereby defining the position of the upper electrodes of the light-emitting elements LED1-LED3. The upper side of the support part 516 and the upper electrodes of the light-emitting elements LED1-LED3 are approximately coplanar. In this embodiment, the support part 516 is, for example, columnar and has a height less than or equal to the lowest one of the light-emitting elements LED1-LED3, but the present application is not limited thereto.

More specifically, the metal layer ML3 includes lower electrode leads 5121-5123, and the metal layer ML4 includes upper electrode leads 5141-5143. The lower electrodes of the light-emitting elements LED1-LED3 are electrically connected to the corresponding lower electrode leads 5121-5123 via bonding parts AD, respectively. During the placement process, a planar force toward the substrate D111 is applied to the light-emitting elements LED1-LED3, causing their lower electrodes to embed into the bonding parts AD. Due to differences in their dimensions/heights, each light-emitting element LED1-LED3 embeds to varying depths in the bonding parts AD, resulting in corresponding variations in the spacing between the light-emitting elements LED1-LED3 and the substrate D111. For example, as shown in FIG. 30G, the height H1 of the light-emitting element LED1 is greater than the height H2 of the light-emitting element LED2. Thus, after the application of force, the spacing between the light-emitting element LED1 and the substrate D111 will be smaller than that of the light-emitting element LED2, ensuring that the sum of the height H1 of the light-emitting element LED1 and its corresponding spacing from the substrate D111 is approximately equal to the sum of the height H2 of the light-emitting element LED2 and its corresponding spacing from the substrate D111, i.e., equal to the height HL. Similarly, the height H1 of the light-emitting element LED1 is less than the height H3 of the light-emitting element LED3. Therefore, after the application of force, the spacing between the light-emitting element LED1 and the substrate D111 will be greater than that between the light-emitting element LED3 and the substrate D111, ensuring that the sum of the height H1 of the light-emitting element LED1 and its corresponding spacing from the substrate D111 is approximately equal to the sum of the height H3 of the light-emitting element LED3 and its corresponding spacing from the substrate D111.

With the above configuration, the light-emitting elements LED1-LED3 with varying heights H1-H3 will exhibit different substrate spacings, ensuring that the total height HL for each light-emitting element LED1-LED3 remains roughly consistent. This results in a flat surface on the display panel, thereby avoiding poor connections as described in FIG. 27C due to elements being placed too low (e.g., LED2) or too high (e.g., LED3). Furthermore, since the height differences H1-H3 among the light-emitting elements LED1-LED3 are compensated by varying substrate spacings to achieve the same height HL, the upper electrode leads 5141-5143 can maintain uniform line widths. This ensures reliable signal transmission while mitigating process risks such as broken lines or poor contacts caused by bending routing.

In other words, with the structural configuration described in FIG. 30G, the upper surfaces of all light-emitting elements LED1-LED3 can be maintained at the same level without height discrepancies. Consequently, subsequent processes will not be affected by the flatness of the display panel, effectively improving process yield and reliability.

In this embodiment, the substrate D111 may be a flexible or rigid substrate such as a printed circuit board, glass substrate, or thin-film substrate. Depending on the selected material and application requirements, the substrate D111 can be transparent or opaque, which is not limited in the present application.

In some embodiments, the material of the bonding part AD may be any material capable of providing adhesion to stably bond the light-emitting elements LED1-LED3 and the metal layer ML3, such as solder paste, anisotropic conductive film (ACF), or other adhesive materials. Additionally, the bonding process of placing the light-emitting elements LED1-LED3 on the metal layer ML3 via the bonding part AD may be implemented through screen printing bonding, inkjet printing (IJP) bonding, exposure development followed by baking, etc., which is not limited in the present application.

In summary, the display device and display panel proposed in some embodiments of the present application can form independent electrodes within the display panel for touch sensing, allowing the signal timing during display and touch sensing periods to operate independently. This avoids the need for trade-offs, thereby achieving cost efficiency and reducing the complexity of touch signal processing.

Furthermore, the display device and display panel proposed in some embodiments of the present application can configure the protective layer to be higher than or equal to the upper electrode of the light-emitting elements while forming an opening structure. Under this configuration, the surface flatness of the display panel is determined by the protective layer and thus unaffected by LED size and process variations. Additionally, the design of the opening structure can compensate for height differences among LEDs caused by size and process variations while ensuring that the upper electrode leads can electrically connect to the upper electrodes of each LED through the openings. This ensures uniform line widths for the upper electrode leads formed on the protective layer, guaranteeing consistent electrical signal transmission characteristics for each LED. Other embodiments of the display device, display panel, and their manufacturing methods proposed in the present application involve applying a force toward the substrate during the process, causing the light-emitting elements to displace differently based on their individual sizes/heights and resulting in varying substrate spacings. This keeps the upper electrodes of the light-emitting elements aligned on the same plane. Under this configuration, size variations among individual LEDs are compensated by different substrate spacings, unaffected by LED size and process variations, enabling a flat module surface. Consequently, the upper electrode leads formed on the protective layer can all have uniform widths, ensuring consistent electrical signal transmission characteristics for each LED. Since the upper surfaces of all light-emitting elements can be maintained at the same level without height differences, subsequent processes are unaffected by display panel flatness, effectively improving process yield and reliability.

It is worth mentioning that in some embodiments, the implementations shown in FIGS. 30A to 30G for achieving LED surface planarization can also be applied to the touch control display panel designs in FIGS. 27A to 29B, thereby providing a touch control display panel with improved surface flatness. In other words, although some structures in the embodiments of FIG. 29/FIG. 30 are not depicted in FIG. 30/FIG. 29 (e.g., the wiring layer WL, isolation layer DL, etc.), those skilled in the art should understand, upon referring to the descriptions of the aforementioned embodiments, that the scope disclosed in the present application also includes embodiments that simultaneously incorporate the structures of both FIG. 29 and FIG. 30. This is clarified here in advance.

Additionally, it should be noted here that the material layers described in the embodiments of the present application (e.g., metal layer, insulating layer, etc.) may be referred to by the same or different terms across different embodiments. However, these terms are only used to describe the relative relationships between components within the current embodiment and do not specifically define the relative relationships of material layers between different embodiments. For example, “metal layer ML1” and “metal layer ML2” are used to describe two structurally/functionally distinct metal material layers within the same embodiment. That is, the metal layer ML1 (or the first metal layer) in one embodiment may correspond to the metal layer ML2 (or the second metal layer) in another embodiment. In other words, unless explicitly excluded in the present application, material layers designated by the same term may be the same or different across different embodiments. This is clarified here in advance.

Although the present application has been disclosed through the aforementioned embodiments, it is not intended to limit the scope of the present application. Any modifications or variations made by those skilled in the art without departing from the spirit and scope of the present application, relative to the above embodiments, shall still fall within the technical scope protected by the present application. Therefore, the protection scope of the present application shall be determined by the claims.

What is claimed is:

1. A display panel, comprising:
a substrate having a display region and a non-display region, wherein the non-display region comprises a bezel area; a pixel array disposed on the display region of the substrate and comprising a plurality of pixel units arranged in an array;
a plurality of scan lines formed on the substrate and electrically connected to each row of pixel units in the pixel array;
a plurality of data lines formed on the substrate and electrically connected to each column of pixel units in the pixel array; and
an electrostatic protection structure disposed in at least a portion of the bezel area and comprising a first metal layer, a first insulating layer, a second metal layer, and a second insulating layer stacked in sequence, wherein at least one of the first metal layer and the second metal layer has a porous structure to form a discontinuous island structure in a cross-section of the electrostatic protection structure.

2. The display panel according to claim 1, wherein the electrostatic protection structure further comprises:
a first conducting layer formed between the first insulating layer and the second insulating layer and electrically connected to one of the first metal layer and the second metal layer,
wherein the first conducting layer is a light-transmitting conducting layer, and the first conducting layer, the first insulating layer and the second insulating layer are stacked at the porous structure to form a plurality of light-transmitting parts, wherein the plurality of light-transmitting parts are sequentially spaced along an arrangement direction of the porous structures.

3. The display panel according to claim 1, wherein a cross-sectional width of the first metal layer is greater than that of the second metal layer.

4. The display panel according to claim 3, wherein the panel electrostatic protection structure comprises an inner ring structure and an outer ring structure, wherein the inner ring structure has the first metal layer and the second metal layer, and the outer ring structure only has the first metal layer.

5. The display panel according to claim 4, wherein the electrostatic protection structure forms a metal stripe pattern surrounding part of the non-display region based on the plurality of light-transmitting parts and the porous structure, and the electrostatic protection structure further comprises a bridge region disposed in another portion of the non-display region, wherein the first metal layer and the second metal layer are electrically isolated from each other in an region of the metal stripe pattern and only electrically contact each other in the bridge region.

6. The display panel according to claim 1, wherein a spacing between the electrostatic protection structure and an edge of the substrate is greater than or equal to 20 millimeters.

7. The display panel according to claim 1, wherein the display panel further comprises:
a first fan-out transmission part disposed on one side of the non-display region and having a plurality of fan-out lines, wherein the plurality of fan-out lines of the first fan-out transmission part are electrically connected to odd-numbered scan lines respectively; and
a second fan-out transmission part disposed on an opposite side of the non-display region relative to the first fan-out transmission part and having a plurality of fan-out lines, wherein the plurality of fan-out lines of the second fan-out transmission part are electrically connected to even-numbered scan lines respectively,
wherein the plurality of scan lines comprise a first scan line group and a second scan line group, the plurality of fan-out lines electrically connected to the first scan line group are formed on the substrate in a first line structure, and the plurality of fan-out lines electrically connected to the second scan line group are formed on the substrate in a second line structure.

8. The display panel according to claim 7, wherein the first line structure comprises a single-layer metal line structure formed by the first metal layer, and the second line structure comprises a double-layer metal line structure formed by alternating the first metal layer and the second metal layer.

9. The display panel according to claim 8, wherein fan-out lines formed by the second metal layer are connected to the corresponding scan lines via a bridge architecture, and the bridge architecture comprises:
a first through hole formed on a partial region of the second insulating layer covering the second metal layer;
a second through hole formed on a partial region of the first insulating layer and the second insulating layer covering the first metal layer; and
a second conducting layer, covering the second insulating layer, connected to the second metal layer through the first through hole and connected to the first metal layer through the second through hole, thereby electrically connecting the first metal layer and the second metal layer via the second conducting layer.

10. The display panel according to claim 7, wherein the non-display region further comprises a data circuit fan-out area adjacent to the display region, wherein a shortest distance between any scan line comprised in the first scan line group and the data circuit fan-out area is greater than a shortest distance between any scan line comprised in the second scan line group and the data circuit fan-out area.

11. The display panel according to claim 1, wherein the plurality of pixel units comprises a first pixel unit, and the first pixel unit comprises:
a thin film transistor having a first terminal, a second terminal, and a control terminal, wherein the first terminal is electrically connected to a corresponding data line, and the control terminal is electrically connected to a corresponding scan line;
a third insulating layer formed on the substrate;
a third metal layer formed on the third insulating layer and electrically connected to the second terminal of the thin film transistor;
a fourth insulating layer covering the third metal layer;
a common electrode having a grid structure and formed on the fourth insulating layer, wherein the common electrode comprises a first portion and a second portion, an orthographic projection region of the first portion of the common electrode at least partially overlaps with an orthographic projection region of the third metal layer, and an orthographic projection region of the second portion of the common electrode substantially does not overlap with the orthographic projection region of the third metal layer; and
an extended metal layer electrically connected to the third metal layer and covered by the fourth insulating layer, wherein at least a portion of the extended metal layer is formed within the orthographic projection region of the second portion of the common electrode.

12. The display panel according to claim 11, wherein the first pixel unit further comprises:
a counter substrate;
a liquid crystal layer formed between the common electrode and the counter substrate; and
a black matrix formed on a side of the counter substrate facing the substrate, wherein an orthographic projection region of at least a portion of the black matrix overlaps with the orthographic projection region of the second portion of the common electrode,
wherein the extended metal layer is located within the orthographic projection region of at least the portion of the black matrix.

13. The display panel according to claim 11, wherein two adjacent pixel units among the plurality of pixel units have a gap region, and the extended metal layer comprises:
a first extension part, with one end connected to the second terminal of the corresponding thin film transistor and the other end extending toward the gap region to be formed on the third insulating layer and at least partially covering the third metal layer; and
a second extension part, with one end connected to the other end of the first extension part and the other end extending along the orthographic projection region of the second portion of the common electrode to be formed on the third insulating layer.

14. The display panel according to claim 11, wherein two adjacent pixel units of the plurality of pixel units have a gap region, and the extended metal layer comprises:
a first extension part, with one end connected to the third metal layer and the other end extending toward the gap region to be formed on the third insulating layer; and
a second extension part, with one end connected to the other end of the first extension part and the other end extending along the orthographic projection region of the second portion of the common electrode to be formed on the third insulating layer.

15. The display panel according to claim 1, wherein the plurality of pixel units comprises a first pixel unit and a second pixel unit, wherein the first pixel unit is electrically connected to a n^{th} scan line, and the second pixel unit is electrically connected to a (n+1)^{th} scan line, where n is a natural number, and wherein the second pixel unit comprises:
a thin film transistor having a first terminal, a second terminal, and a control terminal, wherein the first terminal is electrically connected to a corresponding data line, and the control terminal is electrically connected to the (n+1)^{th} scan line;
a third insulating layer formed on the substrate and covering the n^{th} scan line;
a third metal layer formed on the third insulating layer and electrically connected to the second terminal of the thin film transistor, wherein the third metal layer has a first portion and a second portion;
a fourth insulating layer covering the third metal layer; and
a common electrode, having a grid structure and formed on the fourth insulating layer, and comprising a first portion and a second portion,
wherein an orthographic projection region of the first portion of the third metal layer at least partially overlaps with an orthographic projection region of the first portion of the common electrode, and
wherein an orthographic projection region of the second portion of the third metal layer at least partially overlaps with orthographic projection regions of the second portion of the common electrode and the n^{th} scan line.

16. The display panel according to claim 15, wherein the n^{th} scan line located between two adjacent rows of pixel units comprises a first line segment and a second line segment connected to each other, wherein the first line segment and the second line segment are not parallel to each other.

17. The display panel according to claim 16, wherein an overlapping area between orthographic projection regions of the second portion of the third metal layer and the first line segment of the n^{th} scan line is substantially the same as an overlapping area between orthographic projection regions of the second portion of the third metal layer and the second line segment.

18. The display panel according to claim 16, wherein an overlapping area between orthographic projection regions of the second portion of the third metal layer and one of the first line segment and the second line segment of the n^{th} scan line is greater than an overlapping area between orthographic projection regions of the second portion of the third metal layer and the other of the first line segment and the second line segment.

19. The display panel according to claim 1, further comprising:
a scan driving circuit disposed on the non-display region and comprising a plurality of scan units electrically connected to the plurality of scan lines, wherein each of the scan units comprises at least one holding capacitor, and a structure of the holding capacitor comprises the first metal layer, the first insulating layer, the second metal layer, the second insulating layer, a third conducting layer, and a fourth conducting layer, wherein:
the third conducting layer and the fourth conducting layer are light-transmitting conducting layers, the third conducting layer is disposed on the second insulating layer, and the fourth conducting layer is disposed on the first insulating layer and is at least partially covered by the second insulating layer, wherein one end of the fourth conducting layer is connected to the second metal layer;
wherein at least a partial region of the first metal layer is formed with a through hole to expose the at least partial region of the first metal layer from the first insulating layer and the second insulating layer,
wherein the third conducting layer is connected to the exposed at least partial region of the first metal layer via the through hole.

20. The display panel according to claim 19, wherein a portion of the second metal layer extends over another partial region of the fourth conducting layer, such that the second metal layer and the fourth conducting layer at least partially overlap in a normal direction of the substrate.

21. The display panel according to claim 19, wherein the holding capacitor is a sum of a first capacitor, a second capacitor, and a third capacitor, wherein the first capacitor is constituted based on a first overlapping region of the first metal layer and the second metal layer and the first insulating layer located in the first overlapping region, the second capacitor is constituted based on a second overlapping region of the second metal layer and the third conducting layer and the second insulating layer located in the second overlapping region, and the third capacitor is constituted based on a third overlapping region of the third conducting layer and the fourth conducting layer and the second insulating layer located in the third overlapping region.

22. The display panel according to claim 1, wherein the display panel further comprises:
a third metal layer formed in the display region on the substrate and comprising a plurality of first electrode regions and a plurality of second electrode regions, wherein the plurality of first electrode regions and the plurality of second electrode regions are electrically independent from each other and alternately arranged on the substrate at intervals;
a plurality of light-emitting elements, wherein each of the light-emitting elements comprises a first electrode and a second electrode formed on opposite sides, and the first electrode is electrically connected to a corresponding first electrode region;
a protective layer filled between the plurality of light-emitting elements and covering at least a portion of a surface of each light-emitting element; and
a fourth metal layer formed on the protective layer and comprising a plurality of third electrode regions, wherein the plurality of third electrode regions are respectively formed on the plurality of light-emitting elements and electrically connected to the second electrodes of the corresponding light-emitting elements,
wherein each pixel unit comprises a display unit and a touch control sensing unit, the display unit comprises a corresponding light-emitting element and a first electrode region and a third electrode region electrically connected to the corresponding light-emitting element, and the touch control sensing unit comprises a second electrode region and a fourth electrode region adjacent to the display unit.

23. The display panel according to claim 22, wherein the orthographic projection regions of the plurality of third electrode regions on the substrate do not completely overlap with the orthographic projection regions of the plurality of second electrode regions on the substrate.

24. The display panel according to claim 23, wherein the orthographic projection regions of the plurality of third electrode regions on the substrate and the orthographic projection regions of the plurality of second electrode regions on the substrate do not overlap at all.

25. The display panel according to claim 24, wherein the fourth metal layer further comprises a plurality of fourth electrode regions, wherein the plurality of third electrode regions and the plurality of fourth electrode regions are electrically independent from each other, and the plurality of fourth electrode regions are electrically connected to the corresponding plurality of second electrode regions respectively.

26. An electrostatic protection structure, comprising:
a mother substrate comprising a plurality of array blocks; and
a plurality of display panels sequentially arranged on the array blocks of the mother substrate, wherein each of the array blocks comprises:
a first metal layer formed on each of the array blocks in a manner of surrounding at least two of the plurality of display panels, thereby forming a plurality of first electrostatic discharge lines on each of the array blocks;
a first insulating layer covering the first metal layer and exposing at least a portion of the first metal layer;
a second metal layer formed on the first insulating layer in a manner of surrounding at least two of the plurality of display panels, thereby forming a plurality of second electrostatic discharge lines corresponding to the plurality of first electrostatic discharge lines on each of the array blocks;
a second insulating layer covering the second metal layer and exposing at least a portion of the second metal layer; and
a first conducting layer formed in a bridge region, wherein at least a portion of the first conducting layer is connected to the first metal layer through a portion exposed by the first insulating layer, and at least another portion of the first conducting layer is connected to the second metal layer through a portion exposed by the second insulating layer, thereby electrically connecting the plurality of first electrostatic discharge lines and the plurality of second electrostatic discharge lines in the bridge region.

27. The electrostatic protection structure according to claim 26, wherein a portion of the bridge region is disposed at a corner of each of the array blocks.

28. The electrostatic protection structure according to claim 27, wherein another portion of the bridge region is disposed at a position equidistant from bridge regions at two adjacent corners.

29. The electrostatic protection structure according to claim 26, wherein the first insulating layer electrically isolates each of the first electrostatic discharge lines in a non-bridge region, and the second insulating layer electrically isolates each of the second electrostatic discharge lines in the non-bridge region.

30. The electrostatic protection structure according to claim 26, wherein among the plurality of first electrostatic discharge lines and the plurality of second electrostatic discharge lines, a pitch between two adjacent first electrostatic discharge lines or second electrostatic discharge lines is greater than 200 μm.

31. The electrostatic protection structure according to claim 30, wherein the pitch between two adjacent first electrostatic discharge lines or second electrostatic discharge lines is between 200 μm-300 μm.

32. The electrostatic protection structure according to claim 30, wherein a width of the plurality of first electrostatic discharge lines and the plurality of second electrostatic discharge lines does not exceed 1500 μm.

33. The electrostatic protection structure according to claim 26, wherein each of the display panels has a common electrode, and the common electrode of each of the display panels is electrically connected to those of adjacent display panels.

34. The electrostatic protection structure according to claim 33, wherein the plurality of display panels are arranged in a same direction.

35. The electrostatic protection structure according to claim 33, wherein adjacent two rows or two columns of the plurality of display panels are arranged in opposite directions based on a virtual symmetric line.

36. The electrostatic protection structure according to claim 26, wherein each of the display panels comprises:
a substrate having a display region and a non-display region, wherein the non-display region comprises a bezel area; a pixel array disposed on the display region of the substrate and comprising a plurality of pixel units arranged in an array;
a plurality of scan lines formed on the substrate and electrically connected to each row of pixel units in the pixel array;
a plurality of data lines formed on the substrate and electrically connected to each column of pixel units in the pixel array; and
a plurality of metal stripe patterns surrounding at least a portion of the bezel area, wherein each metal stripe pattern comprises the first metal layer, the first insulating layer, the second metal layer and the second insulating layer that are arranged in stacked manner,
wherein in each metal stripe pattern, at least one of the first metal layer and the second metal layer has a porous structure to form a discontinuous island structure in a cross-section of the corresponding metal stripe pattern.

37. The electrostatic protection structure according to claim 36, wherein each metal stripe pattern further comprises:
a second conducting layer formed between the first insulating layer and the second insulating layer and electrically connected to one of the first metal layer and the second metal layer,
wherein the second conducting layer is a light-transmitting conducting layer, and the second conducting layer, the first insulating layer and the second insulating layer are stacked at the porous structure to form a plurality of light-transmitting parts, wherein the plurality of light-transmitting parts are sequentially spaced along an arrangement direction of the porous structures.

38. The electrostatic protection structure according to claim 36, wherein each of the metal stripe patterns has an inner ring structure and an outer ring structure, wherein the inner ring structure comprises the first metal layer and the second metal layer, the outer ring structure does not comprise the second metal layer, and a cross-sectional width of the first metal layer in each of the metal stripe patterns is greater than that of the second metal layer.

39. A display device, comprising:
the display panel according to claim 1, wherein each pixel unit comprises a display unit and a touch control sensing unit;
a display driver chip electrically connected to the display unit for controlling an illumination state of the display unit; and
a touch control sensing chip electrically connected to the touch control sensing unit for driving the touch control sensing unit.

40. The display device according to claim 39, wherein the display panel further comprises:
a third metal layer formed in the display region on the substrate and comprising a plurality of first electrode regions and a plurality of second electrode regions, wherein the plurality of first electrode regions and the plurality of second electrode regions are electrically independent from each other and are alternately arranged on the substrate at intervals;
a plurality of light-emitting elements, wherein each light-emitting element comprises a first electrode and a second electrode formed on opposite sides, and the first electrode is electrically connected to a corresponding first electrode region;
a protective layer filled between the plurality of light-emitting elements and covering at least a portion of a surface of each light-emitting element; and
a fourth metal layer formed on the protective layer and comprising a plurality of third electrode regions, wherein the plurality of third electrode regions are respectively formed on the plurality of light-emitting elements and electrically connected to the second electrodes of the corresponding light-emitting elements,
wherein each pixel unit comprises a display unit and a touch control sensing unit, the display unit comprises a corresponding light-emitting element and a first electrode region and a third electrode region electrically connected to the corresponding light-emitting element, and the touch control sensing unit comprises a second electrode region and a fourth electrode region adjacent to the display unit.

41. The display device according to claim 40, wherein the display panel further comprises:
a first fan-out transmission part disposed on one side of the non-display region and having a plurality of fan-out lines, wherein the plurality of fan-out lines of the first fan-out transmission part are electrically connected to odd-numbered scan lines respectively; and
a second fan-out transmission part disposed on an opposite side of the non-display region relative to the first fan-out transmission part and having a plurality of fan-out lines, wherein the plurality of fan-out lines of the second fan-out transmission part are electrically connected to even-numbered scan lines respectively,
wherein the plurality of scan lines comprise a first scan line group and a second scan line group, the plurality of fan-out lines electrically connected to the first scan line group are formed on the substrate in a first line structure, and the plurality of fan-out lines electrically connected to the second scan line group are formed on the substrate in a second line structure.

42. The display device according to claim 41, wherein the display driver chip comprises:
a scan driving circuit disposed on the non-display region and comprising a plurality of scan units for electrically connecting the plurality of scan lines, wherein each of the scan units comprises at least one holding capacitor, and a structure of the holding capacitor comprises the first metal layer, the first insulating layer, the second metal layer, the second insulating layer, the third conducting layer and the fourth conducting layer, wherein:
the third conducting layer and the fourth conducting layer are light-transmitting conducting layers, the third conducting layer is disposed on the second insulating layer, and the fourth conducting layer is disposed on the first insulating layer and is at least partially covered by the second insulating layer, wherein one end of the fourth conducting layer is connected to the second metal layer;
wherein at least a partial region of the first metal layer is formed with a through hole to expose the at least partial region of the first metal layer from the first insulating layer and the second insulating layer,
wherein the third conducting layer is connected to the exposed at least partial region of the first metal layer via the through hole.

43. The display device according to claim 41, wherein the plurality of pixel units comprises a first pixel unit, and the first pixel unit comprises:
a thin film transistor having a first terminal, a second terminal, and a control terminal, wherein the first terminal is electrically connected to a corresponding data line, and the control terminal is electrically connected to a corresponding scan line;
a third insulating layer formed on the substrate;
a third metal layer formed on the third insulating layer and electrically connected to the second terminal of the thin film transistor;
a fourth insulating layer covering the third metal layer;
a common electrode having a grid structure and formed on the fourth insulating layer, wherein the common electrode comprises a first portion and a second portion, an orthographic projection region of the first portion of the common electrode at least partially overlaps with an orthographic projection region of the third metal layer, and an orthographic projection region of the second portion of the common electrode substantially does not overlap with the orthographic projection region of the third metal layer; and
an extended metal layer electrically connected to the third metal layer and covered by the fourth insulating layer, wherein at least a portion of the extended metal layer is formed within the orthographic projection region of the second portion of the common electrode.

44. The display device according to claim 41, wherein the plurality of pixel units comprises a first pixel unit and a second pixel unit, wherein the first pixel unit is electrically connected to a n^{th} scan line, and the second pixel unit is electrically connected to a (n+1)^{th} scan line, where n is a natural number, and wherein the second pixel unit comprises:
a thin film transistor having a first terminal, a second terminal, and a control terminal, wherein the first terminal is electrically connected to a corresponding data line, and the control terminal is electrically connected to the (n+1)^{th} scan line;
a third insulating layer formed on the substrate and covering the n^{th} scan line;
a third metal layer formed on the third insulating layer and electrically connected to the second terminal of the thin film transistor, wherein the third metal layer has a first portion and a second portion;
a fourth insulating layer covering the third metal layer; and
a common electrode, having a grid structure and formed on the fourth insulating layer, and comprising a first portion and a second portion,
wherein an orthographic projection region of the first portion of the third metal layer at least partially overlaps with an orthographic projection region of the first portion of the common electrode, and
wherein an orthographic projection region of the second portion of the third metal layer at least partially overlaps with orthographic projection regions of the second portion of the common electrode and the n^{th} scan line.
